(19) United States
(12) Patent Application Publication
(10) Pub. No.: US 2026/0202748 A1
(43) Pub. Date: Jul. 16, 2026

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM Corporation, Tokyo (JP)

(72) Inventors: Yuka Kamino, Shizuoka (JP); Tomoaki Yoshioka, Shizuoka (JP); Shuhei Yamaguchi, Shizuoka (JP)

(73) Assignee: FUJIFILM Corporation, Tokyo (JP)

(21) Appl. No.: 19/562,962

(22) Filed: Mar. 11, 2026

Related U.S. Application Data
(63) Continuation of application No. PCT/JP2024/029650, filed on Aug. 21, 2024.

(30) Foreign Application Priority Data
Sep. 13, 2023 (JP) 2023-148781
Feb. 2, 2024 (JP) 2024-014850

(51) Int. Cl. G03F 7/039; G03F 7/004

(52) U.S. Cl. CPC G03F 7/0395; G03F 7/0045

(57) ABSTRACT

An actinic ray-sensitive or radiation-sensitive resin composition containing a resin (A) including a repeating unit having a group that is decomposed by an action of an acid, thereby increasing polarity, and a compound (B) having a specified structure and having a molecular weight of 400 or more, and an actinic ray-sensitive or radiation-sensitive film, a pattern forming method, and a method for producing an electronic device that use the actinic ray-sensitive or radiation-sensitive composition.

### CROSS REFERENCE TO RELATED APPLICATION

This is a continuation of International Application No. PCT/JP2024/029650 filed on Aug. 21, 2024, and claims priorities from Japanese Patent Application No. 2023-148781 filed on Sep. 13, 2023, and Japanese Patent Application No. 2024-014850 filed on Feb. 2, 2024, the entire disclosures of which is incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device. More specifically, the present invention relates to an actinic ray-sensitive or radiation-sensitive resin composition that can be suitably used in ultramicrolithography processes applicable to, for example, processes for producing ultra-LSIs (Large Scale Integrations) and high-capacity microchips, processes for producing nanoimprint molds, and processes for producing high-density information recording media, and other photofabrication processes, an actinic ray-sensitive or radiation-sensitive film, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB: Electron Beam), X-rays, extreme ultraviolet rays (EUV: Extreme Ultraviolet), or the like is also being developed. With this, resist compositions effectively sensitive to various actinic rays or radiations have been developed.

JP1998-83079A (JP-H10-83079A), JP2000-10270A, JP2012-181510A, and JP2013-130717A describe resist compositions containing a photobase generator.

### SUMMARY OF THE INVENTION

In recent years, resist compositions have been required to have higher performance, and, for example, further improvements in resolution, process margin, and the like are expected. The process margin refers to an allowable range (margin) in which a desired result can be obtained even in the case of variations in various conditions (for example, the temperature during heating) in the process of pattern formation using a resist composition; the wider this allowable range, the better the process margin. In pattern formation using a resist composition, after exposure of a resist film formed from the resist composition and before development, baking (heating) may be performed. The heating after exposure is also referred to as PEB (Post Exposure Bake). The process margin for the temperature of PEB is also referred to as “PEB temperature dependence”. The lower the PEB temperature dependence, the smaller the changes in the performance in response to the changes in the temperature of PEB, which is preferred.

Accordingly, an object of the present invention is to provide an actinic ray-sensitive or radiation-sensitive resin composition that provides high resolution and has low PEB temperature dependence. Another object of the present invention is to provide an actinic ray-sensitive or radiation-sensitive film, a pattern forming method, and a method for producing an electronic device that use the actinic ray-sensitive or radiation-sensitive resin composition.

The inventors of the present invention have found that the following features can address the above-described objects.

[1]

An actinic ray-sensitive or radiation-sensitive resin composition including:
a resin (A) including a repeating unit having a group that is decomposed by an action of an acid, thereby increasing polarity; and
a compound (B) represented by a formula (N1) below and having a molecular weight of 400 or more,

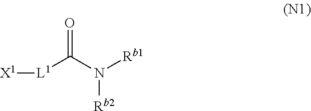

wherein in the formula (N1),
L¹ represents a single bond, *¹—OCR^{b3}R^{b4}—*², or *¹—CR^{b5}R^{b6}—*², *¹ represents a bonding site to C(═O), *² represents a bonding site to X¹,
X¹ represents an aryl group, a heteroaryl group, *³—CR^{b7}═CR^{b8}R^{b9}, or *³—C≡CR^{b10}, *³ represents a bonding site to L¹,
R^{b1} represents a hydrogen atom or a substituent,
R^{b2} represents a substituent,
provided that R^{b1} and R^{b2} do not include a structure represented by a formula (NX1) below, and R^{b1} and R^{b2} may be bonded together to form a ring,
R^{b3} to R^{b8} each independently represent a hydrogen atom or a substituent,
R^{b9} and R^{b10} each independently represent a substituent,

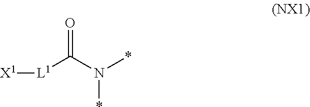

in the formula (NX1), L¹ and X¹ respectively have the same meanings as L¹ and X¹ in the formula (N1), and * represents a bonding site.
   [2]

The actinic ray-sensitive or radiation-sensitive resin composition according to [1], wherein, when L¹ in the formula (N1) represents a single bond or *¹—OCR^{b3}R^{b4}—*², X¹ in the formula (N1) represents an aryl group, a heteroaryl group, or *³—CR^{b7}═CR^{b8}R^{b9}, or
when L¹ in the formula (N1) represents *¹—CR^{b5}R^{b6}—*², X¹ in the formula (N1) represents an aryl group or a heteroaryl group.
   [3]

The actinic ray-sensitive or radiation-sensitive resin composition according to [1] or [2], wherein the compound (B) is represented by a formula (N2) below:

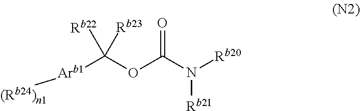

in the formula (N2),
R^{b20} represents a hydrogen atom or a substituent,
R^{b21} represents a substituent,
provided that R^{b20} and R^{b21} do not include the structure represented by the formula (NX1), and R^{b20} and R^{b21} may be bonded together to form a ring,
R^{b22} and R^{b23} each independently represent a hydrogen atom or a substituent,
R^{b24} represents a substituent,
Ar^{b1} represents an aromatic ring group having 4 to 20 ring members,
n1 represents an integer of 0 to 12, and when n1 represents an integer of 2 or more, a plurality of R^{b24} may be the same or different, and the plurality of R^{b24} may be bonded together to form a ring.
   [3]

The actinic ray-sensitive or radiation-sensitive resin composition according to [3], wherein R^{b22} and R^{b23} in the formula (N2) each independently represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group.

[4]

The actinic ray-sensitive or radiation-sensitive resin composition according to [3] or [4], wherein R^{b20} and R^{b21} in the formula (N2) each independently represent an alkyl group or a cycloalkyl group, and R^{b20} and R^{b21} may be bonded together to form a ring.

[6]

The actinic ray-sensitive or radiation-sensitive resin composition according to [1] or [2], wherein the compound (B) is represented by a formula (N3) below:

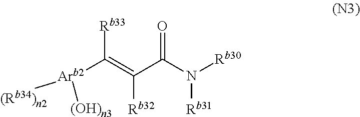

in the formula (N3),
R^{b30} represents a hydrogen atom or a substituent,
R^{b31} represents a substituent,
provided that R^{b30} and R^{b31} do not include the structure represented by the formula (NX1), and R^{b30} and R^{b31} may be bonded together to form a ring,
R^{b32} and R^{b33} each independently represent a hydrogen atom or a substituent,
R^{b34} represents a substituent other than a hydroxy group,
Ar^{b2} represents an aromatic ring group having 4 to 20 ring members,
n2 represents an integer of 0 to 11, and when n2 represents an integer of 2 or more, a plurality of R^{b34} may be the same or different, and the plurality of R^{b34} may be bonded together to form a ring, and n3 represents 1 or 2.
   [7]

The actinic ray-sensitive or radiation-sensitive resin composition according to [1] or [2], wherein the compound (B) is represented by a formula (N4) below:

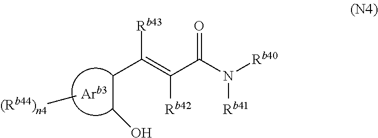

in the formula (N4),
R^{b40} and R^{b41} each independently represent an alkyl group or a cycloalkyl group, provided that R^{b40} and R^{b41} do not include the structure represented by the formula (NX1), and R^{b40} and R^{b41} may be bonded together to form a ring,
R^{b42} and R^{b43} each independently represent a hydrogen atom or a substituent,
R^{b44} represents a substituent other than a hydroxy group,
Ar^{b3} represents an aromatic ring group having 4 to 20 ring members,
n4 represents an integer of 0 to 11, and when n4 represents an integer of 2 or more, a plurality of R^{b44} may be the same or different, and the plurality of R^{b44} may be bonded together to form a ring.
   [8]

The actinic ray-sensitive or radiation-sensitive resin composition according to [1] or [2], wherein, in the formula (N1),
R^{b1} represents a hydrogen atom, an alkyl group, a cycloalkyl group, an aryl group, or a group represented by a formula (GN1) below, and
R^{b2} represents an alkyl group, a cycloalkyl group, an aryl group, or a group represented by the following formula (GN1),

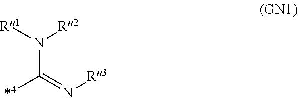

in the formula (GN1), Rⁿ¹ to Rⁿ³ each independently represent a hydrogen atom or a substituent, provided that at least one of R^{b1} to Rⁿ³ represents a substituent, at least two of R^{b1} to Rⁿ³ may be bonded together to form a ring, and
*⁴ represents a bonding site to the nitrogen atom.
   [9]

The actinic ray-sensitive or radiation-sensitive resin composition according to any one of [1] to [8], wherein the compound (B) has a molecular weight of 450 or more.

[10]

The actinic ray-sensitive or radiation-sensitive resin composition according to any one of [1] to [9], wherein the resin (A) has a repeating unit represented by a formula (Pa1) below:

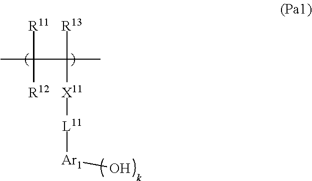

in the formula (Pa1), R¹¹, R¹², and R¹³ each independently represent a hydrogen atom, an alkyl group, a cycloalkyl group, a halogen atom, a cyano group, or an alkoxycarbonyl group; R¹² may be bonded to Ar₁ to form a ring and, in this case, R¹² represents a single bond or an alkylene group;
X¹¹ represents a single bond, —COO—, or —CONR¹⁴—,
R¹⁴ represents a hydrogen atom or an alkyl group,
L¹¹ represents a single bond or an alkylene group;
Ar₁ represents a (k+1)-valent aromatic ring group or represents, in a case of being bonded to R¹² to form a ring, a (k+2)-valent aromatic ring group; and
k represents an integer of 1 to 5.
   [11]

The actinic ray-sensitive or radiation-sensitive resin composition according to any one of [1] to [10], wherein the resin (A) has a repeating unit represented by a formula (Ga1) below:

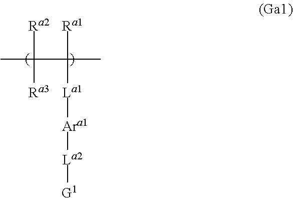

in the formula (Ga1), R^{a1}, R^{a2}, and R^{a3} each independently represent a hydrogen atom, an alkyl group, a cycloalkyl group, a halogen atom, a cyano group, or an alkoxycarbonyl group,
L^{a1} represents a single bond or a divalent linking group,
Ar^{a1} represents an aromatic ring group,
L^{a2} represents —O— or —C(═O)O—,
G¹ represents a group represented by a formula (G-1) or (G-2) below:

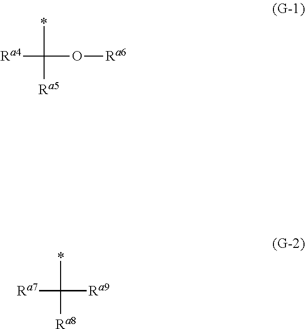

in the formula (G-1), R^{a4} represents a hydrogen atom, an alkyl group, a cycloalkyl group, an aryl group, an aralkyl group, or an alkenyl group,
R^{a5} and R^{a6} each independently represent an alkyl group, a cycloalkyl group, an aryl group, an aralkyl group, or an alkenyl group,
R^{a4} and R^{a5} may be bonded together to form a ring;
when G¹ is a group represented by the formula (G-1), Ar^{a1} may be bonded to R^{a3} or R^{a4} to form a ring;
*represents a bonding site, and
in the formula (G-2), R^{a7}, R^{a8}, and R^{a9} each independently represent an alkyl group, a cycloalkyl group, an aryl group, an aralkyl group, or an alkenyl group, two of R^{a7}, R^{a8}, and R^{a9} may be bonded together to form a ring, and
*represents a bonding site.
   [12]

The actinic ray-sensitive or radiation-sensitive resin composition according to any one of [1] to [11], further including a compound (C) that generates an acid upon irradiation with an actinic ray or a radiation.

[13]

The actinic ray-sensitive or radiation-sensitive resin composition according to any one of [1] to [12], further including an acid diffusion control agent (D).

[14]

An actinic ray-sensitive or radiation-sensitive film formed from the actinic ray-sensitive or radiation-sensitive resin composition according to any one of [1] to [13].

[15]

A pattern forming method including
using the actinic ray-sensitive or radiation-sensitive resin composition according to any one of [1] to [13] to form an actinic ray-sensitive or radiation-sensitive film on a substrate,
exposing the actinic ray-sensitive or radiation-sensitive film, and
using a developer to develop the exposed actinic ray-sensitive or radiation-sensitive film to form a pattern.
   [16]

A method for producing an electronic device, the method including the pattern forming method according to [15].

The present invention can provide an actinic ray-sensitive or radiation-sensitive resin composition that provides high resolution and has low PEB temperature dependence. The present invention can also provide an actinic ray-sensitive or radiation-sensitive film, a pattern forming method, and a method for producing an electronic device that use the actinic ray-sensitive or radiation-sensitive resin composition.

### DESCRIPTION OF THE PREFERRED EMBODIMENTS

Hereinafter, the present invention will be described in detail.

Features may be described below on the basis of representative embodiments of the present invention; however, the present invention is not limited to such embodiments.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, soft X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, X-rays, or EUV, but also patterning using a corpuscular beam such as an electron beam or an ion beam.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M, manufactured by Tosoh Corporation, column temperature: 40° C., flow rate: 1.0 mL/min, detector: differential refractive index detector (Refractive Index Detector)).

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified. Examples of the substituent include monovalent non-metallic atomic groups except for the hydrogen atom and, for example, can be selected from the group consisting of the following substituents T.

### Substituents T

Examples of the substituents T include halogen atoms such as a fluorine atom, a chlorine atom, a bromine atom, and an iodine atom; alkoxy groups such as a methoxy group, an ethoxy group, and a tert-butoxy group; cycloalkyloxy groups; aryloxy groups such as a phenoxy group and a p-tolyloxy group; alkoxycarbonyl groups such as a methoxycarbonyl group and a butoxycarbonyl group; cycloalkyloxycarbonyl groups; aryloxycarbonyl groups such as a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; a sulfanyl group; alkylsulfanyl groups such as a methylsulfanyl group and a tert-butylsulfanyl group; arylsulfanyl groups such as a phenylsulfanyl group and a p-tolylsulfanyl group; alkylsulfonyl groups; arylsulfonyl groups; alkyl groups; alkenyl groups; cycloalkyl groups; aryl groups; heteroaryl groups; a hydroxy group; a carboxyl group; a formyl group; a sulfo group; a cyano group; alkylaminocarbonyl groups; arylaminocarbonyl groups; a sulfonamide group; a silyl group; an amino group; and a carbamoyl group. When these substituents can further have one or more substituents, groups having, as such additional substituents, one or more substituents selected from the group consisting of the above-described substituents (for example, monoalkylamino groups, dialkylamino groups, arylamino groups, and trifluoromethyl groups) are also included in examples of the substituents T.

In this Specification, the bonding directions of divalent groups described are not limited unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H⁺ dissociation free energy in an aqueous solution on the basis of a thermodynamic cycle. The H⁺ dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

In this Specification, “solid content” means components that are included in the actinic ray-sensitive or radiation-sensitive resin composition and are to form the actinic ray-sensitive or radiation-sensitive film and does not include solvents. As long as a component is included in the actinic ray-sensitive or radiation-sensitive resin composition and forms the actinic ray-sensitive or radiation-sensitive film, even when the component has the form of liquid, it is regarded as the solid content.

### Actinic Ray-Sensitive or Radiation-Sensitive Resin Composition

The actinic ray-sensitive or radiation-sensitive resin composition of the present invention (also referred to as “composition of the present invention”) is an actinic ray-sensitive or radiation-sensitive resin composition including a resin (A) including a repeating unit having a group that is decomposed by action of an acid to undergo an increase in polarity, and a compound (B) represented by a formula (N1) below and having a molecular weight of 400 or more.

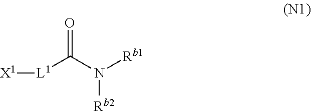

In the formula (N1),
L¹ represents a single bond, *¹—OCR^{b3}R^{b4}—*², or *¹—CR^{b5}R^{b6}—*², *¹ represent a bonding site to C(═O), *² represent a bonding site to X¹,
X¹ represents an aryl group, a heteroaryl group, *³—CR^{b7}═CR^{b8}R^{b9}, or *³—C≡CR^{b10}, *³ represent a bonding site to L¹,
R^{b1} represents a hydrogen atom or a substituent, R^{b2} represents a substituent, provided that R^{b1} and R^{b2} do not include a structure represented by a formula (NX1) below, R^{b1} and R^{b2} may be bonded together to form a ring,
R^{b3} to R^{b8} each independently represent a hydrogen atom or a substituent, and R^{b9} and R^{b10} each independently represent a substituent.

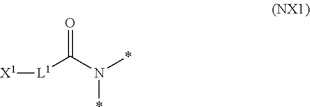

In the formula (NX1), L¹ and X¹ respectively have the same meanings as L¹ and X¹ in the formula (N1), and * represent a bonding site.

The composition of the present invention is typically a resist composition, and may be a positive resist composition or may be a negative resist composition. The composition of the present invention may be a resist composition for alkali development or may be a resist composition for organic-solvent development.

The composition of the present invention may be a chemical amplification resist composition or may be a non-chemical amplification resist composition. The composition of the present invention is typically a chemical amplification resist composition.

The composition of the present invention can be used to form an actinic ray-sensitive or radiation-sensitive film. The actinic ray-sensitive or radiation-sensitive film formed using the composition of the present invention is typically a resist film.

Resin (A) Including Repeating Unit Having Group that is Decomposed by Action of Acid to Undergo Increase in Polarity

The composition of the present invention contains a resin (A) including a repeating unit having a group that is decomposed by action of an acid to undergo an increase in polarity (also simply referred to as “resin (A)”).

### Repeating Unit Having Acid-Decomposable Group

The resin (A) preferably has a repeating unit having an acid-decomposable group.

The acid-decomposable group is a group that is decomposed by action of an acid to undergo an increase in polarity.

The acid-decomposable group is typically a group that is decomposed by action of an acid to generate a polar group. The acid-decomposable group preferably has a structure in which the polar group is protected with a group (leaving group) that leaves by action of an acid. Typically, the resin (A) is subjected to action of an acid to undergo an increase in polarity to undergo an increase in the degree of solubility in the alkali developer, but undergo a decrease in the degree of solubility in organic solvents.

The polar group is preferably an alkali-soluble group; examples thereof include acidic groups such as a carboxy group, a phenolic hydroxy group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

Examples of the leaving group that leaves by action of an acid include groups represented by formulas (Y1) to (Y4).

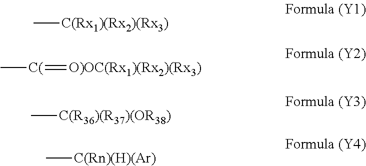

In the formula (Y1) and the formula (Y2), Rx₁ to Rx₃ each independently represent an alkyl group (linear or branched), a cycloalkyl group (monocyclic or polycyclic), an aryl group (monocyclic or polycyclic), an aralkyl group (linear or branched), an alkenyl group (linear or branched), or an alkynyl group (linear or branched). Note that, when all of Rx₁ to Rx₃ are alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded together to form a ring (that may be either monocyclic or polycyclic).

For Rx₁ to Rx₃, the alkyl group may be either linear or branched. The alkyl group is preferably an alkyl group having 1 to 10 carbon atoms, such as a methyl group, an ethyl group, an n-propyl group, an isopropyl group, an n-butyl group, an isobutyl group, or a t-butyl group, and more preferably an alkyl group having 1 to 5 carbon atoms.

For Rx₁ to Rx₃, the cycloalkyl group preferably has 3 to 20 carbon atoms, and more preferably 4 to 15 carbon atoms. For Rx₁ to Rx₃, the cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. In the cycloalkyl group, one or more methylene groups constituting the ring may be replaced by a heteroatom such as an oxygen atom, a sulfur atom, or a nitrogen atom, a group having a heteroatom such as a carbonyl group, or a vinylidene group. One or more ethylene groups constituting the ring may be replaced by a vinylene group.

For Rx₁ to Rx₃, the aryl group is preferably an aryl group having 6 to 20 carbon atoms, more preferably an aryl group having 6 to 10 carbon atoms, and may be, for example, a phenyl group, a naphthyl group, or an anthryl group.

For Rx₁ to Rx₃, the aralkyl group is preferably a group in which one hydrogen atom in the above-described alkyl group for Rx₁ to Rx₃ is substituted with an aryl group having 6 to 10 carbon atoms (preferably a phenyl group), and may be, for example, a benzyl group.

For Rx₁ to Rx₃, the alkenyl group may be an alkenyl group having 2 to 20 carbon atoms, is preferably an alkenyl group having 2 to 10 carbon atoms, and, for example, preferably a vinyl group or an allyl group.

For Rx₁ to Rx₃, the alkynyl group may be an alkynyl group having 2 to 20 carbon atoms, is preferably an alkynyl group having 2 to 10 carbon atoms, and, for example, preferably an ethynyl group.

The ring formed by bonding together two of Rx₁ to Rx₃ is preferably a cycloalkane ring. The cycloalkane ring formed by bonding together two of Rx₁ to Rx₃ may be a monocyclic cycloalkane ring such as a cyclopentane ring or a cyclohexane ring, or may be a polycyclic cycloalkane ring such as a norbornane ring, a tetracyclodecane ring, a tetracyclododecane ring, or an adamantane ring. The cycloalkane ring is preferably a monocyclic cycloalkane ring having 5 to 6 carbon atoms.

In the cycloalkane ring formed by bonding together two of Rx₁ to Rx₃, one or more methylene groups constituting the ring may be replaced by a heteroatom such as an oxygen atom, a sulfur atom, or a nitrogen atom, a group having a heteroatom such as a carbonyl group, or a vinylidene group. One or more ethylene groups constituting the ring may be replaced by a vinylene group. The ring formed by bonding together two of Rx₁ to Rx₃ may have a substituent. The group represented by the formula (Y1) or the formula (Y2) preferably has, for example, a form in which Rx₁ is a methyl group or an ethyl group, and Rx₂ and Rx₃ are bonded together to form a cycloalkane ring.

In the formula (Y3), R₃₆ to R₃₈ each independently represent a hydrogen atom or a monovalent organic group. R₃₇ and R₃₈ may be bonded together to form a ring. The monovalent organic group may be, for example, an alkyl group, a cycloalkyl group, an aryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group having a heteroatom such as a carbonyl group. For example, in the alkyl group, the cycloalkyl group, the aryl group, and the aralkyl group, one or more methylene groups may be replaced by a heteroatom such as an oxygen atom and/or a group having a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

In the formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

The repeating unit having an acid-decomposable group is preferably a repeating unit represented by a formula (Ga1) below.

The resin (A) preferably has a repeating unit represented by the formula (Ga1) below.

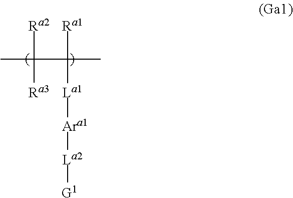

In the formula (Ga1), R^{a1}, R^{a2}, and R^{a3} each independently represent a hydrogen atom, an alkyl group, a cycloalkyl group, a halogen atom, a cyano group, or an alkoxycarbonyl group, L^{a1} represents a single bond or a divalent linking group, Ar^{a1} represents an aromatic ring group, L^{a2} represents —O— or —C(═O)O—, and G¹ represents a group represented by the following formula (G-1) or (G-2).

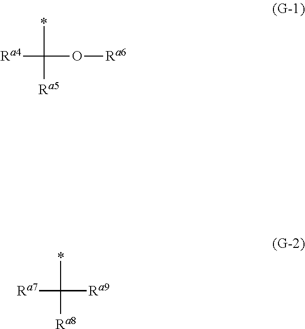

In the formula (G-1), R^{a4} represents a hydrogen atom, an alkyl group, a cycloalkyl group, an aryl group, an aralkyl group, or an alkenyl group, R^{a5} and R^{a6} each independently represent an alkyl group, a cycloalkyl group, an aryl group, an aralkyl group, or an alkenyl group, R^{a4} and R^{a5} may be bonded together to form a ring; when G¹ is a group represented by the formula (G-1), Ar^{a1} may be bonded to R^{a3} or R^{a4} to form a ring; and * represents a bonding site. In the formula (G-2), R^{a7}, R^{a8}, and R^{a9} each independently represent an alkyl group, a cycloalkyl group, an aryl group, an aralkyl group, or an alkenyl group, two of R^{a7}, R^{a8}, and R^{a9} may be bonded together to form a ring, and * represents a bonding site.

In the formula (Ga1), R^{a1}, R^{a2}, and R^{a3} each independently represent a hydrogen atom, an alkyl group, a cycloalkyl group, a halogen atom, a cyano group, or an alkoxycarbonyl group.

For R^{a1}, R^{a2}, and R^{a3}, the alkyl group may be either linear or branched. The number of carbon atoms of the alkyl group is not particularly limited, but is preferably 1 to 10, more preferably 1 to 5, and particularly preferably 1 to 3. Examples of the alkyl group include a methyl group, an ethyl group, an n-propyl group, an isopropyl group, an n-butyl group, an isobutyl group, and a t-butyl group.

For R^{a1}, R^{a2}, and R^{a3}, the number of carbon atoms of the cycloalkyl group is not particularly limited, but is preferably 3 to 20, and more preferably 5 to 15. For R^{a1}, R^{a2}, and R^{a3}, the cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group.

For R^{a1}, R^{a2}, and R^{a3}, the halogen atom may be a fluorine atom, a chlorine atom, a bromine atom, or an iodine atom, and is preferably a fluorine atom or an iodine atom.

For R^{a1}, R^{a2}, and R^{a3}, the alkyl group included in the alkoxycarbonyl group may be either linear or branched. For the alkyl group included in the alkoxycarbonyl group, the number of carbon atoms is not particularly limited, but is preferably 1 to 5, and more preferably 1 to 3.

R^{a1}, R^{a2}, and R^{a3} each independently preferably represent a hydrogen atom or an alkyl group.

L^{a1} in the formula (Ga1) represents a single bond or a divalent linking group. The divalent linking group represented by L^{a1} is not particularly limited, but may be, for example, —O—, —CO—, —COO—, —CONR^{a10}—, an alkylene group, a cycloalkylene group, or a group in which two or more of these groups are combined. R^{a10} represents a hydrogen atom or an alkyl group.

The alkylene group represented by L^{a1} may be either linear or branched. The number of carbon atoms of the alkylene group is not particularly limited. The alkylene group is not particularly limited, but is preferably, for example, an alkylene group having 1 to 8 carbon atoms such as a methylene group, an ethylene group, a propylene group, a butylene group, a hexylene group, or an octylene group.

The number of carbon atoms of the cycloalkylene group represented by L^{a1} is not particularly limited, but is preferably 3 to 20, and more preferably 5 to 15. The cycloalkylene group may be a monocyclic cycloalkylene group such as a cyclopentylene group or a cyclohexylene group, or may be a polycyclic cycloalkylene group such as a norbornylene group, a tetracyclodecanylene group, a tetracyclododecanylene group, or an adamantylene group.

The alkyl group represented by R^{a10} may be either linear or branched, may be, for example, an alkyl group having 1 to 20 carbon atoms such as a methyl group, an ethyl group, a propyl group, an isopropyl group, an n-butyl group, a sec-butyl group, a hexyl group, a 2-ethylhexyl group, an octyl group, or a dodecyl group, and is preferably an alkyl group having 1 to 8 carbon atoms.

Ar^{a1} in the formula (Ga1) represents an aromatic ring group, and specifically represents a divalent aromatic ring group. The divalent aromatic ring group may be, for example, an arylene group having 6 to 18 carbon atoms, such as a phenylene group, a tolylene group, a naphthylene group, an anthrylene group, or a biphenylene group. The divalent aromatic ring group may also be, for example, a divalent aromatic ring group including a heterocyclic ring including at least one heteroatom selected from the group consisting of a nitrogen atom, an oxygen atom, and a sulfur atom, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aromatic ring group may have a substituent.

Ar^{a1} preferably represents an arylene group having 6 to 12 carbon atoms, and more preferably a phenylene group or a naphthylene group.

In the formula (Ga1), L^{a2} represents —O— or —C(═O)O—.

In the formula (Ga1), G¹ represents a group represented by the formula (G-1) or (G-2).

In the formula (G-1), R^{a4} represents a hydrogen atom, an alkyl group, a cycloalkyl group, an aryl group, an aralkyl group, or an alkenyl group. The alkyl group, the cycloalkyl group, the aryl group, the aralkyl group, and the alkenyl group may have a substituent.

The alkyl group of R^{a4} may be either linear or branched. The alkyl group is preferably an alkyl group having 1 to 10 carbon atoms, such as a methyl group, an ethyl group, an n-propyl group, an isopropyl group, an n-butyl group, an isobutyl group, or a t-butyl group, and more preferably an alkyl group having 1 to 5 carbon atoms.

The cycloalkyl group of R^{a4} preferably has 3 to 20 carbon atoms, and more preferably 4 to 15 carbon atoms. The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. In the cycloalkyl group, for example, one of the methylene groups constituting the ring may be replaced by a heteroatom such as an oxygen atom, a group having a heteroatom such as a carbonyl group, or a vinylidene group. In the cycloalkyl group, one or more of the ethylene groups constituting the cycloalkane ring may be replaced by a vinylene group.

The aryl group of R^{a4} is preferably an aryl group having 6 to 20 carbon atoms, more preferably an aryl group having 6 to 10 carbon atoms, and may be, for example, a phenyl group, a naphthyl group, or an anthryl group.

The aralkyl group of R^{a4} is preferably a group in which one hydrogen atom in the above-described alkyl group of R^{a4} is substituted with an aryl group having 6 to 10 carbon atoms (preferably a phenyl group), and may be, for example, a benzyl group.

The alkenyl group of R^{a4} may be an alkenyl group having 2 to 20 carbon atoms, preferably an alkenyl group having 2 to 10 carbon atoms, and is preferably, for example, a vinyl group or an allyl group.

R^{a4} preferably represents a hydrogen atom, an alkyl group, or a cycloalkyl group.

In the formula (G-1), R^{a5} and R^{a}s each independently represent an alkyl group, a cycloalkyl group, an aryl group, an aralkyl group, or an alkenyl group. The descriptions, specific examples, and preferred ranges of the alkyl group, cycloalkyl group, aryl group, aralkyl group, and alkenyl group represented by R^{a5} and R^{a6} are the same as those described above for R^{a4}, R^{a5} and R^{a6} each independently preferably represent an alkyl group or a cycloalkyl group.

In the formula (G-1), R^{a4} and R^{a5} may be bonded together to form a ring. The ring formed by bonding together R^{a4} and R^{a5} is preferably a cycloalkane ring. The cycloalkane ring may be a monocyclic cycloalkane ring such as a cyclopentane ring or a cyclohexane ring, or may be a polycyclic cycloalkane ring such as a norbornane ring, a tetracyclodecane ring, a tetracyclododecane ring, or an adamantane ring. The cycloalkane ring is preferably a monocyclic cycloalkane ring having 5 to 6 carbon atoms. In the cycloalkane ring, one or more methylene groups constituting the ring may be replaced by a heteroatom such as an oxygen atom, a nitrogen atom, or a sulfur atom, a group having a heteroatom such as a carbonyl group, or a vinylidene group. One or more ethylene groups constituting the ring may be replaced by a vinylene group. The ring formed by bonding together R^{a4} and R^{a5} may have a substituent.

When G¹ in the formula (Ga1) is a group represented by the formula (G-1), Ar^{a1} may be bonded to R^{a3} or R^{a4} to form a ring. The descriptions, specific examples, and preferred ranges of the ring formed by bonding together Ar^{a1} and R^{a3} or R^{a4} are the same as those described above for the ring formed by bonding together R^{a4} and R^{a5}.

In the formula (G-2), R^{a7}, R^{a8}, and R^{a9} each independently represent an alkyl group, a cycloalkyl group, an aryl group, an aralkyl group, or an alkenyl group. The descriptions, specific examples, and preferred ranges of the alkyl group, cycloalkyl group, aryl group, aralkyl group, and alkenyl group represented by R^{a7}, R^{a8}, and R^{a9} are the same as those described above for R^{a4}, R^{a7}, R^{a8}, and R^{a9} each independently preferably represent an alkyl group or a cycloalkyl group.

Two of R^{a7}, R^{a8}, and R^{a9} in the formula (G-2) may be bonded together to form a ring. The descriptions, specific examples, and preferred ranges of the ring formed by bonding together two of R^{a7}, R^{a8}, and R^{a9} are the same as those described above for the ring formed by bonding together R^{a4} and R^{a8}.

Specific examples of the repeating unit having an acid-decomposable group will be described below, but the present invention is not limited thereto. Rx represent H, CH₃, CF₃, or CH₂OH. Rxa and Rxb each independently represent a linear or branched alkyl group having 1 to 5 carbon atoms. p represent an integer of 0 or more. Z represent a substituent. When a plurality of Z's are present, the plurality of Z's may be the same or different. Me represents a methyl group.

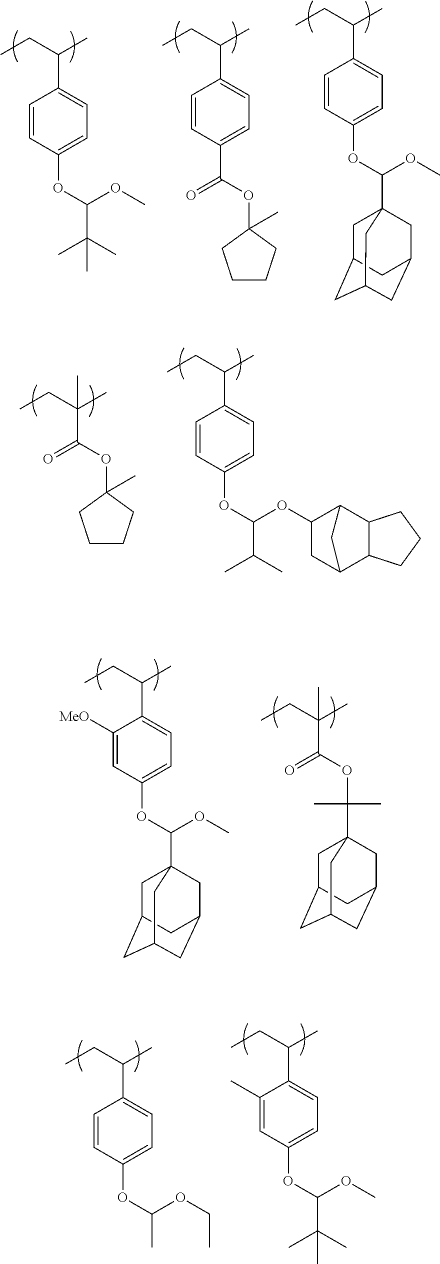

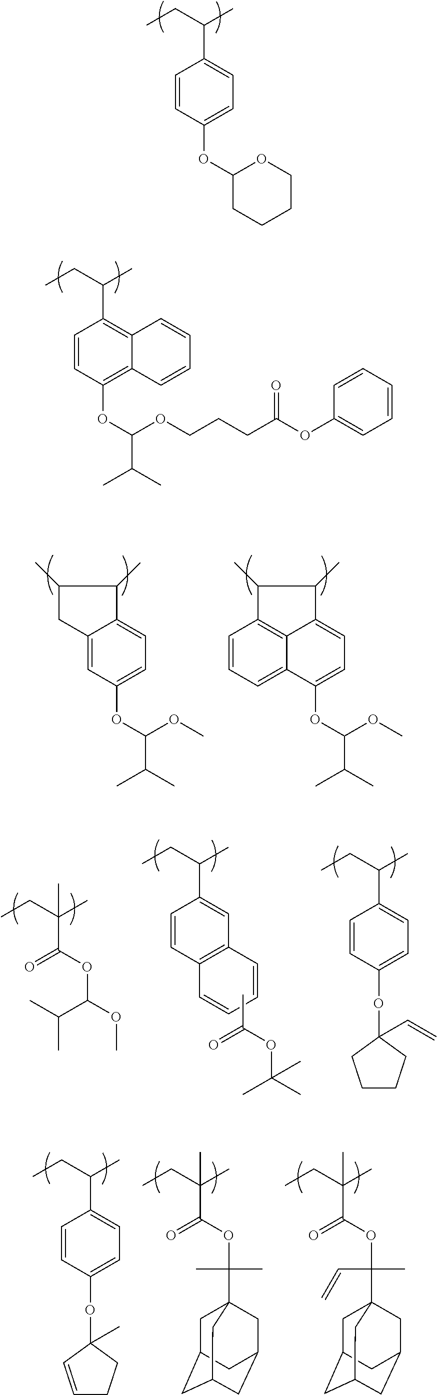

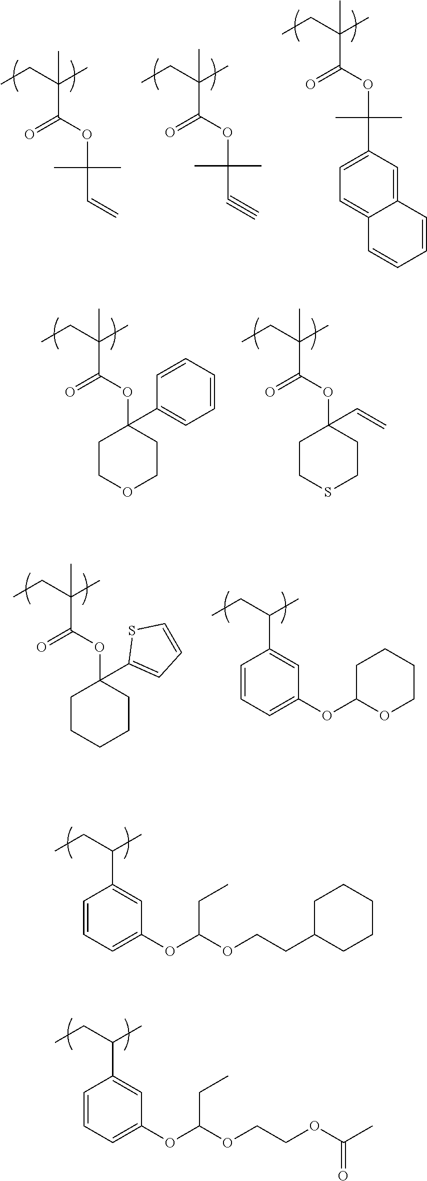

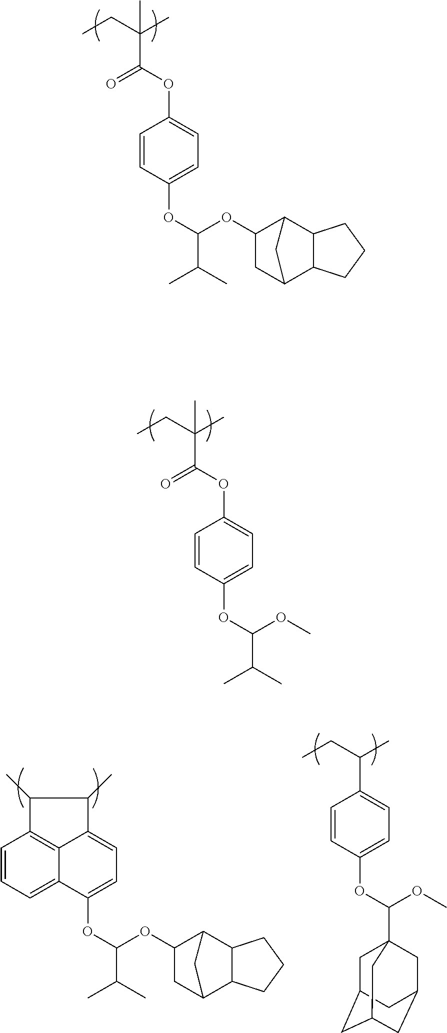

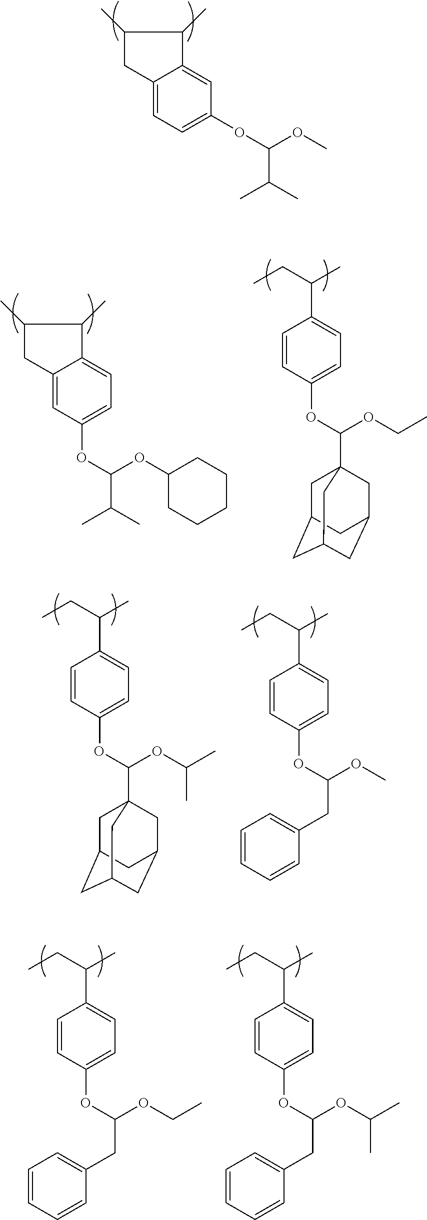

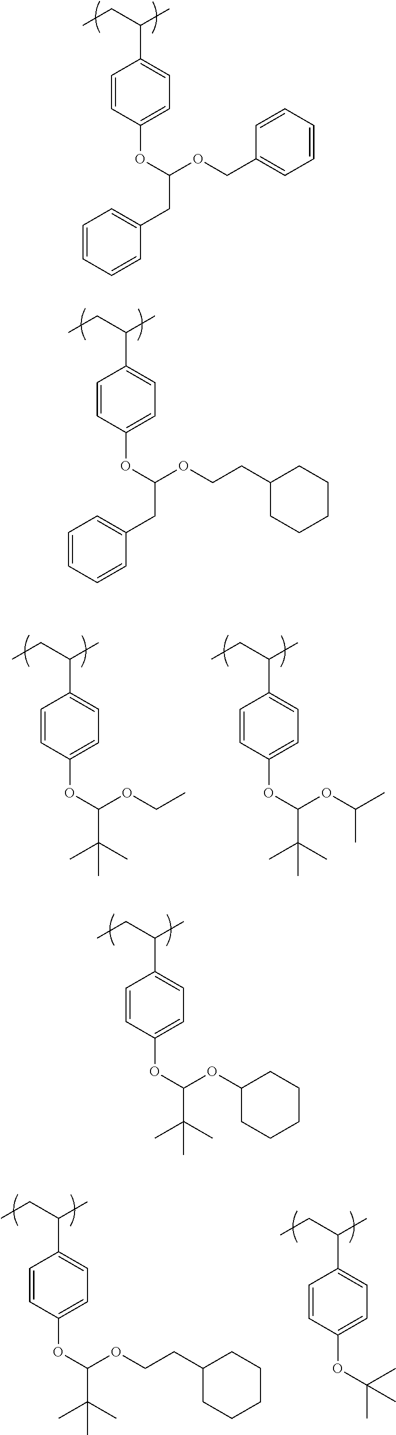

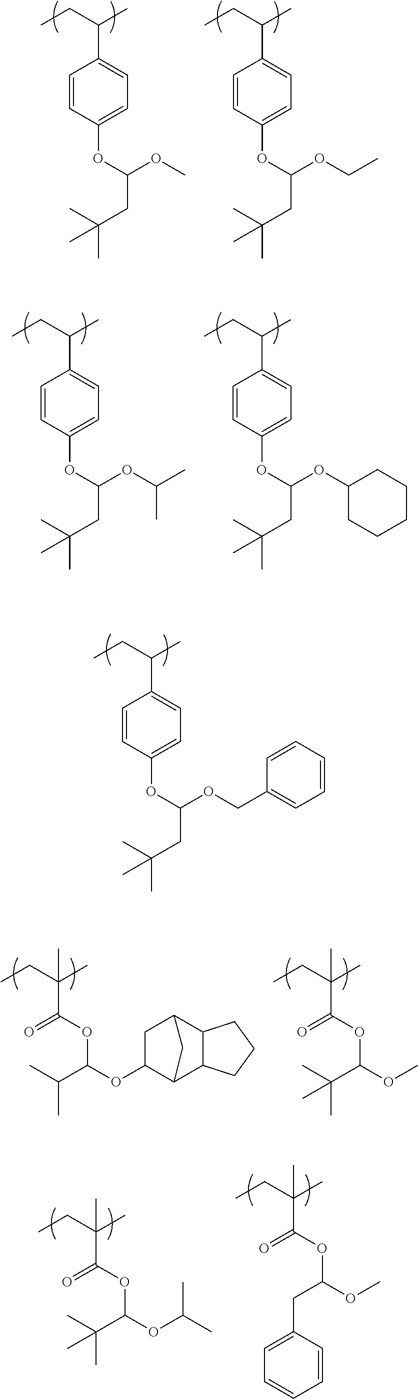

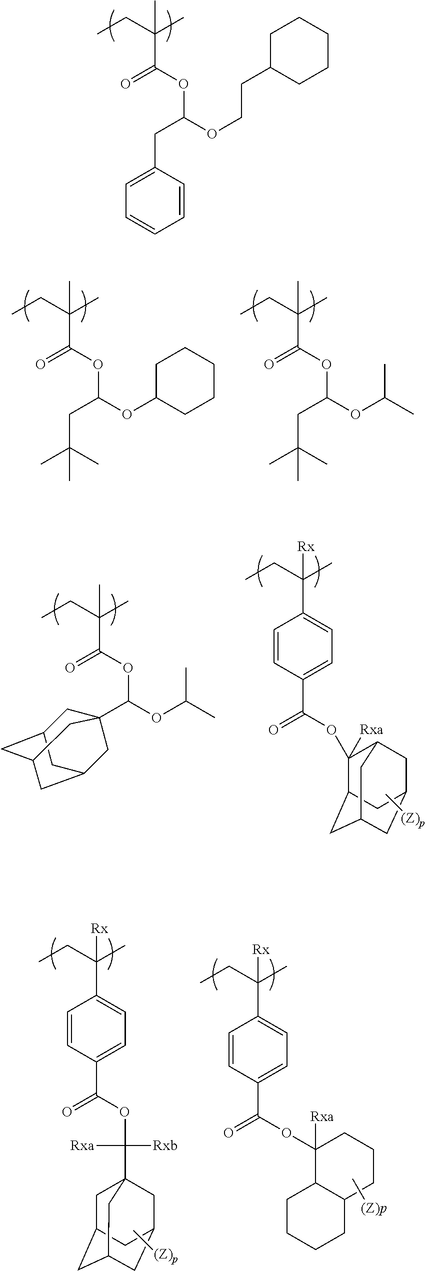

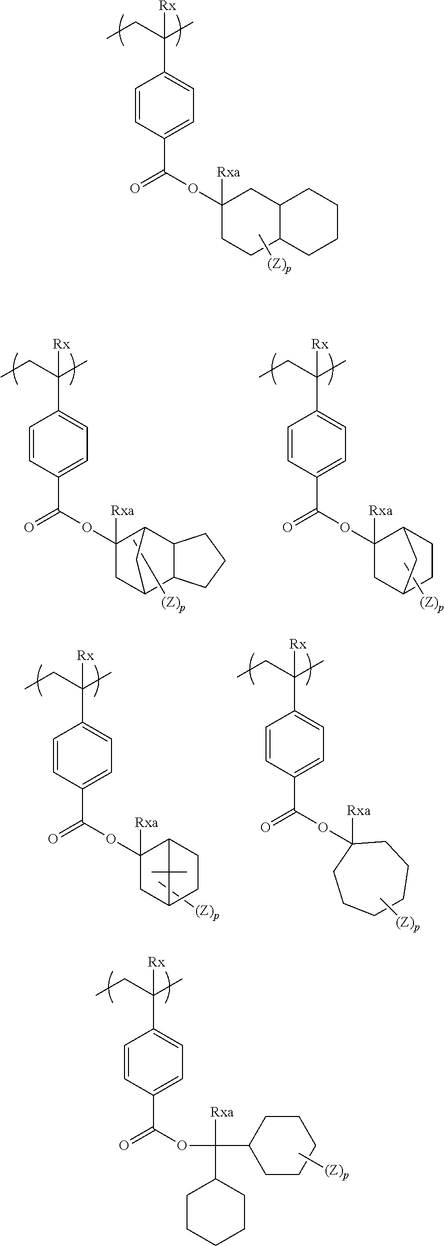

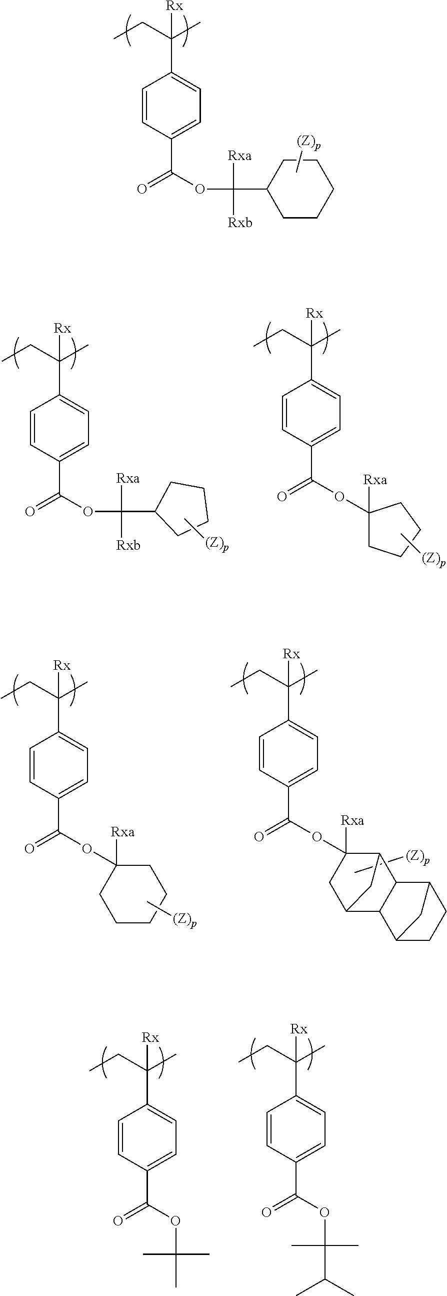

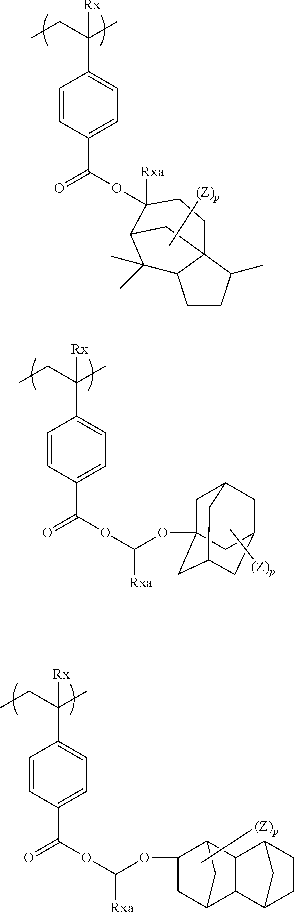

The content of the repeating unit having an acid-decomposable group relative to all the repeating units in the resin (A) is preferably 5 mol % or more, more preferably 10 mol % or more, and still more preferably 15 mol % or more. The content of the repeating unit having an acid-decomposable group relative to all the repeating units in the resin (A) is preferably 70 mol % or less, more preferably 60 mol % or less, and still more preferably 50 mol % or less.

The repeating unit having an acid-decomposable group included in the resin (A) may be of one type, or may be of two or more types. When the resin (A) includes two or more types of repeating units having an acid-decomposable group, the total content thereof is preferably within such a preferred content range.

### Repeating Unit Having Phenolic Hydroxyl Group

The resin (A) preferably has a repeating unit having a phenolic hydroxyl group.

The repeating unit having a phenolic hydroxyl group is preferably a repeating unit different from the above-described repeating unit having an acid-decomposable group.

The repeating unit having a phenolic hydroxyl group is preferably a repeating unit represented by a formula (Pa1) below.

The resin (A) preferably has a repeating unit represented by the formula (Pa1) below.

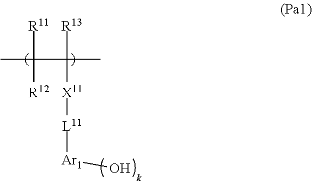

In the formula (Pa1), R¹¹, R¹², and R¹³ each independently represent a hydrogen atom, an alkyl group, a cycloalkyl group, a halogen atom, a cyano group, or an alkoxycarbonyl group; R¹² may be bonded to Ar₁ to form a ring and, in this case, R¹² represents a single bond or an alkylene group; X¹¹ represents a single bond, —COO—, or —CONR¹⁴—; R¹⁴ represents a hydrogen atom or an alkyl group; L¹¹ represents a single bond or an alkylene group; Ar₁ represents a (k+1)-valent aromatic ring group or represents, in a case of being bonded to R¹² to form a ring, a (k+2)-valent aromatic ring group; and k represents an integer of 1 to 5.

In the formula (Pa1), R¹¹, R¹², and R¹³ each independently represent a hydrogen atom, an alkyl group, a cycloalkyl group, a halogen atom, a cyano group, or an alkoxycarbonyl group. The descriptions, specific examples, and preferred ranges for R¹¹, R¹², and R¹³ are the same as those described above for R^{a1}, R^{a2}, and R^{a3} in the formula (Ga1).

X¹¹ in the formula (Pa1) represents a single bond, —COO—, or —CONR¹⁴—. R¹⁴ represents a hydrogen atom or an alkyl group. The alkyl group represented by R¹⁴ may be either linear or branched, may be, for example, an alkyl group having 1 to 20 carbon atoms such as a methyl group, an ethyl group, a propyl group, an isopropyl group, an n-butyl group, a sec-butyl group, a hexyl group, a 2-ethylhexyl group, an octyl group, or a dodecyl group, and is preferably an alkyl group having 1 to 8 carbon atoms.

L¹¹ in the formula (Pa1) represents a single bond or an alkylene group. The alkylene group of L¹¹ may be either linear or branched. The number of carbon atoms of the alkylene group is not particularly limited. The alkylene group is not particularly limited, but is preferably an alkylene group having 1 to 8 carbon atoms such as a methylene group, an ethylene group, a propylene group, a butylene group, a hexylene group, or an octylene group.

In the formula (Pa1), Ar₁ represents a (k+1)-valent aromatic ring group or, in the case of being bonded to R¹² to form a ring, represents a (k+2)-valent aromatic ring group. k represents an integer of 1 to 5.

When k is 1, Ar₁ represents a divalent aromatic ring group. The divalent aromatic ring group may be, for example, an arylene group having 6 to 18 carbon atoms, such as a phenylene group, a tolylene group, a naphthylene group, an anthrylene group, or a biphenylene group. The divalent aromatic ring group may also be a divalent aromatic ring group including a heterocyclic ring including at least one heteroatom selected from the group consisting of a nitrogen atom, an oxygen atom, and a sulfur atom, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aromatic ring group may have a substituent.

When k is an integer of 2 or more, specific examples of the (k+1)-valent aromatic ring group include groups provided by removing any (k−1) hydrogen atoms from the above-described specific examples of the divalent aromatic ring group.

The (k+1)-valent aromatic ring group may further have a substituent.

The substituent that the (k+1)-valent aromatic ring group may have is not particularly limited, but examples thereof include alkyl groups such as a methyl group, an ethyl group, a propyl group, an isopropyl group, an n-butyl group, a sec-butyl group, a hexyl group, a 2-ethylhexyl group, an octyl group, and a dodecyl group; alkoxy groups such as a methoxy group, an ethoxy group, a hydroxyethoxy group, a propoxy group, a hydroxypropoxy group, and a butoxy group; and aryl groups such as a phenyl group.

Ar₁ preferably represents an aromatic ring group having 6 to 18 carbon atoms, and more preferably represents a benzene ring group, a naphthalene ring group, or a biphenylene ring group.

The repeating unit represented by the formula (Pa1) preferably includes a hydroxystyrene structure. That is, Ar₁ preferably represents a benzene ring group.

k preferably represents an integer of 1 to 3, and more preferably represents 1 or 2.

Specific examples of the repeating unit having a phenolic hydroxyl group will be described below, but the present invention is not limited thereto. In the following structural formulas, G¹ and G² each independently represent a hydrogen atom, a methyl group, a cyano group, a hydroxy group, or a hydroxymethyl group. f1 represent an integer of 1 to 3.

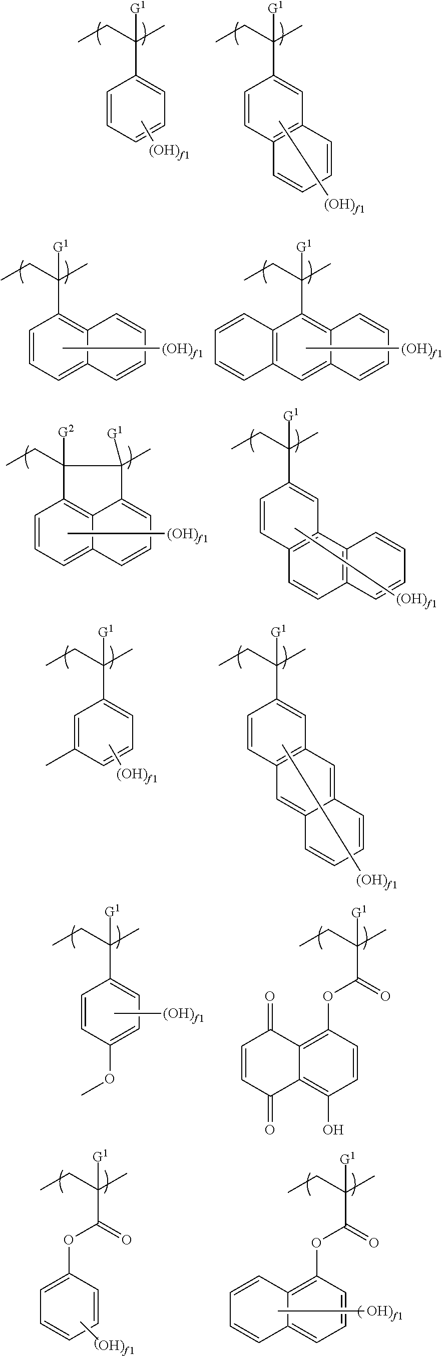

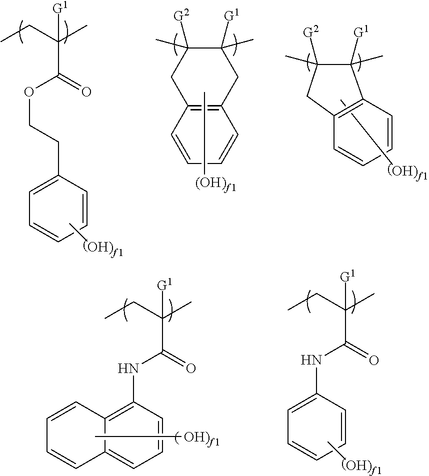

When the resin (A) has a repeating unit having a phenolic hydroxyl group, the content of the repeating unit having a phenolic hydroxyl group in the resin (A) is not particularly limited, but is, relative to all the repeating units in the resin (A), preferably 20 mol % or more, more preferably 30 mol % or more, and still more preferably 40 mol % or more. The content of the repeating unit having a phenolic hydroxyl group relative to all the repeating units in the resin (A) is preferably 90 mol % or less, more preferably 85 mol % or less, and still more preferably 80 mol % or less.

The repeating unit having a phenolic hydroxyl group included in the resin (A) may be of one type, or may be of two or more types. When the resin (A) includes two or more types of repeating units having a phenolic hydroxyl group, the total content thereof is preferably within such a preferred content range.

### Repeating Unit Having Lactone Group, Sultone Group, or Carbonate Group

The resin (A) may have a repeating unit having a lactone group, a sultone group, or a carbonate group (hereafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The carbonate group is preferably a cyclic carbonic acid ester group.

For the repeating unit having a cyclic carbonic acid ester group, for example, the descriptions in [0127] to [0133] of WO2022/024928A can be referred to. The above descriptions are incorporated herein.

The resin (A) preferably has a repeating unit having a lactone group, a sultone group, or a carbonate group obtained by removing one or more hydrogen atoms from a ring-member atom of a lactone structure represented by any one of the following formulas (LC1-1) to (LC1-22), a sultone structure represented by any one of the following formulas (SL1-1) to (SL1-3), or a cyclic carbonic acid ester structure represented by any one of the following formulas (CC1-1) to (CC1-2), and the lactone group, the sultone group, or the carbonate group may be directly bonded to the main chain. For example, the ring-member atoms of the lactone group, the sultone group, or the carbonate group may constitute the main chain of the resin (A). The lactone group, the sultone group, and the carbonate group may have a substituent.

In the following structural formulas, R^{L} represent a substituent. When a plurality of R^{L} are present, the plurality of R^{L} may be the same or may be different. R^{L} may be, for example, an alkyl group having 1 to 8 carbon atoms, a cycloalkyl group having 4 to 10 carbon atoms, an alkoxy group having 1 to 8 carbon atoms, an alkoxycarbonyl group having 2 to 8 carbon atoms, a carboxyl group, a halogen atom, a cyano group, or an acid-decomposable group. e1 represent an integer of 0 to 4. When a plurality of e1 are present, the plurality of e1 may be the same or may be different. When e1 is 2 or more, the plurality of R^{L} present may be the same or different, and the plurality of R^{L} present may bonded together to form a ring.

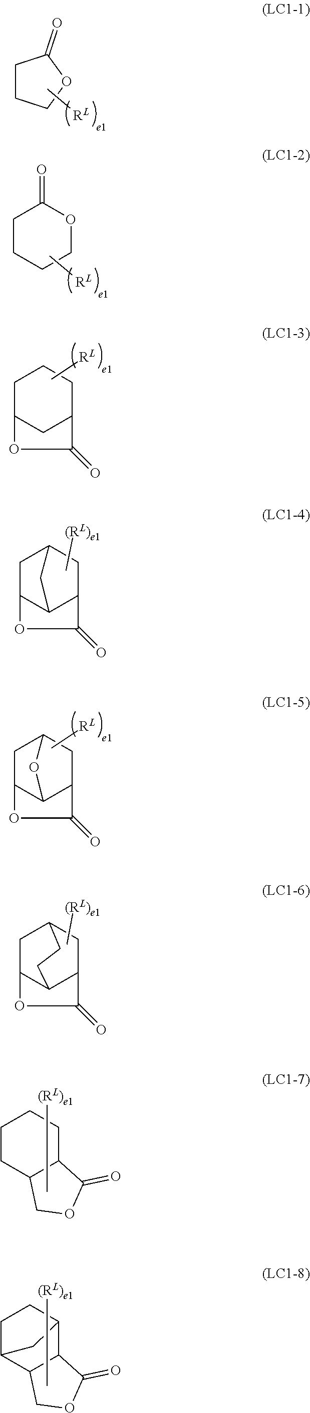

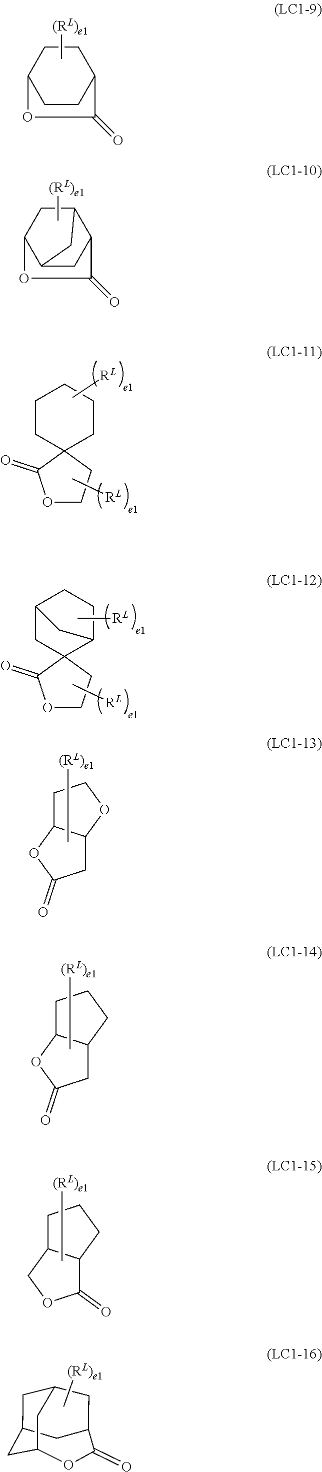

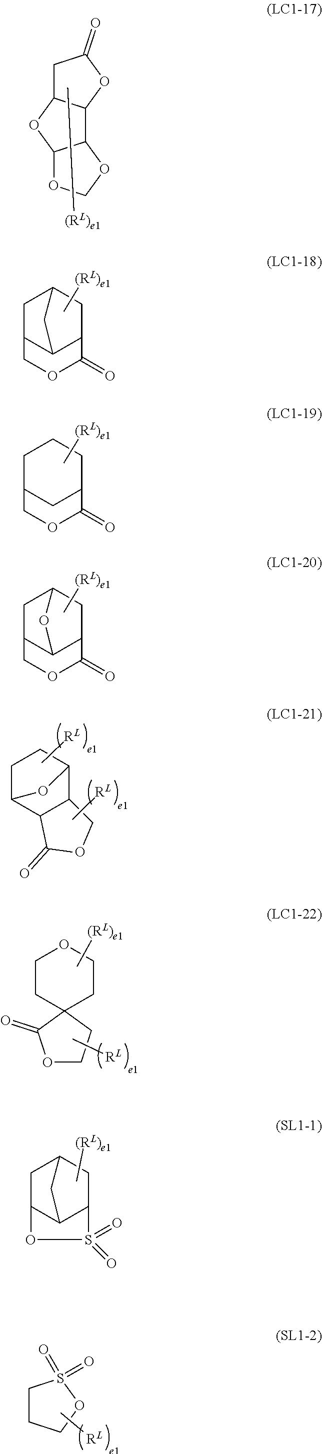

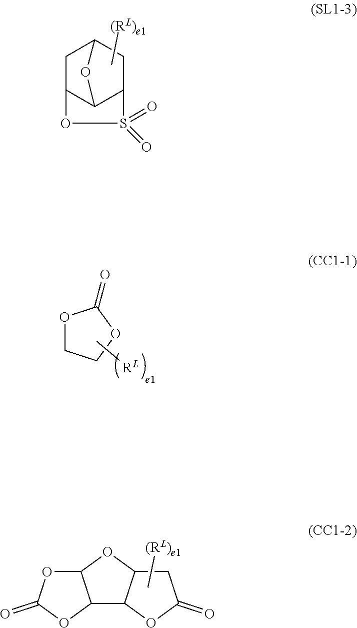

Examples of the repeating unit having a lactone group, a sultone group, or a carbonate group include a repeating unit represented by the following formula (AJ-2).

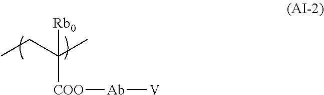

In the formula (AI-2), Rb₀ represents a hydrogen atom, a halogen atom, or an alkyl group having 1 to 4 carbon atoms. The alkyl group of Rb₀ may have a substituent. The substituent that the alkyl group of Rb₀ may have may be a hydroxyl group or a halogen atom.

The halogen atom of Rb₀ may be a fluorine atom, a chlorine atom, a bromine atom, or an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, or a divalent linking group that is a combination of the foregoing. In particular, Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by removing one hydrogen atom from a ring-member atom of a lactone structure represented by any one of the formulas (LC1-1) to (LC1-22), a group formed by removing one hydrogen atom from a ring-member atom of a sultone structure represented by any one of the formulas (SL1-1) to (SL1-3), or a group formed by removing one hydrogen atom from a ring-member atom of a cyclic carbonic acid ester structure represented by any one of the formulas (CC1-1) to (CC1-2).

When the resin (A) includes the unit Y, the unit Y content relative to all the repeating units in the resin (A) may be 1 mol % or more, or may be 10 mol % or more. The unit Y content relative to all the repeating units in the resin (A) may be 80 mol % or less, or may be 70 mol % or less.

The resin (A) also preferably does not include the unit Y

### Repeating Unit Having Photoacid Generation Group

The resin (A) may have a repeating unit having a group that generates an acid upon irradiation with an actinic ray or a radiation (also referred to as a “photoacid generation group”). The repeating unit having a photoacid generation group may be a repeating unit represented by a formula (4).

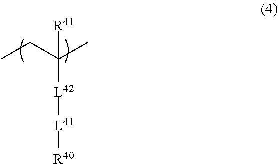

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

L⁴¹ represents a single bond or a divalent linking group, and preferably represents a single bond or an ester bond (—COO—).

L⁴² is preferably a linking group formed of at least one selected from the group consisting of an alkylene group, a cycloalkylene group, an arylene group, —O—, —CO—, —S—, —SO—, —SO₂—, and —NR—. R represents a hydrogen atom or an organic group (preferably an organic group having 1 to 10 carbon atoms such as an alkyl group, a cycloalkyl group, or an aryl group).

The alkylene group may be either linear or branched. The number of carbon atoms of the alkylene group is not particularly limited, but is preferably 1 to 10.

The cycloalkylene group may be a monocyclic cycloalkylene group or a polycyclic cycloalkylene group. The number of carbon atoms of the cycloalkylene group is not particularly limited, but is preferably 3 to 20, and more preferably 5 to 15.

The number of carbon atoms of the arylene group is not particularly limited, but is preferably 6 to 20, and more preferably 6 to 10.

The alkylene group, the cycloalkylene group, and the arylene group may have a substituent, and such substituents may be the above-described substituents T.

R⁴⁰ is preferably a group represented by the following formula (S4-1).

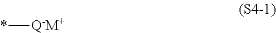

In the formula (54-1), Q⁻ represents an acid residue, and M⁺ represents a cation. * represents a bonding site to L⁴¹.

The acid residue is a group formed by dissociation of a proton from an acid.

Q⁻ is preferably a carboxylate anion group (COO—), a sulfonate anion group (SO₃⁻), or a sulfonamide group (represented by N—SO₂R^{N1}; R^{N1} represents an organic group, may be an organic group having 1 to 10 carbon atoms, is preferably an alkyl group, a fluoroalkyl group, or an aryl group), and more preferably a sulfonate anion group.

The descriptions, specific examples, and preferred ranges of M⁺ are the same as those described later for M⁺ in the description of the photoacid generator.

Specific examples of the repeating unit having a photoacid generation group include the repeating units described in [0094] to [0105] of JP2014-041327A, the repeating units described in [0094] of WO2018/193954A, and the repeating units described in [0138] of WO2022/024928A. The above descriptions are incorporated herein.

Examples of the repeating unit represented by the formula (4) include the repeating units described in Paragraphs [0094] to [0105] of JP2014-041327A, and the repeating units described in Paragraph [0094] of WO2018/193954A.

When the resin (A) includes a repeating unit having a photoacid generation group, the content of the repeating unit having a photoacid generation group relative to all the repeating units in the resin (A) is preferably 1 mol % or more, more preferably 3 mol % or more, and particularly preferably 5 mol % or more. The content of the repeating unit having a photoacid generation group relative to all the repeating units in the resin (A) is preferably 40 mol % or less, more preferably 30 mol % or less, and particularly preferably 20 mol % or less.

The resin (A) also preferably does not include a repeating unit having a photoacid generation group.

### Repeating Unit Represented by Formula (V-1) or Formula (V-2)

The resin (A) may have a repeating unit represented by a formula (V-1) below or a formula (V-2) below.

The repeating unit represented by the following formula (V-1) and the repeating unit represented by the following formula (V-2) are also preferably repeating units different from the above-described repeating units.

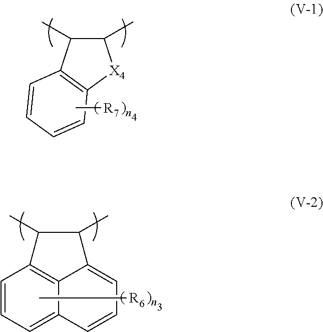

In the formulas (V-1) and (V-2), R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. The alkyl group is preferably a linear, branched, or cyclic alkyl group having 1 to 10 carbon atoms. n₃ represents an integer of 0 to 6. n₄ represents an integer of 0 to 4. X₄ is a methylene group, an oxygen atom, or a sulfur atom.

Examples of the repeating unit represented by the formula (V-1) or the formula (V-2) include the repeating units described in Paragraph [0100] of WO2018/193954A.

### Repeating Unit for Lowering Mobility of Main Chain

The resin (A) may have a high glass transition temperature (Tg) from the viewpoint that excessive diffusion of the generated acid or pattern collapse during development can be suppressed. Tg may be more than 90° C., may be more than 100° C., may be more than 110° C., or may be more than 125° C. From the viewpoint of providing a high dissolution rate in the developer, Tg may be 400° C. or less, or may be 350° C. or less.

In this Specification, the glass transition temperature (Tg) of the polymer such as the resin (A) (hereafter, “Tg's of the repeating units”) is calculated by the following method. First, for the repeating units included in the polymer, the Tg's of homopolymers composed only of the repeating units are individually calculated by the Bicerano method. Subsequently, the mass ratios (%) of the repeating units relative to all the repeating units in the polymer are calculated. Subsequently, the Fox equation (described in Materials Letters 62 (2008) 3152, for example) is used to calculate Tg's for the mass ratios and the Tg's are summed up to determine the Tg(° C.) of the polymer.

The Bicerano method is described in Prediction of polymer properties, Marcel Dekker Inc, New York (1993). The calculation of Tg by the Bicerano method can be performed using the software for estimating properties of polymers, MDL Polymer (MDL Information Systems, Inc.).

For the repeating unit for lowering the mobility of the main chain, the contents of of WO2022/024928A are referred to.

Repeating unit having at least one group species selected from the group consisting of lactone group, sultone group, carbonate group, hydroxy group, cyano group, and alkali-soluble group

The resin (A) may have a repeating unit having at least one group species selected from the group consisting of a lactone group, a sultone group, a carbonate group, a hydroxy group, a cyano group, and an alkali-soluble group.

In the resin (A), the repeating unit having a lactone group, a sultone group, or a carbonate group may be the repeating unit having been described above in <Repeating unit having lactone group, sultone group, or carbonate group>. Preferred contents are also the same as those having been described in <Repeating unit having lactone group, sultone group, or carbonate group>.

The resin (A) may have a repeating unit having a hydroxy group or a cyano group. This results in improvement in adhesiveness to the substrate and affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano group include those described in Paragraphs [0081] to [0084] of JP2014-098921A.

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the α position, with an electron-withdrawing group (for example, a hexafluoroisopropanol group), and is preferably a carboxyl group. When the resin (A) includes the repeating unit having an alkali-soluble group, improved resolution is provided particularly in the contact hole application. Examples of the repeating unit having an alkali-soluble group include those described in Paragraphs [0085] and [0086] of JP2014-098921A.

### Repeating Unit Having Alicyclic Hydrocarbon Structure and not Exhibiting Acid-Decomposability

The resin (A) may have a repeating unit having an alicyclic hydrocarbon structure and not exhibiting acid-decomposability. This results in, during liquid immersion exposure, a reduction in leaching of, from the resist film to the immersion liquid, low-molecular-weight components. Examples of the repeating unit having an alicyclic hydrocarbon structure and not exhibiting acid-decomposability include a repeating unit derived from 1-adamantyl (meth)acrylate, diamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

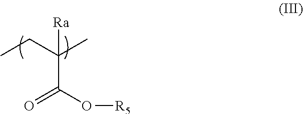

In the formula (III), R₅ represents a hydrocarbon group having at least one ring structure and not having a hydroxy group or a cyano group. Ra represents a hydrogen atom, an alkyl group, or a —CH₂—O—Ra₂ group. In the formula, Ra₂ represents a hydrogen atom, an alkyl group, or an acyl group.

Examples of the repeating unit not having a hydroxy group or a cyano group and represented by the formula (III) include those described in Paragraphs [0087] to [0094] of JP2014-098921A.

### Other Repeating Unit

Furthermore, the resin (A) may have another repeating unit other than the above-described repeating units.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group. Examples of the repeating unit include those described in [0170] of WO2022/024928A.

For the resin (A), the contents of [0112] to [0118] and [0171] to [0172] of WO2022/024928A can be further referred to.

The resin (A) can be synthesized by standard procedures (for example, radical polymerization).

The resin (A) has a weight-average molecular weight (Mw) of, as a polystyrene-equivalent value determined by the GPC method, preferably 30000 or less, more preferably 1000 to 30000, still more preferably 3000 to 30000, and particularly preferably 5000 to 15000.

The resin (A) has a dispersity (molecular weight distribution, Pd, Mw/Mn) of preferably 1 to 5, more preferably 1 to 3, still more preferably 1.0 to 3.0, and particularly preferably 1.1 to 2.0. As the dispersity lowers, the resolution becomes higher, the resist profile becomes better, the sidewalls of the resist pattern become smoother, and the roughness performance becomes higher.

The content of the resin (A) in the composition of the present invention relative to the total solid content of the composition of the present invention is preferably 40.0 to 99.9 mass %, and more preferably 60.0 to 90.0 mass %.

Such resins (A) may be used alone or may be used in combination of two or more thereof. When two or more resins (A) are used, the total content thereof is preferably within such a preferred content range.

### Compound (B) Represented by Formula (N1) and Having Molecular Weight of 400 or More

The composition of the present invention contains a compound (B) represented by the following formula (N1) and having a molecular weight of 400 or more (also simply referred to as “compound (B)”).

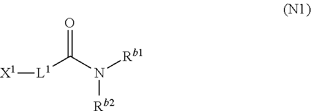

In the formula (N1),
L¹ represents a single bond, *¹—OCR^{b3}R^{b4}—*², or *¹—CR^{B5}R^{b6}—*², *¹ represent a bonding site to C(═O), *² represent a bonding site to X¹,
X¹ represents an aryl group, a heteroaryl group, *³—CR^{b7}═CR^{b8}R^{b9}, or *³—C≡CR^{b10}, *³ represent a bonding site to L¹,
R^{b1} represents a hydrogen atom or a substituent, R^{b2} represents a substituent, provided that R^{b1} and R^{b2} do not include a structure represented by a formula (NX1) below, R^{b1} and R^{b2} may be bonded together to form a ring,
R^{b3} to R^{b8} each independently represent a hydrogen atom or a substituent, and R^{b9} and R^{b10} each independently represent a substituent.

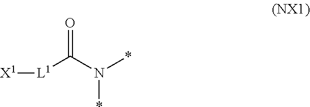

In the formula (NX1), L¹ and X¹ respectively have the same meanings as L¹ and X¹ in the formula (N1), and * represent a bonding site.

The compound (B), which has a molecular weight of 400 or more, is less likely to volatilize during heating, to thereby inferentially achieve reduction in the PEB temperature dependence of the composition of the present invention. However, the present invention is not limited at all by such an inferred mechanism.

The molecular weight of the compound (B) is 400 or more, and preferably 450 or more. The molecular weight of the compound (B) is preferably 1500 or less, more preferably 1000 or less, and particularly preferably 800 or less.

The compound (B) is preferably a compound that generates a base upon irradiation with an actinic ray or a radiation (photobase generator).

The compound (B) is preferably a compound that generates a primary amine, a secondary amine, or a tertiary amine upon irradiation with an actinic ray or a radiation, and more preferably a compound that generates a tertiary amine.

The compound (B) is preferably a compound different from the above-described resin (A).

In the formula (N1), L¹ represents a single bond, *¹—OCR^{b3}R^{b4}—*² or *¹—CR^{b5}R^{b6}—*², *¹ represent a bonding site to C(═O), *² represent a bonding site to X¹, and
R^{b3}, R^{b4}, R^{b5}, and R^{b6} each independently represent a hydrogen atom or a substituent. R^{b3} and R^{b4} may be the same or different. R^{b5} and R^{b6} may be the same or different.

The substituent represented by R^{b3} is not particularly limited, and examples include the above-described substituents T; the substituent is preferably an organic group, and more preferably an organic group having 1 to 30 carbon atoms. The substituent represented by R^{b3} is preferably an alkyl group, an alkoxy group, an alkylthio group, a cycloalkyl group, a cycloalkyloxy group, a cycloalkylthio group, an aryl group, a heteroaryl group, an aryloxy group, an arylthio group, or an acyl group, and more preferably an alkyl group, an alkoxy group, an alkylthio group, a cycloalkyl group, a cycloalkyloxy group, a cycloalkylthio group, an aryl group, a heteroaryl group, an aryloxy group, or an arylthio group. These groups may further have one or more substituents. In such a case of having an additional substituent, examples of the substituent include fluoroalkyl groups and fluoroalkyloxy groups.

The alkyl group represented by R^{b3} may be linear or branched. The number of carbon atoms in the alkyl group is not particularly limited, but is, for example, preferably 1 to 20, more preferably 1 to 15, and still more preferably 1 to 10. The alkyl group may have a substituent. The alkyl group may include an ether bond (—O—) in the chain. Examples of the alkyl group include a methyl group, an ethyl group, a propyl group, an isopropyl group, an n-butyl group, an isobutyl group, a sec-butyl group, a t-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an eicosyl group.

The descriptions, specific examples, and preferred ranges of the alkyl groups included in the alkoxy group and alkylthio group represented by R^{b3} are respectively the same as those described above for the alkyl group represented by R^{b3}

The cycloalkyl group represented by R^{b3} may be monocyclic or polycyclic. The number of carbon atoms of the cycloalkyl group is not particularly limited, but is, for example, preferably 3 to 20, more preferably 4 to 15, and still more preferably 5 to 10. The cycloalkyl group may have a substituent. In the cycloalkyl group, for example, one of the methylene groups constituting the ring may be replaced by a heteroatom such as an oxygen atom, a group having a heteroatom such as a carbonyl group, or a vinylidene group. In the cycloalkyl group, one or more of the ethylene groups constituting the cycloalkane ring may be replaced by a vinylene group. Examples of the cycloalkyl group include a cyclopentyl group, a cyclohexyl group, a norbornyl group, a tetracyclodecanyl group, a tetracyclododecanyl group, and an adamantyl group.

The descriptions, specific examples, and preferred ranges of the cycloalkyl group included in the cycloalkyloxy group and cycloalkylthio group represented by R^{b3} are respectively the same as those described above for the cycloalkyl group represented by R^{b3}

The number of carbon atoms of the aryl group represented by R^{b3} is not particularly limited, but is, for example, preferably 6 to 30, more preferably 6 to 20, and still more preferably 6 to 15. The aryl group may have a substituent. The aryl group may be a monocyclic group or may be a polycyclic group.

The aryl group may be a group formed by removing one hydrogen atom from a fused ring compound (for example, indane or indene) having a structure where an aromatic hydrocarbon (for example, a monocyclic or polycyclic aromatic hydrocarbon having 6 to 15 carbon atoms such as benzene or naphthalene) is fused with at least one selected from the group consisting of a cycloalkane (for example, a monocyclic or polycyclic cycloalkane having 3 to 12 carbon atoms such as cyclopentane or cyclohexane; the cycloalkane may have, as a group constituting the ring, one or more carbonyl groups), a cycloalkene (for example, a monocyclic or polycyclic cycloalkene having 3 to 12 carbon atoms such as cyclohexene; the cycloalkene may have, as a group constituting the ring, one or more carbonyl groups), and a non-aromatic heterocyclic compound (for example, a five-membered non-aromatic heterocyclic compound such as pyrrolidine, pyrroline, 2-oxazolidone, tetrahydrofuran, or tetrahydrothiophene, or a six-membered non-aromatic heterocyclic compound such as morpholine, piperidine, piperazine, or tetrahydropyran; the non-aromatic heterocyclic compound may have, as a group constituting the ring, at least one selected from the group consisting of a carbonyl group, a sulfonyl group, and an ethylene group).

Examples of the aryl group include a phenyl group, a naphthyl group, an anthryl group, a fluorenyl group, and a phenanthryl group.

The descriptions, specific examples, and preferred ranges of the aryl groups included in the aryloxy group and arylthio group represented by R^{b3} are respectively the same as those described above for the aryl group represented by R^{b3}

The heteroaryl group (aromatic heterocyclic group) represented by R^{b3} preferably includes, as a ring member, at least one heteroatom selected from the group consisting of a nitrogen atom, an oxygen atom, and a sulfur atom. The number of ring members of the heteroaryl group is not particularly limited, but is preferably 3 to 30, more preferably 4 to 20, and still more preferably 5 to 15. The number of carbon atoms of the heteroaryl group is not particularly limited, but is preferably 1 to 28, more preferably 2 to 18, and still more preferably 2 to 13. The heteroaryl group may have a substituent. The heteroaryl group may be a monocyclic group or may be a polycyclic group.

Examples of the heteroaryl group include groups formed by removing one hydrogen atom from five-membered aromatic heterocyclic compounds such as pyrrole, imidazole, pyrazole, oxazole, isoxazole, thiazole, isothiazole, triazole, thiophene, furan, oxadiazole, thiadiazole, dioxazole, dithiazole, and tetrazole, and groups formed by removing one hydrogen atom from six-membered aromatic heterocyclic compounds such as pyridine, pyrazine, pyrimidine, pyridazine, triazine, thiazine, and oxazine.

The heteroaryl group may also be a group formed by removing one hydrogen atom from a fused cyclic compound having a structure in which such a five-membered aromatic heterocyclic compound or such a six-membered aromatic heterocyclic compound is fused with at least one selected from the group consisting of the above-described five-membered aromatic heterocyclic compounds, the above-described six-membered aromatic heterocyclic compounds, aromatic hydrocarbons (monocyclic or polycyclic aromatic hydrocarbons having 6 to 15 carbon atoms such as benzene and naphthalene), cycloalkanes (monocyclic or polycyclic cycloalkanes having 3 to 12 carbon atoms such as cyclopentane and cyclohexane), cycloalkenes (monocyclic or polycyclic cycloalkenes having 3 to 12 carbon atoms such as cyclohexene), non-aromatic heterocyclic compounds (for example, five-membered non-aromatic heterocyclic compounds such as pyrrolidine, pyrroline, 2-oxazolidone, tetrahydrofuran, and tetrahydrothiophene, and six-membered non-aromatic heterocyclic compounds such as morpholine, piperidine, piperazine, and tetrahydropyran) (for example, indole, isoindole, benzimidazole, benzotriazole, purine, quinazoline, quinoxaline, cinnoline, pteridine, acridine, carbazole, benzofuran, benzothiophene, quinoline, and isoquinoline).

The acyl group represented by R^{b3} is represented by R_{C1}C(═O)—, and R^{C1} preferably represents an organic group. The organic group represented by Rei is preferably an alkyl group, a cycloalkyl group, an aryl group, or a heteroaryl group. The descriptions, specific examples, and preferred ranges of the alkyl group, cycloalkyl group, aryl group, and heteroaryl group represented by R^{C1} are respectively the same as those described above for R^{b3}.

The descriptions, specific examples, and preferred ranges of the substituents represented by R^{b4}, R^{b5}, and R^{b6} are respectively the same as those described above for R^{b3}

R^{b3}, R^{b4}, R^{b5}, and R^{b6} preferably each independently represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group.

In the formula (N1), X¹ represents an aryl group, a heteroaryl group, *³—CR^{b7}═CR^{b8}R^{b9}, or *³—C≡CR^{b10}, and *³ represent a bonding site to L¹. R^{b7} and R^{b8} each independently represent a hydrogen atom or a substituent. R^{b9} and R^{b10} each independently represent a substituent. R^{b7}, R^{b8}, and R^{b9} may be the same or different.

The descriptions, specific examples, and preferred ranges of the aryl group and heteroaryl group represented by X¹ are respectively the same as those described above for R^{b3}.

The descriptions, specific examples, and preferred ranges of the substituents represented by R^{b7}, R^{b8}, R^{b9}, and R^{b10} are respectively the same as those described above for R^{b3}

R^{b7} and R^{b8} each independently preferably represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group.

R^{b9} and R^{b10} each independently preferably represent an alkyl group, an alkoxy group, an alkylthio group, a cycloalkyl group, a cycloalkyloxy group, a cycloalkylthio group, an aryl group, a heteroaryl group, an aryloxy group, or an arylthio group, and more preferably represent an aryl group or a heteroaryl group.

In the formula (N1), R^{b1} represents a hydrogen atom or a substituent.

The substituent represented by R^{b1} is not particularly limited, examples thereof include the above-described Substituents T; the substituent is preferably an organic group, and more preferably an alkyl group, an alkoxy group, an alkylthio group, a cycloalkyl group, a cycloalkyloxy group, a cycloalkylthio group, an aryl group, a heteroaryl group, an aryloxy group, an arylthio group, an acyl group, or a group represented by a formula (GN1) below.

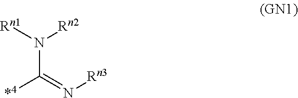

In the formula (GN1), Rⁿ¹ to Rⁿ³ each independently represent a hydrogen atom or a substituent, provided that at least one of Rⁿ¹ to Rⁿ³ represents a substituent, at least two of Rⁿ¹ to Rⁿ³ may be bonded to form a ring, and *⁴ represents a bonding site to the nitrogen atom.

The descriptions, specific examples, and preferred ranges of the alkyl group, alkoxy group, alkylthio group, cycloalkyl group, cycloalkyloxy group, cycloalkylthio group, aryl group, heteroaryl group, aryloxy group, arylthio group, and acyl group represented by R^{b1} are respectively the same as those described above for R^{b3}.

In the formula (GN1), Rⁿ¹ to Rⁿ³ each independently represent a hydrogen atom or a substituent.

The substituent represented by Rⁿ¹ is not particularly limited, and examples thereof include the above-described Substituents T; the substituent is preferably an organic group, more preferably an alkyl group, an aryl group, a heteroaryl group, an alkoxycarbonyl group, a cycloalkyloxycarbonyl group, an aryloxycarbonyl group, an alkylsulfonyl group, or an arylsulfonyl group.

The alkyl group represented by Rⁿ¹ and the alkyl group included in the substituent represented by Rⁿ¹ (for example, the alkyl group included in the alkoxy group, alkylcarbonyloxy group, or alkoxycarbonyl group represented by Rⁿ¹) may be linear or branched. The number of carbon atoms of the alkyl group is not particularly limited, but is, for example, preferably 1 to 20, more preferably 1 to 15, and still more preferably 1 to 10. The alkyl group may have a substituent. The alkyl group may include an ether bond (—O—) in the chain. Examples of the alkyl group include a methyl group, an ethyl group, a propyl group, an isopropyl group, an n-butyl group, an isobutyl group, a sec-butyl group, a t-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an eicosyl group.

The descriptions, specific examples, and preferred ranges of the substituents represented by Rⁿ² and Rⁿ³ are respectively the same as those described above for Rⁿ¹.

At least two of Rⁿ¹ to Rⁿ³ may be bonded together to form a ring. The ring formed by bonding together at least two of Rⁿ¹ to Rⁿ³ (also referred to as “ring X”) may be a non-aromatic nitrogen-containing heterocycle or an aromatic nitrogen-containing heterocycle.

The case where the ring X is a non-aromatic nitrogen-containing heterocycle will be described.

The non-aromatic nitrogen-containing heterocycle may be saturated or unsaturated.

The number of ring members of the non-aromatic nitrogen-containing heterocycle is not particularly limited, but is preferably 3 to 30, more preferably 3 to 20, and still more preferably 3 to 15. The number of carbon atoms of the non-aromatic nitrogen-containing heterocycle is not particularly limited, but is preferably 1 to 28, more preferably 2 to 18, and still more preferably 2 to 13.

The non-aromatic nitrogen-containing heterocycle may be monocyclic or may be polycyclic.

Examples of the non-aromatic nitrogen-containing heterocycle include five-membered non-aromatic nitrogen-containing heterocycles such as pyrrolidine, pyrroline, and 2-oxazolidone, and six-membered non-aromatic nitrogen-containing heterocycles such as morpholine, piperidine, and piperazine.

Alternatively, the non-aromatic nitrogen-containing heterocycle may be a fused ring having a structure in which such a five-membered non-aromatic nitrogen-containing heterocycle or such a six-membered non-aromatic nitrogen-containing heterocycle is fused with at least one selected from the group consisting of cycloalkanes (monocyclic or polycyclic cycloalkanes having 3 to 12 carbon atoms such as cyclopentane and cyclohexane), cycloalkenes (monocyclic or polycyclic cycloalkenes having 3 to 12 carbon atoms such as cyclohexene), the above-described five-membered non-aromatic nitrogen-containing heterocycles, and the above-described six-membered non-aromatic nitrogen-containing heterocycles.

The non-aromatic nitrogen-containing heterocycle may have a substituent.

One or more methylene groups constituting the ring of the non-aromatic nitrogen-containing heterocycle may be replaced with at least one selected from the group consisting of a carbonyl bond, an ester bond, an amide bond, and a sulfone bond (—SO₂—).

When the bond between adjacent atoms included in the non-aromatic nitrogen-containing heterocycle is a single bond, the single bond may be replaced with a multiple bond (for example, a double bond).

The case where the ring X is an aromatic nitrogen-containing heterocycle will be described.

The number of ring members of the aromatic nitrogen-containing heterocycle is not particularly limited, but is preferably 3 to 30, and more preferably 4 to 20. The number of carbon atoms of the aromatic nitrogen-containing heterocycle is not particularly limited, but is preferably 2 to 20, and more preferably 3 to 15.

The aromatic nitrogen-containing heterocycle may be monocyclic or may be polycyclic.

Examples of the aromatic nitrogen-containing heterocycle include five-membered aromatic nitrogen-containing heterocycles such as pyrrole, imidazole, pyrazole, oxazole, isoxazole, thiazole, isothiazole, triazole, oxadiazole, thiadiazole, dioxazole, dithiazole, and tetrazole, and six-membered aromatic nitrogen-containing heterocycles such as pyridine, pyrazine, pyrimidine, pyridazine, triazine, thiazine, and oxazine.

Alternatively, the aromatic nitrogen-containing heterocycle may be a fused ring having a structure in which such a five-membered aromatic nitrogen-containing heterocycle or such a six-membered aromatic nitrogen-containing heterocycle is fused with at least one selected from the group consisting of the above-described five-membered aromatic nitrogen-containing heterocycles, the above-described six-membered aromatic nitrogen-containing heterocycles, aromatic hydrocarbons (monocyclic or polycyclic aromatic hydrocarbons having 6 to 15 carbon atoms such as benzene and naphthalene), cycloalkanes (monocyclic or polycyclic cycloalkanes having 3 to 12 carbon atoms such as cyclopentane and cyclohexane), cycloalkenes (monocyclic or polycyclic cycloalkenes having 3 to 12 carbon atoms such as cyclohexene), and non-aromatic nitrogen-containing heterocycles (the above-described five-membered non-aromatic nitrogen-containing heterocycles and the above-described six-membered non-aromatic nitrogen-containing heterocycles) (for example, indole, isoindole, benzimidazole, benzotriazole, purine, quinazoline, quinoxaline, cinnoline, pteridine, acridine, carbazole, quinoline, and isoquinoline).

The aromatic nitrogen-containing heterocycle may have a substituent.

R^{b1} preferably represents a hydrogen atom, an alkyl group, a cycloalkyl group, an aryl group, or a group represented by the formula (GN1).

In the formula (N1), R^{b2} represents a substituent.

The descriptions, specific examples, and preferred ranges of the substituent represented by R^{b2} are respectively the same as those described above for R^{b1}.

R^{b2} preferably represents an alkyl group, a cycloalkyl group, an aryl group, or a group represented by the formula (GN1).

In a preferred embodiment of the compound (B), in the formula (N1), R^{b1} represents a hydrogen atom, an alkyl group, a cycloalkyl group, an aryl group, or a group represented by the formula (GN1), and R^{b2} represents an alkyl group, a cycloalkyl group, an aryl group, or a group represented by the formula (GN1).

R^{b1} and R^{b2} in the formula (N1) may be bonded together to form a ring. The descriptions, specific examples, and preferred ranges of the ring formed by bonding together R^{b1} and R^{b2} are the same as those described above for the ring X. The ring formed by bonding together R^{b1} and R^{b2} is preferably a non-aromatic nitrogen-containing heterocycle.

However, R^{b1} and R^{b2} do not include the structure represented by the formula (NX1).

L¹ and X¹ in the formula (NX1) respectively have the same meanings as L¹ and X¹ in the formula (N1) described above, and the descriptions and specific examples of L¹ and X¹ are also the same.

Preferably, when L¹ in the formula (N1) represents a single bond or *¹—OCR^{b3}R^{b4}—*², X¹ in the formula (N1) represents an aryl group, a heteroaryl group, or *³—CR^{b7}═CR⁸R^{b9}, or
when L¹ in the formula (N1) represents *¹—CR^{b5}R^{b6}—*², X¹ in the formula (N1) represents an aryl group or a heteroaryl group.

The compound (B) is preferably represented by a formula (N2) below.

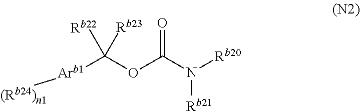

In the formula (N2),
R^{b20} represents a hydrogen atom or a substituent, R^{b21} represents a substituent, provided that R^{b20} and R^{b21} do not include the structure represented by the formula (NX1), R^{b20} and R^{b21} may be bonded together to form a ring,
R^{b22} and R^{b23} each independently represent a hydrogen atom or a substituent, R^{b24} represents a substituent,
Ar^{b1} represents an aromatic ring group having 4 to 20 ring members,
n1 represents an integer of 0 to 12; and when n1 represents an integer of 2 or more, a plurality of R^{b24} may be the same or different, and the plurality of R^{b24} may be bonded together to form a ring.

The descriptions, specific examples, and preferred ranges of R^{b20} in the formula (N2) are the same as those described above for R^{b1} in the formula (N1).

The descriptions, specific examples, and preferred ranges of R^{b21} in the formula (N2) are the same as those described above for R^{b2} in the formula (N1).

R^{b20} and R^{b21} may be bonded together to form a ring. The descriptions, specific examples, and preferred ranges of the ring formed by bonding together R^{b20} and R^{b21} are the same as those described above for the ring X. The ring formed by bonding together R^{b20} and R^{b21} is preferably a non-aromatic nitrogen-containing heterocycle.

When the compound (B) is represented by the formula (N2), in a preferred embodiment,

R^{b20} and R^{b21} in the formula (N2) each independently represent an alkyl group or a cycloalkyl group, and R^{b20} and R^{b21} may be bonded together to form a ring.

However, R^{b20} and R^{b21} do not include the above-described structure represented by the formula (NX1).

In the formula (N2), R^{b22} and R^{b23} each independently represent a hydrogen atom or a substituent. R^{b22} and R^{b23} may be the same or different.

The descriptions, specific examples, and preferred ranges of the substituents represented by R^{b22} and R^{b23} in the formula (N2) are respectively the same as those described above for R^{b3} in the formula (N1).

In the formula (N2), R^{b22} and R^{b23} each independently preferably represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group.

In the formula (N2), Ar^{b1} represents an aromatic ring group having 4 to 20 ring members, and preferably represents an aromatic ring group having 4 to 13 ring members.

The aromatic ring group represented by Ar^{b1} may be an aromatic carbocyclic group or an aromatic heterocyclic group.

The aromatic carbocyclic group may be a monocyclic group or may be a polycyclic group.

The aromatic carbocyclic group is preferably a group formed by removing one or more hydrogen atoms from an aromatic hydrocarbon (for example, a monocyclic or polycyclic aromatic hydrocarbon having 6 to 20 carbon atoms (preferably 6 to 13 carbon atoms) such as benzene, naphthalene, or fluorene).

Alternatively, the aromatic carbocyclic group may be a group formed by removing one or more hydrogen atoms from a fused cyclic compound having a structure in which an aromatic hydrocarbon is fused with at least one selected from the group consisting of cycloalkanes (monocyclic or polycyclic cycloalkanes having 3 to 12 carbon atoms such as cyclopentane and cyclohexane), cycloalkenes (monocyclic or polycyclic cycloalkenes having 3 to 12 carbon atoms such as cyclohexene), non-aromatic heterocyclic compounds (five-membered non-aromatic heterocyclic compounds such as pyrrolidine, pyrroline, 2-oxazolidone, tetrahydrofuran, and tetrahydrothiophene, and six-membered non-aromatic heterocyclic compounds such as morpholine, piperidine, piperazine, and tetrahydropyran).

The aromatic heterocyclic group preferably includes, as a ring member, at least one heteroatom selected from the group consisting of a nitrogen atom, an oxygen atom, and a sulfur atom.

The aromatic heterocyclic group may be a monocyclic group or may be a polycyclic group.

The aromatic heterocyclic group may be, for example, a group formed by removing one or more hydrogen atoms from a five-membered aromatic heterocyclic compound such as pyrrole, imidazole, pyrazole, oxazole, isoxazole, thiazole, isothiazole, triazole, thiophene, furan, oxadiazole, thiadiazole, dioxazole, dithiazole, or tetrazole or a six-membered aromatic heterocyclic compound such as pyridine, pyrazine, pyrimidine, pyridazine, triazine, thiazine, or oxazine.

Alternatively, the aromatic heterocyclic group may be a group formed by removing one or more hydrogen atoms from a fused cyclic compound having a structure in which such a five-membered aromatic heterocyclic compound or such a six-membered aromatic heterocyclic compound is fused with at least one selected from the group consisting of the above-described five-membered aromatic heterocyclic compounds, the above-described six-membered aromatic heterocyclic compounds, aromatic hydrocarbons (monocyclic or polycyclic aromatic hydrocarbons having 6 to 15 carbon atoms such as benzene and naphthalene), cycloalkanes (monocyclic or polycyclic cycloalkanes having 3 to 12 carbon atoms such as cyclopentane and cyclohexane), cycloalkenes (monocyclic or polycyclic cycloalkenes having 3 to 12 carbon atoms such as cyclohexene), non-aromatic heterocyclic compounds (the above-described five-membered non-aromatic heterocyclic compounds and the above-described six-membered non-aromatic heterocyclic compounds) (for example, indole, isoindole, benzimidazole, benzotriazole, purine, quinazoline, quinoxaline, cinnoline, pteridine, acridine, carbazole, benzofuran, benzothiophene, quinoline, and isoquinoline).

In the formula (N2), R^{b24} represents a substituent.

The substituent represented by R^{b24} in the formula (N2) is not particularly limited, and examples thereof include the above-described Substituents T; the substituent is preferably a hydroxy group, an alkyl group, an aryl group, a cycloalkyl group, an alkoxy group, an aryloxy group, a cycloalkyloxy group, an acyl group, an alkoxycarbonyl group, an aryloxycarbonyl group, a cycloalkyloxycarbonyl group, a acyloxy group, a halogen atom, a cyano group, a nitro group, an alkylsulfonyl group, an arylsulfonyl group, or the like. When the substituent represented by R^{b24} is an organic group, the number of carbon atoms of the organic group is not particularly limited, but is preferably 1 to 10.

In the formula (N2), n1 represents an integer of 0 to 12, and preferably represents an integer of 0 to 8. However, the upper limit of n1 depends on the aromatic ring group represented by Ar^{b1}. For example, when the aromatic ring group represented by Ar^{b1} is a benzene ring group, the upper limit of n1 is 5.

The compound (B) is also preferably represented by the following formula (N3).

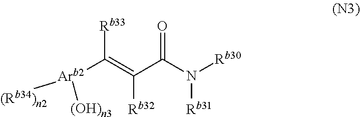

In the formula (N3),
R^{b30} represents a hydrogen atom or a substituent, R^{b31} represents a substituent, provided that R^{b30} and R^{b31} do not include the structure represented by the formula (NX1), R^{b30} and R^{b31} may be bonded together to form a ring,
R^{b32} and R^{b33} each independently represent a hydrogen atom or a substituent, R^{b34} represents a substituent other than a hydroxy group,
Ar^{b2} represents an aromatic ring group having 4 to 20 ring members,
n2 represents an integer of 0 to 11; when n2 represents an integer of 2 or more, a plurality of R^{b34} may be the same or different, and the plurality of R^{b34} may be bonded together to form a ring; and
n3 represents 1 or 2.

The descriptions, specific examples, and preferred ranges of R^{b30} in the formula (N3) are the same as those described above for R^{b1} in the formula (N1).

The descriptions, specific examples, and preferred ranges of R^{b31} in the formula (N3) are the same as those described above for R^{b2} in the formula (N1).

R^{b30} and R^{b31} may be bonded together to form a ring. The descriptions, specific examples, and preferred ranges of the ring formed by bonding together R^{b30} and R^{b31} are the same as those described above for the ring X. The ring formed by bonding together R^{b30} and R^{b31} is preferably a non-aromatic nitrogen-containing heterocycle.

When the compound (B) is represented by the formula (N3), in a preferred embodiment, R^{b30} and R^{b31} in the formula (N3) each independently represent an alkyl group or a cycloalkyl group, and R^{b30} and R^{b31} may be bonded together to form a ring.

However, R^{b30} and R^{b31} do not include the above-described structure represented by the formula (NX1).

In the formula (N3), R^{b32} and R^{b33} each independently represent a hydrogen atom or a substituent. R^{b32} and R^{b33} may be the same or different.

The descriptions, specific examples, and preferred ranges of the substituents represented by R^{b32} and R^{b33} in the formula (N3) are respectively the same as those described above for R^{b3} in the formula (N1).

In the formula (N3), R^{b32} and R^{b33} each independently preferably represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group, and more preferably a hydrogen atom or an alkyl group.

In the formula (N3), Ar^{b2} represents an aromatic ring group having 4 to 20 ring members. The descriptions, specific examples, and preferred ranges of Ar^{b2} are the same as those described above for Ar^{b1} in the formula (N2).

In the formula (N3), R^{b34} represents a substituent other than a hydroxy group. The substituent represented by R^{b34} is not particularly limited as long as it is not a hydroxy group, and examples thereof include the above-described Substituents T (excluding a hydroxy group); the substituent is preferably an alkyl group, an aryl group, a cycloalkyl group, an alkoxy group, an aryloxy group, a cycloalkyloxy group, an acyl group, an alkoxycarbonyl group, an aryloxycarbonyl group, a cycloalkyloxycarbonyl group, an acyloxy group, a halogen atom, a cyano group, a nitro group, an alkylsulfonyl group, an arylsulfonyl group, or the like. When the substituent represented by R^{b34} is an organic group, the number of carbon atoms of the organic group is not particularly limited, but is preferably 1 to 10.

In the formula (N3), n2 represents an integer of 0 to 11, and preferably represents an integer of 0 to 6. However, the upper limit of n2 depends on the aromatic ring group represented by Ar^{b2}. For example, when the aromatic ring group represented by Ar^{b2} is a benzene ring group, the upper limit of n2 is 4.

In the formula (N3), n3 represents 1 or 2, and preferably represents 1.

The compound (B) is also preferably represented by the following formula (N4).

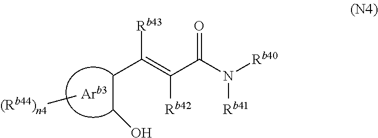

In the formula (N4),
R^{b40} and R^{b41} each independently represent an alkyl group or a cycloalkyl group, provided that R^{b40} and R^{b41} do not include the above-described structure represented by the formula (NX1), R^{b40} and R^{b41} may be bonded together to form a ring,
R^{b42} and R^{b43} each independently represent a hydrogen atom or a substituent, R^{b44} represents a substituent other than a hydroxy group,
Ar^{b3} represents an aromatic ring group having 4 to 20 ring members,
n4 represents an integer of 0 to 11, and when n4 represents an integer of 2 or more, a plurality of R^{b44} may be the same or different, and the plurality of R^{b44} may be bonded together to form a ring.

The OH bonded to the aromatic ring group represented by Ar^{b3} in the formula (N4) is at the ortho position relative to the group represented by the following formula (N4-1) in the formula (N4).

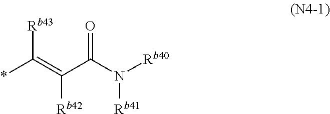

R^{b40} to R^{b43} in the formula (N4-1) respectively have the same meanings as R^{b40} to R^{b43} in the formula (N4). * represents a bonding site to Ar^{b3} in the formula (N4).

The descriptions, specific examples, and preferred ranges of the alkyl group and cycloalkyl group represented by R^{b40} and R^{b41} in the formula (N4) are respectively the same as those described above for R^{b3} in the formula (N1).

R^{b40} and R^{b41} may be bonded together to form a ring. The descriptions, specific examples, and preferred ranges of the ring formed by bonding together R^{b40} and R^{b41} are the same as those described above for the ring X. The ring formed by bonding together R^{b40} and R^{b41} is preferably a non-aromatic nitrogen-containing heterocycle.

However, R^{b40} and R^{b41} do not include the above-described structure represented by the formula (NX1).

In the formula (N4), R^{b42} and R^{b43} each independently represent a hydrogen atom or a substituent. R^{b42} and R^{b43} may be the same or different.

The descriptions, specific examples, and preferred ranges of the substituents represented by R^{b42} and R^{b43} in the formula (N4) are respectively the same as those described above for R^{b3} in the formula (N1).

In the formula (N4), R^{b42} and R^{b43} each independently preferably represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group, and more preferably represents a hydrogen atom or an alkyl group.

In the formula (N4), Ar^{b3} represents an aromatic ring group having 4 to 20 ring members. The descriptions, specific examples, and preferred ranges of Ar^{b3} are the same as those described above for Ar^{b1} in the formula (N2).

In the formula (N4), R^{b44} represents a substituent. The descriptions, specific examples, and preferred ranges of R^{b44} are the same as those described above for R^{b34} in the formula (N3).

In the formula (N4), n4 represents an integer of 0 to 11, and preferably represents an integer of 0 to 6. However, the upper limit of n4 depends on the aromatic ring group represented by Ar^{b3}. For example, when the aromatic ring group represented by Ar^{b3} is a benzene ring group, the upper limit of n4 is 4.

Specific examples of the compound (B) will be described below together with their molecular weights. However, the present invention is not limited to the following specific examples. Me represent a methyl group.

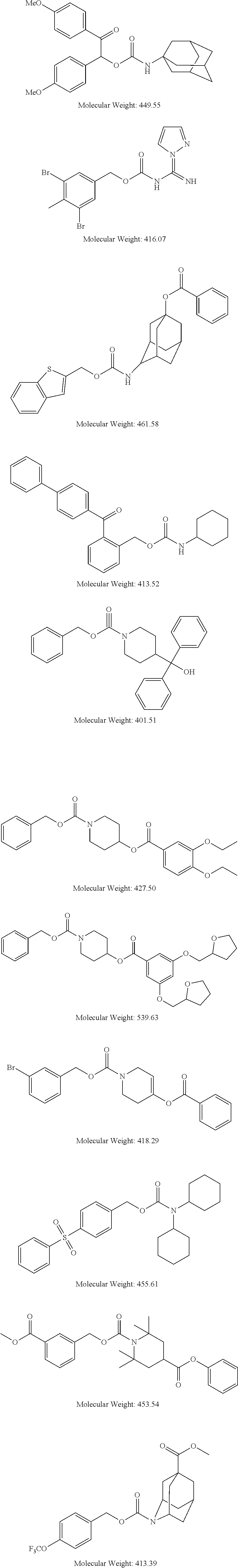

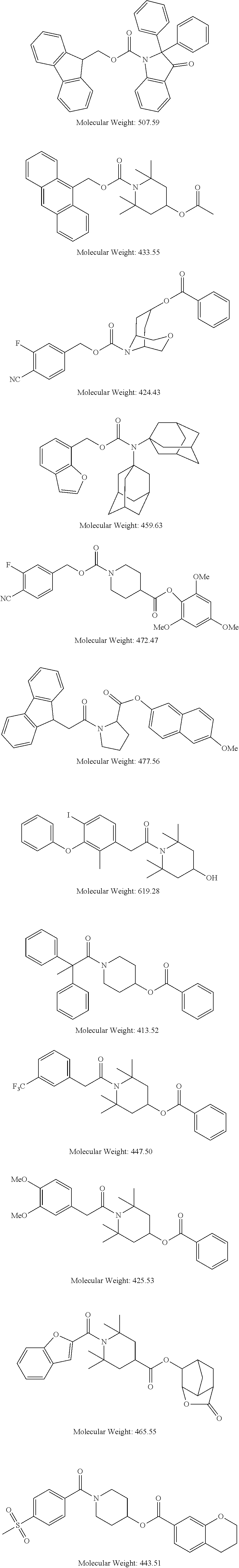

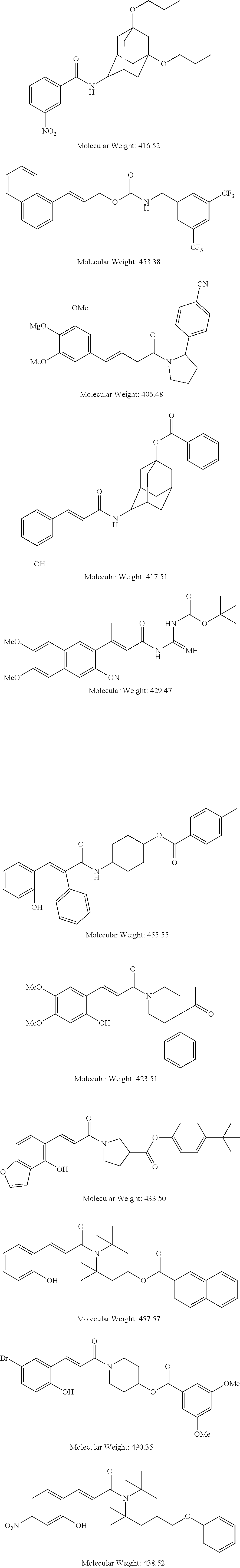

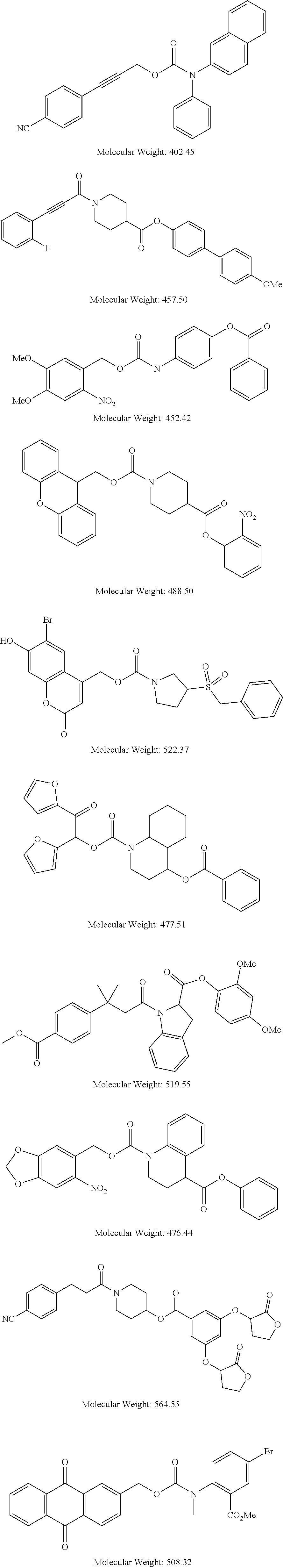

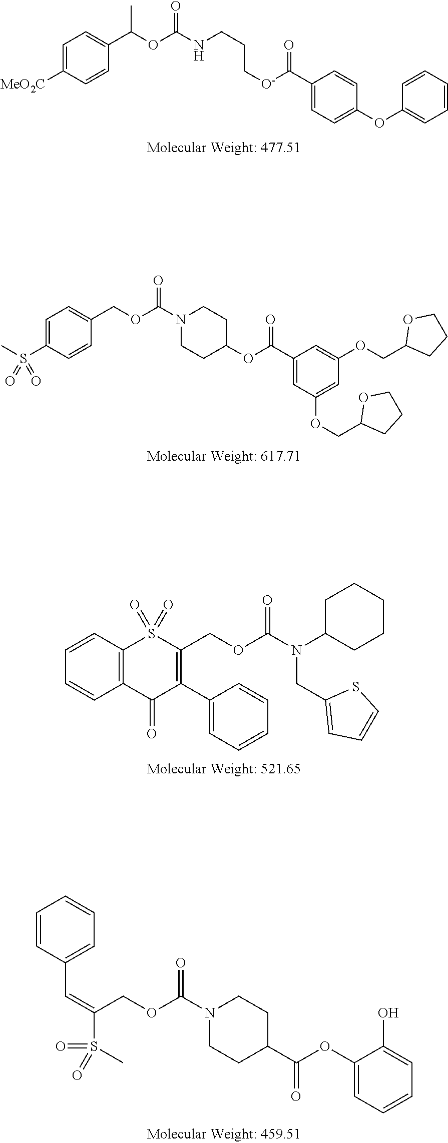

The compound (B) can be synthesized on the basis of a publicly known method.

The content of the compound (B) in the composition of the present invention relative to the total solid content of the composition of the present invention is preferably 1.0 mass % or more, more preferably 2.0 mass % or more, and still more preferably 3.0 mass % or more. The content of the compound (B) relative to the total solid content of the composition of the present invention is preferably 30.0 mass % or less, more preferably 25.0 mass % or less, and still more preferably 20.0 mass % or less.

Such compounds (B) may be used alone or may be used in combination of two or more thereof. When two or more thereof are used, the total content thereof is preferably within such a preferred content range.

Compound (C) that Generates Acid Upon Irradiation with Actinic Ray or Radiation

The composition of the present invention preferably further contains a compound (C) that generates an acid upon irradiation with an actinic ray or a radiation (also referred to as “photoacid generator”).

The photoacid generator is preferably a compound different from the compound (B).

The photoacid generator is preferably a compound that is irradiated with an actinic ray or a radiation to generate an acid having a pKa of less than 0.

The acid generated from the photoacid generator upon irradiation with an actinic ray or a radiation preferably has a pKa of −0.1 or less, and more preferably −0.2 or less. The acid generated from the photoacid generator upon irradiation with an actinic ray or a radiation preferably has a pKa of −1.5 or more, and more preferably −1.0 or more.

The photoacid generator may have the form of a low-molecular-weight compound, or may have the form of being incorporated into a portion of a polymer. Alternatively, the form of a low-molecular-weight compound and the form of being incorporated into a portion of a polymer may be used in combination.

When the photoacid generator has the form of a low-molecular-weight compound, the molecular weight of the photoacid generator is not particularly limited, but is preferably 100 to 3000, more preferably 150 to 2500, and still more preferably 200 to 2000.

When the photoacid generator has the form of being incorporated into a portion of a polymer, it may be incorporated into a portion of the resin (A) or may be incorporated into a resin different from the resin (A).

The photoacid generator preferably has the form of a low-molecular-weight compound.

The photoacid generator may be, for example, a compound (onium salt) represented by “M⁺X⁻”, and is preferably a compound that generates an organic acid upon exposure. Examples of the organic acid include sulfonic acids (such as aliphatic sulfonic acids, aromatic sulfonic acids, and a camphorsulfonic acid), carboxylic acids (such as aliphatic carboxylic acids, aromatic carboxylic acids, and aralkylcarboxylic acids), carbonylsulfonylimidic acid, bis(alkylsulfonyl)imidic acids, and tris(alkylsulfonyl)methide acids.

In the compound represented by “M⁺ X⁻”, M⁺ represents an organic cation. The organic cation is not particularly limited. For the valence, the organic cation may be mono-, di-, or higher valent.

In particular, the organic cation is preferably a cation represented by a formula (ZaI) (hereafter, also referred to as “cation (ZaI)”) or a cation represented by a formula (ZaII) (hereafter, also referred to as “cation (ZaII)”).

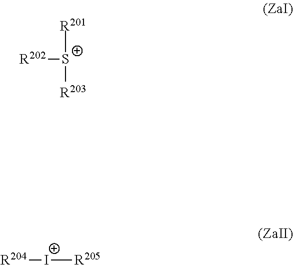

In the formula (ZaI), R²⁰¹, R²⁰², and R²⁰³ each independently represent an organic group.

For R²⁰¹, R²⁰², and R²⁰³, the organic group preferably has 1 to 30 carbon atoms, and more preferably 1 to 20 carbon atoms. Of R²⁰¹ to R²⁰³, two may be bonded together to form a ring structure and the ring may include an oxygen atom, a sulfur atom, an ester group, an amide group, or a carbonyl group. Examples of the group formed by bonding together two of R²⁰¹ to R²⁰³ include alkylene groups (such as a butylene group and a pentylene group), and —CH₂—CH₂—O—CH₂—CH₂—.

Preferred examples of the organic cation in the formula (ZaI) include a cation (ZaI-1), a cation (ZaI-2), a cation (ZaI-3b), and a cation (ZaI-4b) described later.

First, the cation (ZaI-1) will be described.

The cation (ZaI-1) is an aryl sulfonium cation represented by the above-described formula (ZaI) where at least one of R²⁰¹ to R²⁰³ is an aryl group.

In the aryl sulfonium cation, all of R²⁰¹ to R²⁰³ may be aryl groups, or a part of R²⁰¹ to R²⁰³ may be an aryl group and the other may be an alkyl group or a cycloalkyl group.

Alternatively, one of R²⁰¹ to R²⁰³ may be an aryl group and the other two of R²⁰¹ to R²⁰³ may be bonded together to form a ring structure in which the ring may include an oxygen atom, a sulfur atom, an ester group, an amide group, or a carbonyl group. Examples of the group formed by bonding together two of R²⁰¹ to R²⁰³ include alkylene groups in which one or more methylene groups may be substituted with an oxygen atom, a sulfur atom, an ester group, an amide group, and/or a carbonyl group (such as a butylene group, a pentylene group, and —CH₂—CH₂—O—CH₂—CH₂—).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

The aryl group included in the aryl sulfonium cation is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the aryl sulfonium cation has two or more aryl groups, the two or more aryl groups may be the same or different.

The alkyl group or cycloalkyl group that the aryl sulfonium cation has as needed is preferably a linear alkyl group having 1 to 15 carbon atoms, a branched alkyl group having 3 to 15 carbon atoms, or a cycloalkyl group having 3 to 15 carbon atoms, and more preferably a methyl group, an ethyl group, a propyl group, an n-butyl group, a sec-butyl group, a t-butyl group, a cyclopropyl group, a cyclobutyl group, or a cyclohexyl group.

For R²⁰¹ to R²⁰³, a substituent that the aryl group, the alkyl group, and the cycloalkyl group may have is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxyl group, a carboxyl group, an ester group, a sulfinyl group, a sulfonyl group, an alkylthio group, or a phenylthio group.

The substituent may further have, when possible, a substituent; the alkyl group also preferably has, as a substituent, a halogen atom to serve as an alkyl halide group such as a trifluoromethyl group.

Such substituents are also preferably combined appropriately to form an acid-decomposable group.

Note that the acid-decomposable group means a group that is decomposed by action of an acid to generate a polar group, and preferably has a structure in which a group that leaves by action of an acid protects the polar group. The polar group and the leaving group are as described above.

Hereinafter, the cation (ZaI-2) will be described.

The cation (ZaI-2) is a cation represented by the formula (ZaI) where R²⁰¹ to R²⁰³ each independently represent an organic group not having an aromatic ring. The aromatic ring also encompasses aromatic rings including a heteroatom.

For R²⁰¹ to R²⁰³, the organic group not having an aromatic ring preferably has 1 to 30 carbon atoms and more preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

For R²⁰¹ to R²⁰³, the alkyl group and the cycloalkyl group may be, for example, a linear alkyl group having 1 to 10 carbon atoms or a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

R²⁰¹ to R²⁰³ may be further substituted with a halogen atom, an alkoxy group (having, for example, 1 to 5 carbon atoms), a hydroxy group, a cyano group, or a nitro group.

For R²⁰¹ to R²⁰³, substituents are also preferably provided independently as appropriate combinations of substituents to form acid-decomposable groups.

Hereinafter, the cation (ZaI-3b) will be described.

The cation (ZaI-3b) is a cation represented by the following formula (ZaI-3b).

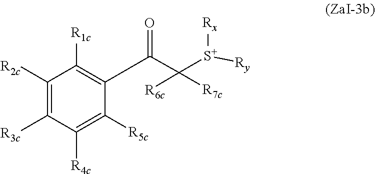

In the formula (ZaI-3b), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R_{7c} each independently represent a hydrogen atom, an alkyl group (for example, a t-butyl group), a cycloalkyl group, a halogen atom, a cyano group, or an aryl group.

Rₓ and Ry each independently represent an alkyl group, a cycloalkyl group, a 2-oxoalkyl group, a 2-oxocycloalkyl group, an alkoxycarbonylalkyl group, an allyl group, or a vinyl group.

For R_{1c} to R_{7c} and Rₓ and R_{y}, such substituents are also preferably provided independently as appropriate combinations of substituents to form acid-decomposable groups.

Any two or more of R_{1c} to R_{5c}, R_{5c} and R_{6c}, R_{6c} and R_{7c}, R_{5c}, and Rₓ, and Rₓ and R_{y} may be individually bonded together to form rings; these rings may each independently include an oxygen atom, a sulfur atom, a ketone group, an ester bond, or an amide bond.

Such a ring may be an aromatic or non-aromatic hydrocarbon ring, an aromatic or non-aromatic heterocycle, or a polycyclic fused ring formed as a combination of two or more of these rings. The ring may be a 3- to 10-membered ring, and is preferably a 4- to 8-membered ring, and more preferably a 5- or 6-membered ring.

Examples of the groups formed by bonding together any two or more of R_{1c} to R_{5c}, R_{6c} and R_{7c}, and Rₓ and R_{y} include alkylene groups such as a butylene group and a pentylene group. In such an alkylene group, a methylene group may be substituted with a heteroatom such as an oxygen atom.

The groups formed by bonding together R_{5c} and R_{6c}, and R_{5c} and Rₓ are preferably single bonds or alkylene groups. Examples of the alkylene groups include a methylene group and an ethylene group.

R_{1c} to R_{5c}, R_{6c}, R_{7c}, Rₓ, R_{y}, and the rings formed by individually bonding together any two or more of R_{1c} to R_{5c}, R_{5c} and R_{6c}, R_{6c} and R_{7c}, R_{5c} and Rₓ, and Rₓ and R_{y} may have a substituent.

Hereinafter, the cation (ZaI-4b) will be described.

The cation (ZaI-4b) is a cation represented by the following formula (ZaI-4b).

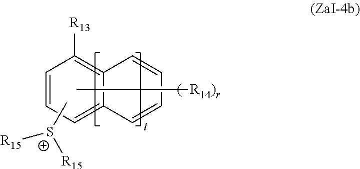

In the formula (ZaI-4b), 1 represents an integer of 0 to 2, and r represents an integer of 0 to 8.

R₁₃ represents a hydrogen atom, a halogen atom (for example, a fluorine atom or an iodine atom), a hydroxyl group, an alkyl group, an alkyl halide group, an alkoxy group, a carboxyl group, an alkoxycarbonyl group, or a group including a cycloalkyl group (may be the cycloalkyl group itself or may be a group including, as a part thereof, the cycloalkyl group). These groups may have a substituent.

R₁₄ represents a hydroxyl group, a halogen atom (for example, a fluorine atom or an iodine atom), an alkyl group, an alkyl halide group, an alkoxy group, an alkoxycarbonyl group, an alkylcarbonyl group, an alkylsulfonyl group, a cycloalkylsulfonyl group, or a group including a cycloalkyl group (may be the cycloalkyl group itself or may be a group including, as a part thereof, the cycloalkyl group). These groups may have a substituent. When a plurality of R₁₄'s are present, R₁₄'s each independently represent such a group, for example, a hydroxyl group.

R₁₅'s each independently represent an alkyl group, a cycloalkyl group, or a naphthyl group. Two R₁₅'s may be bonded together to form a ring. When two R₁₅'s are bonded together to form a ring, the ring skeleton may include a heteroatom such as an oxygen atom or a nitrogen atom.

In an example, two R₁₅'s are preferably alkylene groups and bonded together to form a ring structure. Note that the alkyl group, the cycloalkyl group, the naphthyl group, and the ring formed by bonding together two R₁₅'s may have a substituent.

In the formula (ZaI-4b), for R₁₃, R₁₄, and R₁₅, the alkyl group may be linear or branched. The alkyl group preferably has 1 to 10 carbon atoms. Preferred examples of the alkyl group include a methyl group, an ethyl group, an n-butyl group, and a t-butyl group.

For R¹³ to R₁₅, and Rₓ and R_{y}, such substituents are also preferably provided independently as appropriate combinations of substituents to form acid-decomposable groups.

Hereinafter, the formula (ZaII) will be described.

In the formula (ZaII), R²⁰⁴ and R²⁰⁵ each independently represent an aryl group, an alkyl group, or a cycloalkyl group.

For R²⁰⁴ and R²⁰⁵, the aryl group is preferably a phenyl group or a naphthyl group, and more preferably a phenyl group. For R²⁰⁴ and R²⁰⁵, the aryl group may be an aryl group having a heterocycle having an oxygen atom, a nitrogen atom, a sulfur atom, or the like. Examples of the skeleton of the aryl group having a heterocycle include pyrrole, furan, thiophene, indole, benzofuran, and benzothiophene.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. For R²⁰⁴ and R²⁰⁵, substituents are also preferably provided independently as appropriate combinations of substituents to form acid-decomposable groups.

The following are specific examples of the organic cation; however, the present invention is not limited thereto.

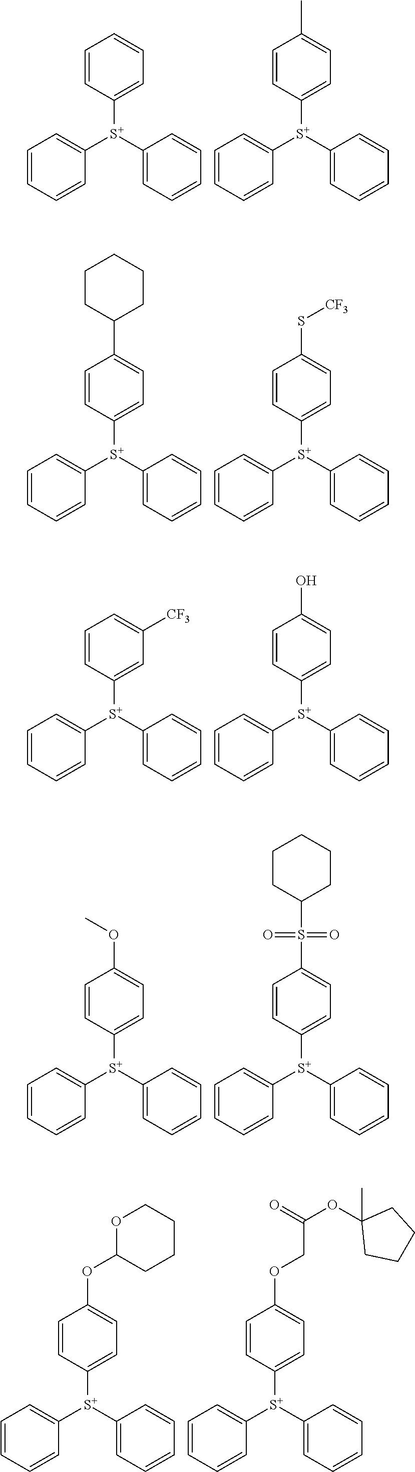

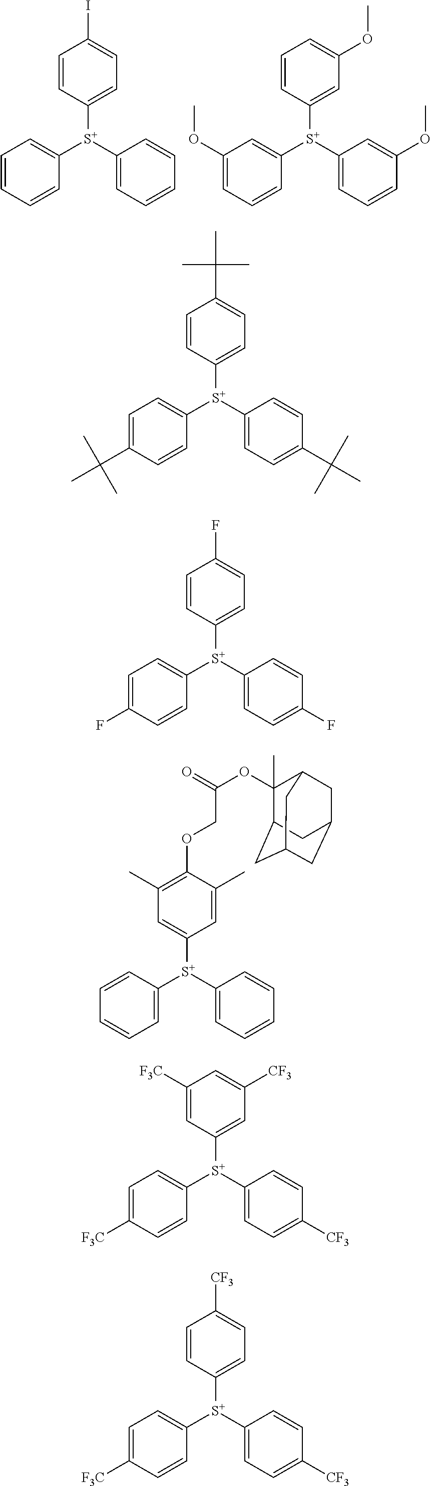

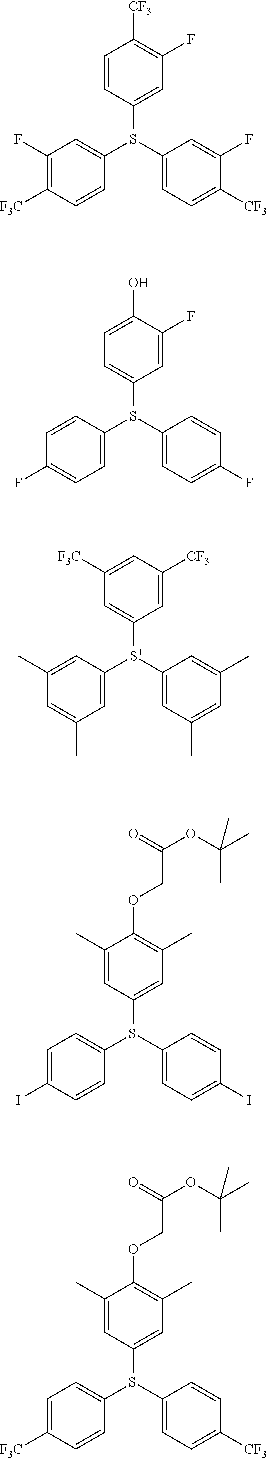

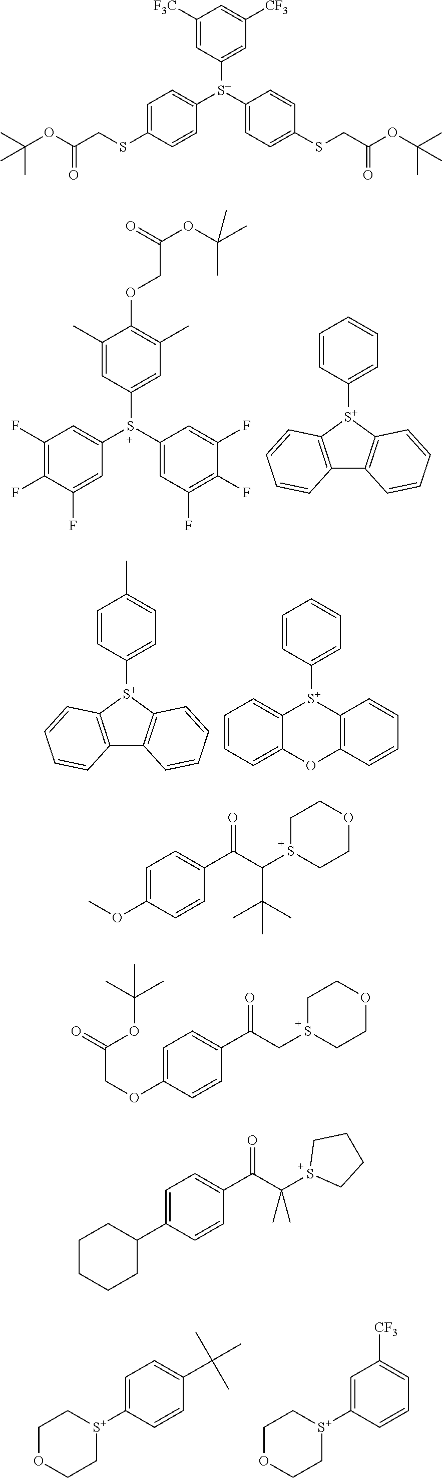

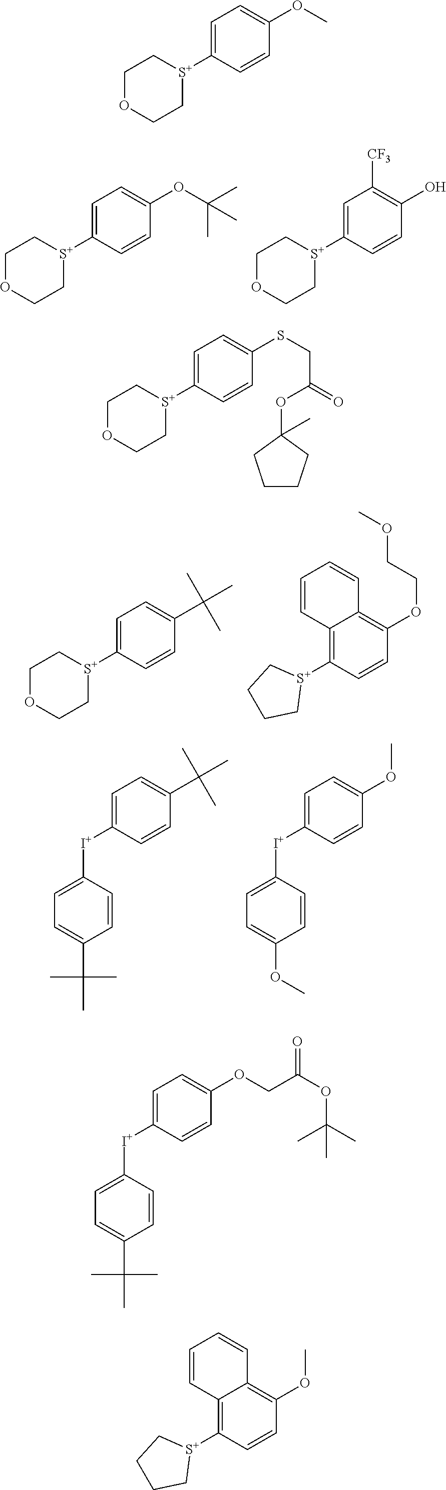

In the compound represented by “M⁺X⁻”, X⁻ represents an organic anion.

The organic anion is not particularly limited, but may be a mono-, di-, or higher valent organic anion.

The organic anion is preferably an anion that has a very low capability of causing a nucleophilic reaction, and more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl)methide anions.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxyl group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or tris(alkylsulfonyl)methide anion, the alkyl groups are preferably an alkyl group having 1 to 5 carbon atoms. A substituent of such an alkyl group may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the non-nucleophilic anion include phosphorus fluoride (for example, PF₆⁻), boron fluoride (for example, BF₄⁻), and antimony fluoride (for example, SbF₆⁻).

The non-nucleophilic anion is preferably an aliphatic sulfonate anion in which at least the α position of sulfonic acid is substituted with a fluorine atom, an aromatic sulfonate anion substituted with a fluorine atom or a group having a fluorine atom, a bis(alkylsulfonyl)imide anion in which the alkyl groups are substituted with fluorine atoms, or a tris(alkylsulfonyl)methide anion in which the alkyl groups are substituted with fluorine atoms. In particular, the anion is more preferably a perfluoroaliphatic sulfonate anion (preferably having 4 to 8 carbon atoms) or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The non-nucleophilic anion is also preferably an anion represented by the following formula (AN1).

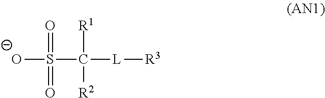

In the formula (AN1), R and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably —R′, —OH, —OR′, —OCOR′, —NH₂, —NR′₂, —NHR′, or —NHCOR′. R′ are monovalent hydrocarbon groups.

Examples of the above-described monovalent hydrocarbon groups represented by R′ include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantyl group; and cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and methylanthryl group; and aralkyl groups such as a benzyl group, a phenethyl group, a phenylpropyl group, a naphthylmethyl group, and an anthrylmethyl group.

In particular, R¹ and R² are each independently preferably a hydrocarbon group (preferably a cycloalkyl group) or a hydrogen atom.

L represents a divalent linking group.

When a plurality of L's are present, L's may be the same or different.

The divalent linking group may be, for example, —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group that is a combination of a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, and more preferably —O—CO—O—, —O—CO—O-alkylene group-, —COO—, —CONH—, —SO₂—, or —COO-alkylene group-.

L is preferably, for example, a group represented by the following formula (AN1-1).

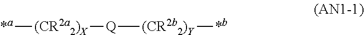

In the formula (AN1-1), *^{a} represents a bonding site to R³ in the formula (AN1).

*^{b} represents a bonding site to —C(R¹)(R²)— in the formula (AN1).

X and Y each independently represent an integer of 0 to 10, and is preferably an integer of 0 to 3.

R^{2a} and R^{2b} each independently represent a hydrogen atom or a substituent.

When a plurality of R^{2a}'s and a plurality of R^{2b}'s are present, the plurality of R^{2a}'s and the plurality of R^{2b}'s present may be individually the same or different.

Note that, when Y is 1 or more, in the formula (AN1), in CR^{2b2} directly bonded to —C(R¹)(R²)—, R^{2b}'s are not fluorine atoms.

Q represents *^{A}—O—CO—O—*^{B}, *^{A}—CO—*^{B}, *^{A}—CO—O—*^{B}, *^{A}—O—CO—*^{B}, *^{A}—O—*^{B}, *^{A}—S—*^{B}, or *^{A}—SO₂—*^{B}.

Note that, when X+Y in the formula (AN1-1) is 1 or more, and R^{2a}'s and R^{2b}'s in the formula (AN1-1) are all hydrogen atoms, Q represents *^{A}—O—CO—O—*^{B}, *^{A}—CO—*^{B}, *^{A}—O—CO—*^{B}, *^{A}—O—*^{B}, *^{A}—S—*^{B}, or *^{A}—SO₂—*^{B}.

*^{A} represent a bonding site on the R³ side in the formula (AN1) and *^{B} represent a bonding site on the —SO₃⁻ side in the formula (AN1).

In the formula (AN1), R³ represents an organic group.

The organic group is not particularly limited as long as it has 1 or more carbon atoms, and may be a linear group (for example, a linear alkyl group) or a branched group (for example, a branched alkyl group such as a t-butyl group), or may be a cyclic group. The organic group may have or may not have a substituent. The organic group may have or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in the formula (AN1).

The organic group having a ring structure, for example, may have or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantyl group), and preferably has 5 to 12 carbon atoms.

The lactone group and the sultone group are, for example, preferably a group provided by removing, in any one of the above-described structures represented by the formulas (LC1-1) to (LC1-21) and the above-described structures represented by the formulas (SL1-1) to (SL1-3), a single hydrogen atom from a ring-member atom constituting the lactone structure or the sultone structure.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following formula (AN2).

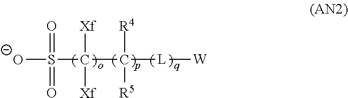

In the formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF₃; still more preferably, both of Xf's are fluorine atoms.

R⁴ and R⁵ each independently represent a hydrogen atom, a fluorine atom, an alkyl group, or an alkyl group substituted with at least one fluorine atom. When a plurality of R⁴'s and a plurality of R⁵'s are present, R⁴'s and R⁵'s may be individually the same or different.

For R⁴ and R⁵, the alkyl group preferably has 1 to 4 carbon atoms. The alkyl group may have a substituent. R⁴ and R⁵ are preferably a hydrogen atom.

L represents a divalent linking group. L has the same definition as L in the formula (AN1).

W represents an organic group including a ring structure. In particular, preferred is a cyclic organic group.

The cyclic organic group may be, for example, an alicyclic group, an aryl group, or a heterocyclic group.

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group.

The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (that may be either linear or branched and preferably has 1 to 12 carbon atoms), a cycloalkyl group (that may have either a monocycle, a polycycle, or a spiro ring, and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon constituting the cyclic organic group (carbon contributing to formation of the ring) may be a carbonyl carbon.

The anion represented by the formula (AN2) is preferably SO₃⁻—CF₂—CH₂—OCO-(L)_{q′}-W, SO₃⁻—CF₂—CHF—CH₂—OCO-(L)_{q′}-W, SO₃⁻—CF₂—COO-(L)_{q′}-W, SO₃⁻—CF₂—CF₂—CH₂—CH₂-(L)_{q}-W, or SO₃⁻—CF₂—CH(CF₃)—OCO-(L)_{q′}-W. Here, L, q, and W are the same as those in the formula (AN2). q′ represent an integer of 0 to 10.

The non-nucleophilic anion is also preferably an aromatic sulfonate anion represented by the following formula (AN3).

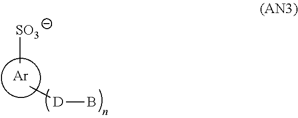

In the formula (AN3), Ar represents an aryl group (such as a phenyl group), and may further have a substituent other than the sulfonate anion and the -(D-B) group. Examples of the substituent that Ar may further have include a fluorine atom and a hydroxy group.

n represents an integer of 0 or more. n is preferably 1 to 4, more preferably 2 to 3, and still more preferably 3.

D represents a single bond or a divalent linking group. The divalent linking group may be an ether group, a thioether group, a carbonyl group, a sulfoxide group, a sulfo group, a sulfonic acid ester group, an ester group, or a group that is a combination of two or more of the foregoing.

B represents a hydrocarbon group.

B is preferably an aliphatic hydrocarbon group, and more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion is, for example, an anion represented by N⁻(SO₂—R^{q})₂.

R^{q}'s represent an alkyl group that may have a substituent, are preferably a fluoroalkyl group, and more preferably a perfluoroalkyl group. Two R^{q}'s may be bonded together to form a ring. The group formed by bonding together two R^{q}'s is preferably an alkylene group that may have a substituent, preferably a fluoroalkylene group, and still more preferably a perfluoroalkylene group. The alkylene group preferably has 2 to 4 carbon atoms.

Other examples of the non-nucleophilic anion include anions represented by the following formulas (d1-1) to (d1-4).

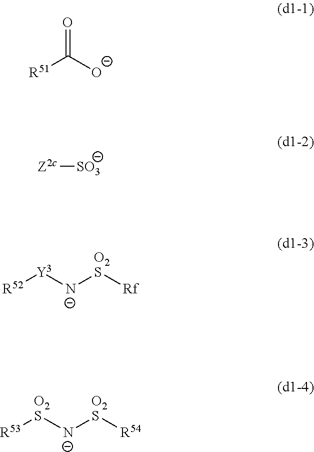

In the formula (d1-1), R⁵¹ represents a hydrocarbon group that may have a substituent (such as a hydroxy group) (for example, an aryl group such as a phenyl group).

In the formula (d1-2), Z^{2c} represents a hydrocarbon group that has 1 to 30 carbon atoms and that may have a substituent (provided that the carbon atom adjacent to S is not substituted with a fluorine atom).

In Z^{2c}, the hydrocarbon group may be linear or branched, and may have a ring structure. In the hydrocarbon group, a carbon atom (preferably, in a case where the hydrocarbon group has a ring structure, a carbon atom serving as a ring-member atom) may be a carbonyl carbon (—CO—). The hydrocarbon group may be, for example, a group that has a norbornyl group that may have a substituent. A carbon atom forming the norbornyl group may be a carbonyl carbon.

In the formula (d1-2), “Z^{2c}—SO₃⁻—” is preferably different from the anions represented by the above-described formulas (AN1) to (AN3). For example, Z^{2c} is preferably not aryl groups. For example, in Z^{2c}, the atoms at the α position and the β position with respect to —SO₃⁻ are preferably atoms other than carbon atoms having, as a substituent, a fluorine atom. For example, in Z^{2c}, the atom at the α position and/or the atom at the β position with respect to —SO₃⁻ is preferably a ring-member atom in a ring group.

In the formula (d1-3), R⁵² represents an organic group (preferably a hydrocarbon group having a fluorine atom); Y³ represents a linear, branched, or cyclic alkylene group, an arylene group, or a carbonyl group; and Rf represents a hydrocarbon group.

In the formula (d1-4), R⁵³ and R⁵⁴ each independently represent an organic group (preferably a hydrocarbon group having a fluorine atom). R⁵³ and R⁵⁴ may be bonded together to form a ring.

Such organic anions may be used alone or may be used in combination of two or more thereof.

The photoacid generator is also preferably at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁⁻ and a cationic moiety M₁⁺ and that forms, upon irradiation with an actinic ray or a radiation, the first acidic moiety represented by HA₁

Structural moiety Y: a structural moiety that is constituted by an anionic moiety A₂⁻ and a cationic moiety M₂⁺ and that forms, upon irradiation with an actinic ray or a radiation, the second acidic moiety represented by HA₂

The compound (I) satisfies the following condition I.

Condition I: a compound PI in which the cationic moiety M₁⁺ in the structural moiety X and the cationic moiety M₂⁺ in the structural moiety Y in the compound (I) are replaced by H⁺ has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂⁺ in the structural moiety Y is replaced by H⁺, and the acid dissociation constant a2 is larger than the acid dissociation constant a1.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant a1 and the acid dissociation constant a2 of the compound PI will be more specifically described as follows: in determination of the acid dissociation constants of the compound PI, the pKa at the time when the compound PI turns into a “compound having A₁⁻ and HA₂” is the acid dissociation constant a1, and the pKa at the time when the “compound having A₁⁻ and HA₂” turns into a “compound having A₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁⁻, one HA₁, and one HA₂” and the acid dissociation constant at the time when the “compound having one A₁⁻, one HA₁, and one HA₂” turns into a “compound having two A₁⁻ and one HA₂” correspond to the above-described acid dissociation constant a1. The acid dissociation constant at the time when the “compound having two A₁⁻ and one HA₂” turns into a “compound having two A₁⁻ and A₂-” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value among the plurality of the acid dissociation constants a1. Note that, in a case where the acid dissociation constant at the time when the compound PI turns into the “compound having one A₁⁻, one HA₁, and one HA₂” is defined as aa, and the acid dissociation constant at the time when the “compound having one A₁⁻, one HA₁, and one HA₂” turns into the “compound having two A₁⁻ and one HA₂” is defined as ab, the relationship between aa and ab satisfies aa<ab.

The acid dissociation constant a1 and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), the A₁⁻ and the A₂⁻, and the M₁⁺ and the M₂⁺ may be individually the same or different, but the A₁⁻ and the A₂⁻ are preferably different from each other.

In the compound PI, the difference (absolute value) between the acid dissociation constant a1 (when a plurality of acid dissociation constants a1 are present, the largest value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the largest value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably −4.0 or more.

In the compound PI, the acid dissociation constant a1 is preferably 2.0 or less, and more preferably 0 or less. Note that the lower limit value of the acid dissociation constant a1 is preferably −20.0 or more.

The anionic moiety A₁⁻ and the anionic moiety A₂⁻ are structural moieties including a negatively charged atom or atomic group and may be, for example, structural moieties selected from the group consisting of formulas (AA-1) to (AA-3) and formulas (BB1-1) to (BB-6) below.

The anionic moiety A₁⁻ is preferably an anionic moiety that can form an acidic moiety having a small acid dissociation constant, in particular, more preferably any one of the formulas (AA-1) to (AA-3), and still more preferably any one of the formulas (AA-1) and (AA-3).

The anionic moiety A₂⁻ is preferably an anionic moiety that can form an acidic moiety having a larger acid dissociation constant than the anionic moiety A₁⁻, more preferably any one of the formulas (B1B-1) to (BB-6), and still more preferably any one of the formulas (B1B-1) and (BB-4).

Note that, in the formulas (AA-1) to (AA-3) and the formulas (B1-1) to (BB-6) below, * represent a bonding site.

In the formula (AA-2), R^{A} represent a monovalent organic group. The monovalent organic groups represented by R^{A} are not particularly limited, but may be, for example, a cyano group, a trifluoromethyl group, or a methanesulfonyl group.

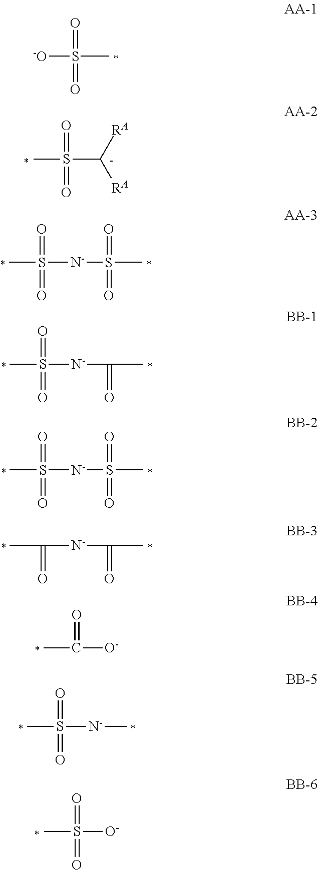

The cationic moiety M₁⁺ and the cationic moiety M₂⁺ are structural moieties including a positively charged atom or atomic group and may be, for example, singly charged organic cations. Note that such an organic cation may be, for example, the above-described organic cation represented by M⁺.

### Compound (II)

The compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

Structural Moiety Z: A Nonionic Moiety that can Neutralize Acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples are also the same.

In a compound PII in which the cationic moiety M₁⁺ in the structural moiety X in the compound (II) is replaced by H⁺, the preferred range of the acid dissociation constant a1 derived from the acidic moiety represented by HA₁ in which the cationic moiety M₁⁺ in the structural moiety X is replaced by H⁺ is the same as in the acid dissociation constant a1 in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A⁻ and one HA₁” and the acid dissociation constant at the time when the “compound having one A₁⁻ and one HA₁” turns into a “compound having two A₁⁻” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to π-conjugation. Examples of the nitrogen atom having an unshared electron pair that does not contribute to π-conjugation include nitrogen atoms having partial structures represented by the following formulas.

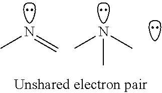

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

Examples of the non-cationic moieties that the compound (I) and the compound (II) can have are as follows.

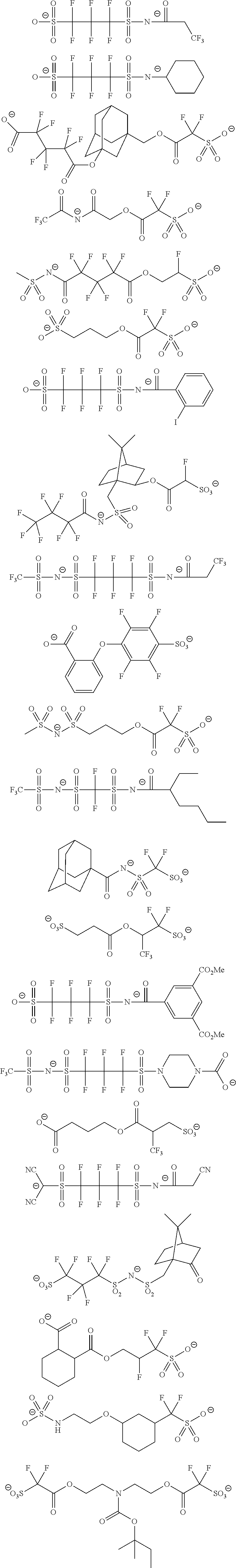

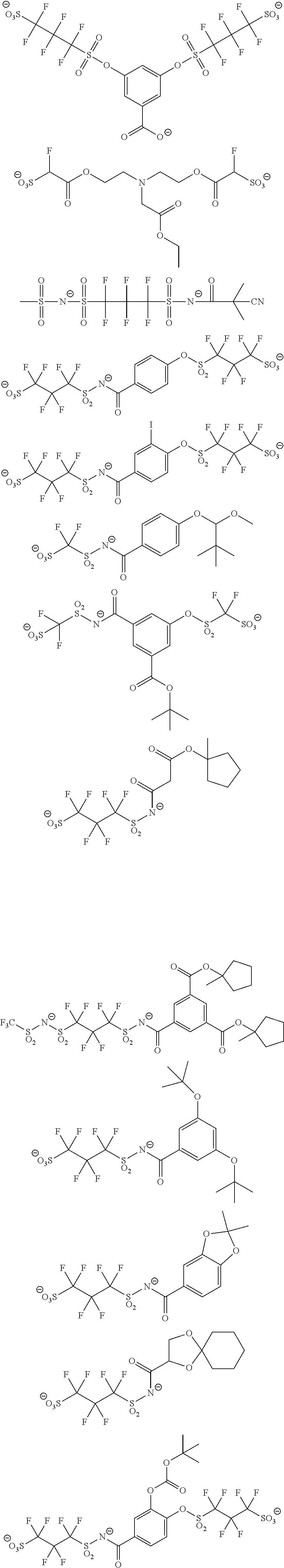

When the composition of the present invention contains a photoacid generator, the content of the photoacid generator is not particularly limited, but is, relative to the total solid content of the composition of the present invention, preferably 0.5 mass % or more, more preferably 1.0 mass % or more, and still more preferably 5.0 mass % or more. The content of the photoacid generator relative to the total solid content of the composition of the present invention is preferably 50.0 mass % or less, more preferably 30.0 mass % or less, and still more preferably 25.0 mass % or less.

Such photoacid generators may be used alone or may be used in combination of two or more thereof. When two or more thereof are used, the total content thereof is preferably within such a preferred content range.

### Acid Diffusion Control Agent (D)

The composition of the present invention may further contain an acid diffusion control agent (D) (also referred to as “compound (D)”).

The compound (D) can serve as a quencher that traps, for example, the acid generated from the photoacid generator or the like during exposure and that suppresses the reaction of the resin (A) in the unexposed regions caused by the excess of the generated acid.

The type of the compound (D) is not particularly limited, and examples thereof include a basic compound (DA), a low-molecular-weight compound (DB) having a nitrogen atom and having a group that leaves by action of an acid, and a compound (DC) whose acid diffusion control ability is reduced or lost upon irradiation with an actinic ray or a radiation.

Examples of the compound (DC) include an acid onium salt compound (DD) that becomes a weak acid relative to the acid generated from a photoacid generator or the like, and a basic compound (DE) whose basicity is reduced or lost upon irradiation with an actinic ray or a radiation.

Specific examples of the basic compound (DA) include, for example, those described in Paragraphs [0132] to [0136] of WO2020/066824A; specific examples of the basic compound (DE) whose basicity is reduced or lost upon irradiation with an actinic ray or a radiation include those described in Paragraphs [0137] to [0155] of WO2020/066824A, and those described in Paragraph [0164] of WO2020/066824A; and, specific examples of the low-molecular-weight compound (DB) having a nitrogen atom and having a group that leaves by action of an acid include those described in Paragraphs [0156] to [0163] of WO2020/066824A.

Specific examples of the onium salt compound (DD) that becomes a weak acid relative to the acid generated from a photoacid generator or the like include, for example, those described in Paragraphs [0305] to [0314] of WO2020/158337A.

In addition to those described above, for example, the publicly known compounds disclosed in Paragraphs [0627] to [0664] in US2016/0070167A, Paragraphs [0095] to [0187] in US2015/0004544A, Paragraphs [0403] to [0423] in US2016/0237190A, and Paragraphs [0259] to [0328] in US2016/0274458A can be suitably used as acid diffusion control agents.

The molecular weight of the compound (D) is not particularly limited, but is preferably 100 to 3000, more preferably 150 to 2500, and still more preferably 200 to 2000.

The compound (D) is also preferably a compound that generates, upon irradiation with an actinic ray or a radiation, an acid having a pKa of 0 or more.

When the composition of the present invention includes the compound (D), the content of the compound (D) relative to the total solid content of the composition of the present invention is preferably 0.1 mass % or more, more preferably 0.5 mass % or more, and still more preferably 1.0 mass % or more. The content of the compound (D) relative to the total solid content of the composition of the present invention is preferably 50.0 mass % or less, more preferably 40.0 mass % or less, and still more preferably 30.0 mass % or less.

Such compounds (D) may be used alone or may be used in combination of two or more thereof. When two or more thereof are used, the total content thereof is preferably within such a preferred content range.

### Hydrophobic Resin

The composition of the present invention may further include a hydrophobic resin different from the resin (A).

The hydrophobic resin is preferably designed so as to be localized in the surface of a resist film; however, unlike surfactants, the hydrophobic resin does not necessarily need to have intramolecularly a hydrophilic group, and does not necessarily contribute to homogeneous mixing of a polar substance and a nonpolar substance.

The hydrophobic resin, from the viewpoint of localization in the surface layer of the film, preferably has one or more species, more preferably two or more species, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include the compounds described in Paragraphs [0275] to [0279] in WO2020/004306A.

When the composition of the present invention includes a hydrophobic resin, the content of the hydrophobic resin relative to the total solid content of the composition of the present invention is preferably 0.01 to 20.0 mass %, and more preferably 0.1 to 15.0 mass %.

Such hydrophobic resins may be used alone, or may be used in combination of two or more thereof. When two or more thereof are used, the total content thereof is preferably within such a preferred content range.

### Surfactant

The composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

When the composition of the present invention includes a surfactant, the content of the surfactant relative to the total solid content of the composition of the present invention is preferably 0.0001 to 2.0 mass %, more preferably 0.0005 to 1.0 mass %, and still more preferably 0.1 to 1.0 mass %.

Such surfactants may be used alone or may be used in combination of two or more thereof. When two or more thereof are used, the total content thereof is preferably within such a preferred content range.

### Solvent

The composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition of the present invention and reducing the number of pattern development defects. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs [0218] to [0226] in WO2020/004306A, and these contents are incorporated herein.

When the solvent further includes a component other than the components (M1) and (M2), the content of the component other than the components (M1) and (M2) relative to the total amount of the solvent is preferably 5 to 30 mass %.

The content of the solvent in the composition of the present invention is determined so that the solid-content concentration is preferably 0.5 to 30 mass %, and more preferably 1 to 20 mass %. This further improves the coatability of the composition of the present invention.

### Other Additives

The composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by action of an acid to cause a decrease in the degree of solubility in organic-based developers, and has a molecular weight of 3000 or less.

The content of other additives is not particularly limited, but may be, relative to the total solid content of the composition of the present invention, 20.0 mass % or less, 10.0 mass % or less, or 5.0 mass % or less.

The other additives may be used alone or may be used in combination of two or more thereof. When two or more thereof are used, the total content thereof is preferably within such a preferred content range.

### Actinic Ray-Sensitive or Radiation-Sensitive Film and Pattern Forming Method

The present invention also relates to an actinic ray-sensitive or radiation-sensitive film formed from the composition of the present invention. The actinic ray-sensitive or radiation-sensitive film of the present invention is preferably a resist film.

The present invention also relates to a pattern forming method. The pattern forming method of the present invention is preferably a pattern forming method having a step of using the composition of the present invention to form an actinic ray-sensitive or radiation-sensitive film (typically, a resist film) on a substrate, a step of exposing the actinic ray-sensitive or radiation-sensitive film, and a step of using a developer to develop the exposed actinic ray-sensitive or radiation-sensitive film.

The procedures of the pattern forming method using the composition of the present invention are not particularly limited, but preferably have the following steps:
Step 1: a step of using the composition of the present invention to form a resist film on a substrate;
Step 2: a step of exposing the resist film; and
Step 3: a step of developing the exposed resist film using a developer.

Hereinafter, procedures of the steps will be individually described in detail.

### Step 1: Resist Film Formation Step

The step 1 is a step of using the composition of the present invention to form a resist film on a substrate.

Examples of the method of using the composition of the present invention to form a resist film on a substrate include a method of applying the composition of the present invention onto a substrate.

Note that the composition of the present invention is preferably filtered through a filter before application as needed. The filter preferably has a pore size of 0.1 m or less, more preferably 0.05 m or less, and still more preferably 0.03 m or less. The filter is preferably formed of polytetrafluoroethylene, polyethylene, or nylon.

The composition of the present invention can be applied onto a substrate (such as a silicon substrate or a silicon dioxide-covered silicon substrate) used in the production of an integrated circuit element, by an appropriate application process using a spinner, a coater, or the like. The application process is preferably spin-coating using a spinner. The spin-coating using a spinner is preferably performed at a rotation rate of 1000 to 3000 rpm (rotations per minute).

After application of the composition of the present invention, the substrate may be dried to form a resist film. Note that, as needed, as underlayers of the resist film, various underlayer films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the resist film is not particularly limited, but is, from the viewpoint of enabling formation of more precise fine patterns, preferably 10 to 120 nm. In particular, in the case of employing EUV exposure, the film thickness of the resist film is more preferably 10 to 65 nm, and still more preferably 15 to 50 nm. In the case of employing ArF liquid immersion exposure, the film thickness of the resist film is more preferably 10 to 120 nm, and still more preferably 15 to 90 nm.

Note that, for an overlying layer of the resist film, a topcoat composition may be used to form a topcoat.

The topcoat composition preferably does not mix with the resist film, and can be uniformly applied for an overlying layer of the resist film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the resist film. Specific examples of the basic compound that can be included in the topcoat include basic compounds that may be included in the composition of the present invention.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the resist film.

The exposure process may be a process of irradiating the formed resist film, through a predetermined mask, with an actinic ray or a radiation.

Examples of the actinic ray or the radiation include infrared light, visible light, ultraviolet light, far-ultraviolet light, extreme ultraviolet light, X-rays, and electron beams; preferred is 250 nm or less; more preferred is 220 nm or less; particularly preferred is far-ultraviolet light having wavelengths of 1 to 200 nm, specifically, the KrF excimer laser (248 nm), the ArF excimer laser (193 nm), the F₂ excimer laser (157 nm), EUV (13.5 nm), X-rays, and electron beams.

After the exposure, before development, baking (heating) is preferably performed. The baking accelerates the reaction in the exposed regions, to provide higher sensitivity and a better pattern profile. The heating after exposure is also referred to as PEB (Post Exposure Bake).

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post exposure bake.

### Step 3: Development Step

The step 3 is a step of using a developer to develop the exposed resist film to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and can be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition and the pattern forming method of the present invention (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt (parts per trillion) or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph [0321] in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter and the adsorption material may be used in combination. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

This Specification also relates to a method for producing an electronic device, the method including the above-described pattern forming method, and an electronic device produced by the production method.

In preferred embodiments, the electronic device of this Specification is mounted on electric and electronic apparatuses (home appliances, OA (Office Automation), media-related apparatuses, optical apparatuses, communication apparatuses, and the like).

### EXAMPLES

Hereinafter, the present invention will be described further in detail with reference to Examples. In the following Examples, materials, usage amounts, ratios, details of treatments, and orders of treatments can be appropriately changed without departing from the spirit and scope of the present invention. Thus, the scope of the present invention should not be construed as being limited to the following Examples.

Various components used in the resist compositions of Examples and Comparative Examples will be described below.

### Resin (A)

As the resin (A), A-1 to A-10 were used.

A-1 to A-10 include the repeating units described in Table 1 below at the contents described in Table 1 below. Table 1 also describes the weight-average molecular weight (Mw) and the dispersity (Mw/Mn) of each resin. The content of each repeating unit is the content ratio (molar ratio) of the repeating unit to all the repeating units included in the resin.

The weight-average molecular weights (Mw) and dispersities (Mw/Mn) of the resins were measured by GPC (carrier: tetrahydrofuran (THF)) (polystyrene-equivalent amounts). The contents of the repeating units were measured by ¹³C-NMR (nuclear magnetic resonance).

TABLE 1

| | Repeating unit (1) | | Repeating unit (2) | | Repeating unit (3) | | | |
|---|---|---|---|---|---|---|---|---|
| Resin | | Content | | Content | | Content | | |
| (A) | Type | (mol %) | Type | (mol %) | Type | (mol %) | Mw | Mw/Mn |
| A-1 | M-1 | 70 | MP-1 | 30 | — | — | 7000 | 1.20 |
| A-2 | M-1 | 50 | M-3 | 20 | MP-4 | 30 | 8000 | 1.60 |
| A-3 | M-2 | 75 | MP-5 | 25 | — | — | 6000 | 1.50 |
| A-4 | M-1 | 70 | MP-2 | 30 | — | — | 9000 | 1.40 |
| A-5 | M-4 | 70 | MP-3 | 30 | — | — | 8000 | 1.30 |
| A-6 | M-1 | 80 | MP-3 | 20 | — | — | 8000 | 1.10 |
| A-7 | M-5 | 50 | M-6 | 30 | MP-5 | 20 | 7000 | 1.40 |
| A-8 | M-6 | 80 | MP-6 | 20 | — | — | 6000 | 1.30 |
| A-9 | M-1 | 65 | MP-1 | 30 | MA-1 | 5 | 8000 | 1.40 |
| A-10 | M-1 | 60 | MP-2 | 35 | MA-2 | 5 | 11000 | 1.60 |

The structural formulas of the repeating units are as follows.

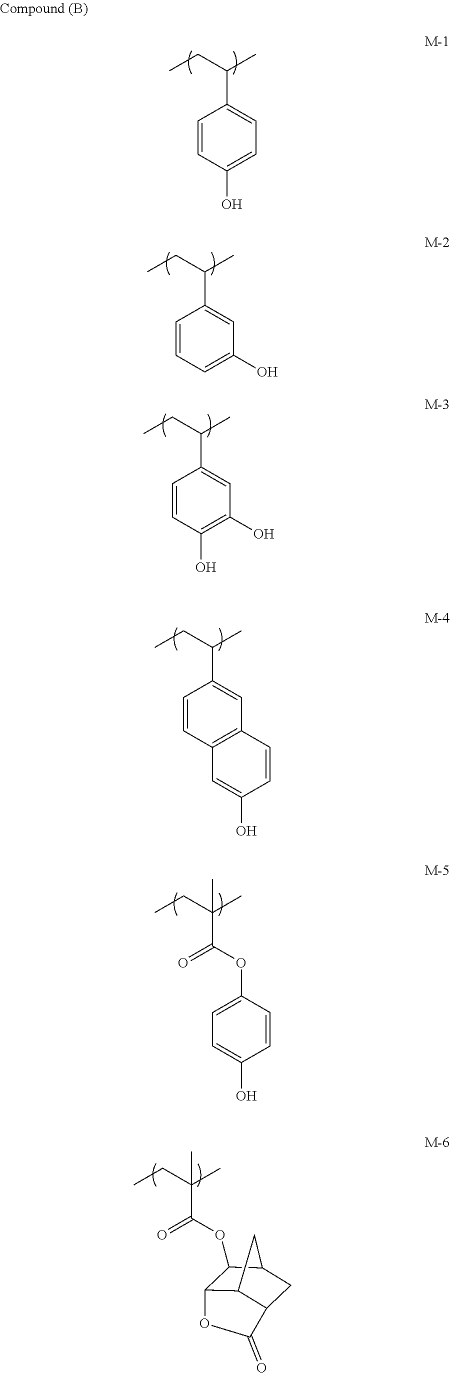

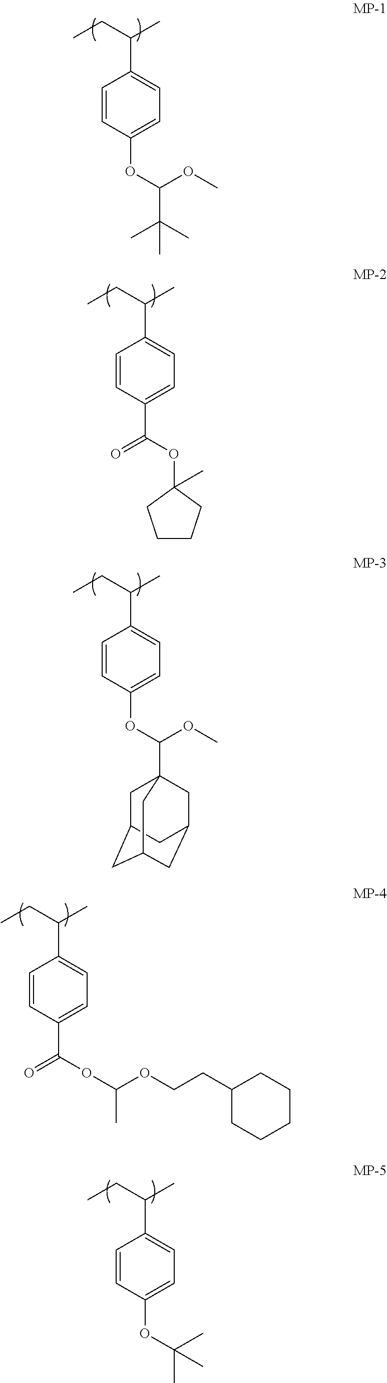

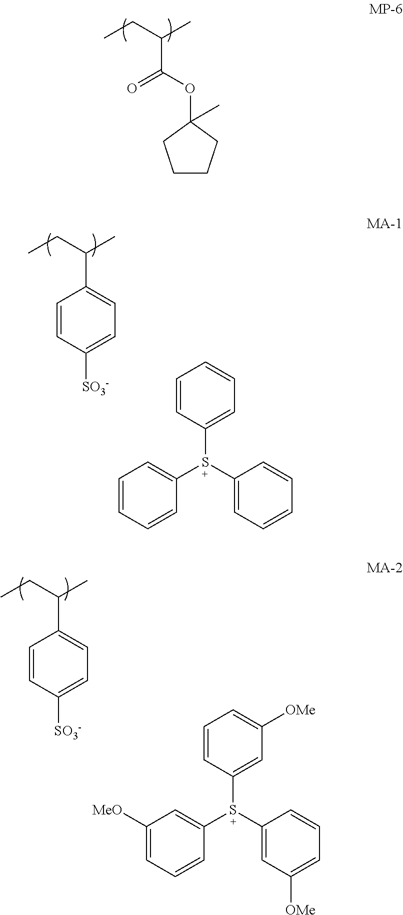

As the compound (B), compounds B-1 to B-35 were used. B-1 to B-35 are photobase generators. As photobase generators other than the compound (B), BR-1 to BR-3 were used. Note that, in Table 3 below, BR-1 to BR-3 are described in the “Compound (B)” column for convenience. The structural formulas and molecular weights of B-1 to B-35 and BR-1 to BR-3 will be described below. Me represent a methyl group.

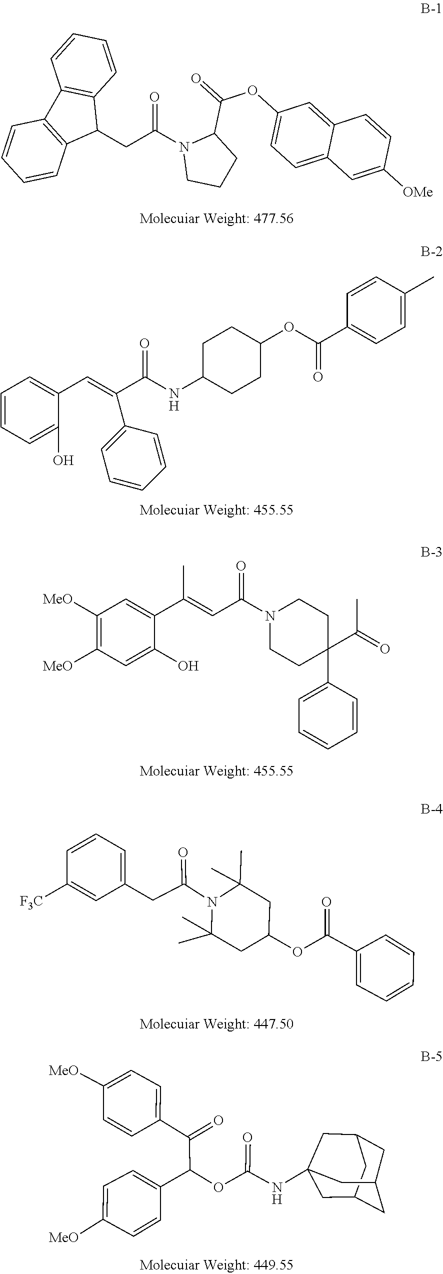 [SMILES: COc1ccc2cc(OC(=O)C3CCCN3C(=O)CC3c4ccccc4-c4ccccc43)ccc2c1 ; Cc1ccc(C(=O)OC2CCC(NC(=O)/C(=C/c3ccccc3O)c3ccccc3)CC2)cc1 ; COc1cc(O)c(/C(C)=C/C(=O)N2CCC(C(C)=O)(c3ccccc3)CC2)cc1OC ; CC1(C)CC(OC(=O)c2ccccc2)CC(C)(C)N1C(=O)Cc1cccc(C(F)(F)F)c1 ; COc1ccc(C(=O)C(OC(=O)NC23CC4CC(CC(C4)C2)C3)c2ccc(OC)cc2)cc1]

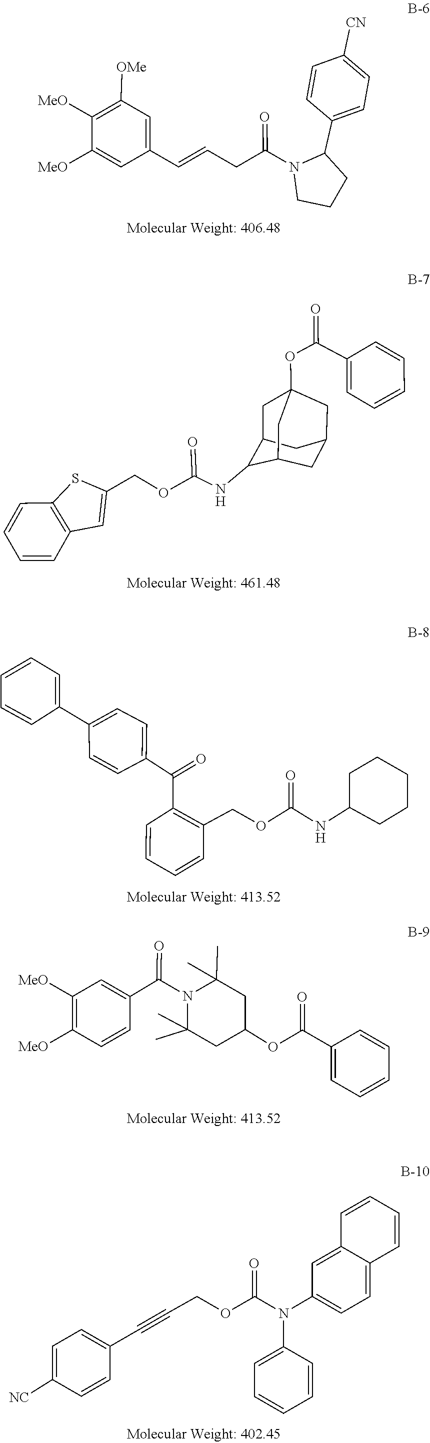 [SMILES: COc1cc(/C=C/CC(=O)N2CCCC2c2ccc(C#N)cc2)cc(OC)c1OC ; O=C(NC1C2CC3CC1CC(OC(=O)c1ccccc1)(C3)C2)OCc1cc2ccccc2s1 ; O=C(NC1CCCCC1)OCc1ccccc1C(=O)c1ccc(-c2ccccc2)cc1 ; COc1ccc(C(=O)N2C(C)(C)CC(OC(=O)c3ccccc3)CC2(C)C)cc1OC ; N#Cc1ccc(C#CCOC(=O)N(c2ccccc2)c2ccc3ccccc3c2)cc1]

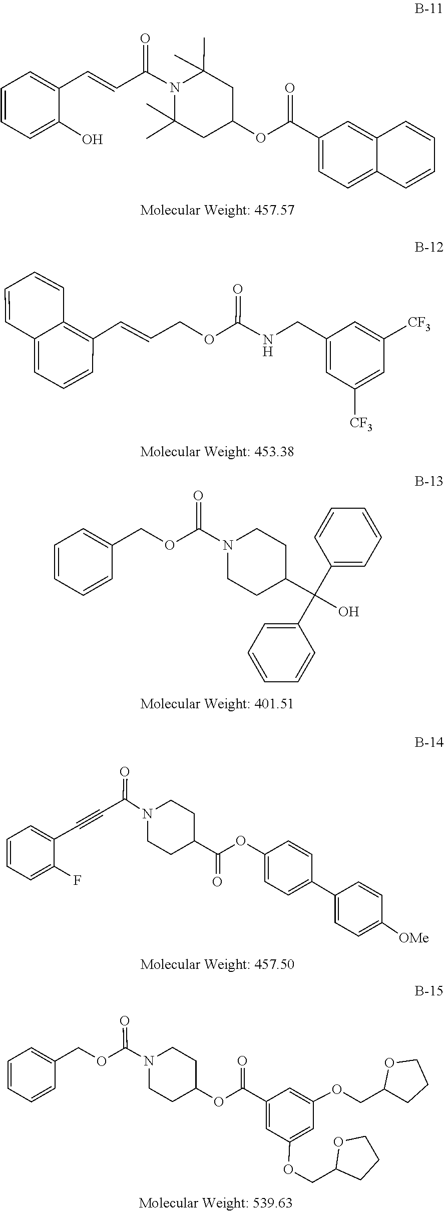 [SMILES: CC1(C)CC(OC(=O)c2ccc3ccccc3c2)CC(C)(C)N1C(=O)/C=C/c1ccccc1O ; O=C(NCc1cc(C(F)(F)F)cc(C(F)(F)F)c1)OC/C=C/c1cccc2ccccc12 ; O=C(OCc1ccccc1)N1CCC(C(O)(c2ccccc2)c2ccccc2)CC1 ; COc1ccc(-c2ccc(OC(=O)C3CCN(C(=O)C#Cc4ccccc4F)CC3)cc2)cc1 ; O=C(OC1CCN(C(=O)OCc2ccccc2)CC1)c1cc(OCC2CCCO2)cc(OCC2CCCO2)c1]

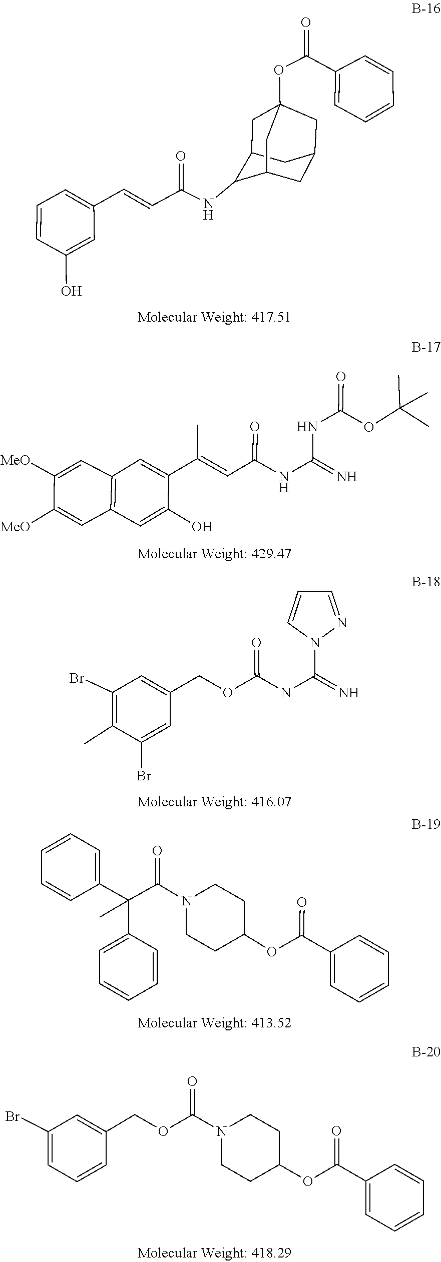 [SMILES: O=C(/C=C/c1cccc(O)c1)NC1C2CC3CC1CC(OC(=O)c1ccccc1)(C3)C2 ; COc1cc2cc(O)c(/C(C)=C/C(=O)NC(=N)NC(=O)OC(C)(C)C)cc2cc1OC ; Cc1c(Br)cc(COC(=O)NC(=N)n2cccn2)cc1Br ; CC(C(=O)N1CCC(OC(=O)c2ccccc2)CC1)(c1ccccc1)c1ccccc1 ; O=C(OC1CCN(C(=O)OCc2cccc(Br)c2)CC1)c1ccccc1]

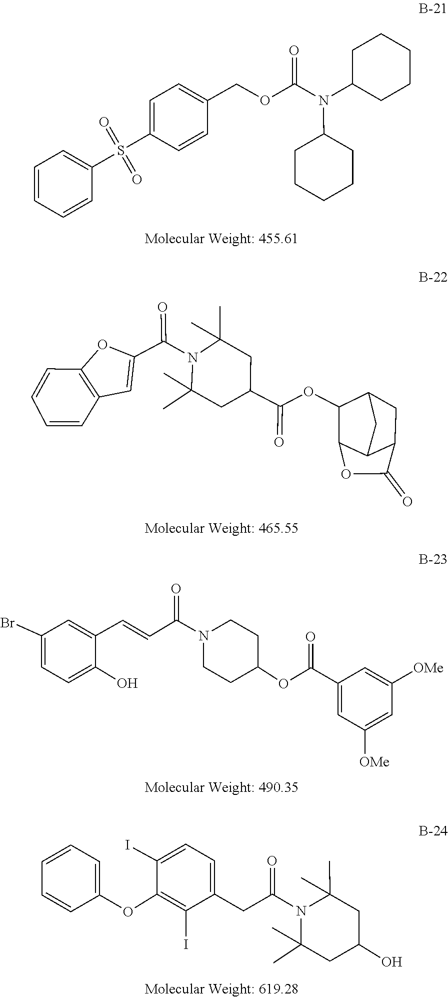 [SMILES: O=C(OCc1ccc(S(=O)(=O)c2ccccc2)cc1)N(C1CCCCC1)C1CCCCC1 ; CC1(C)CC(C(=O)OC2C3CC4C(=O)OC2C4C3)CC(C)(C)N1C(=O)c1cc2ccccc2o1 ; COc1cc(OC)cc(C(=O)OC2CCN(C(=O)/C=C/c3cc(Br)ccc3O)CC2)c1 ; CC1(C)CC(O)CC(C)(C)N1C(=O)Cc1ccc(I)c(Oc2ccccc2)c1I]

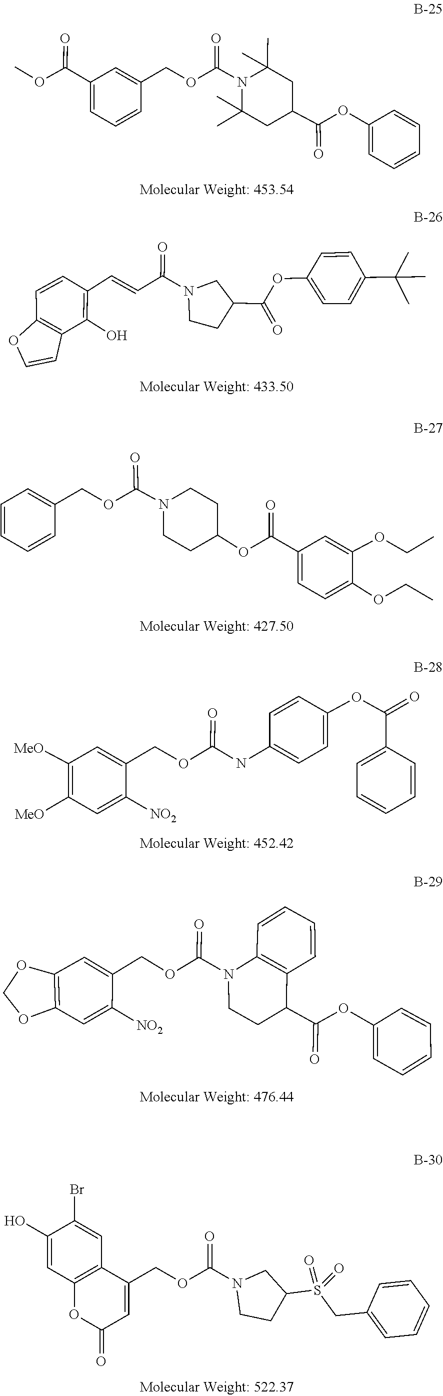

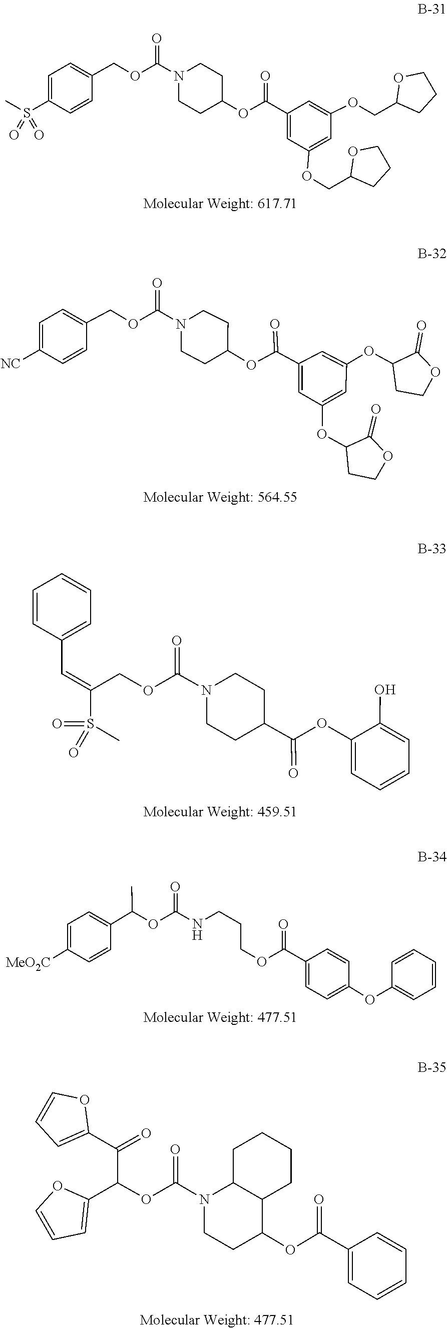 [SMILES: CS(=O)(=O)c1ccc(COC(=O)N2CCC(OC(=O)c3cc(OCC4CCCO4)cc(OCC4CCCO4)c3)CC2)cc1 ; N#Cc1ccc(COC(=O)N2CCC(OC(=O)c3cc(OC4CCOC4=O)cc(OC4CCOC4=O)c3)CC2)cc1 ; CS(=O)(=O)/C(=C/c1ccccc1)COC(=O)N1CCC(C(=O)Oc2ccccc2O)CC1 ; COC(=O)c1ccc(C(C)OC(=O)NCCCOC(=O)c2ccc(Oc3ccccc3)cc2)cc1 ; O=C(OC1CCN(C(=O)OC(C(=O)c2ccco2)c2ccco2)C2CCCCC12)c1ccccc1]

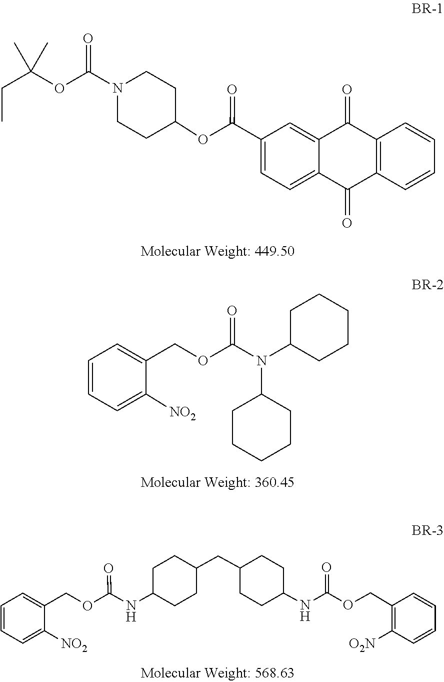 [SMILES: CCC(C)(C)OC(=O)N1CCC(OC(=O)c2ccc3c(c2)C(=O)c2ccccc2C3=O)CC1 ; O=C(OCc1ccccc1[N+](=O)[O-])N(C1CCCCC1)C1CCCCC1 ; O=C(NC1CCC(CC2CCC(NC(=O)OCc3ccccc3[N+](=O)[O-])CC2)CC1)OCc1ccccc1[N+](=O)[O-]]

### Photoacid Generators

As photoacid generators, C-1 and C-2 were used. The structural formulas of C-1 and C-2 will be described below.

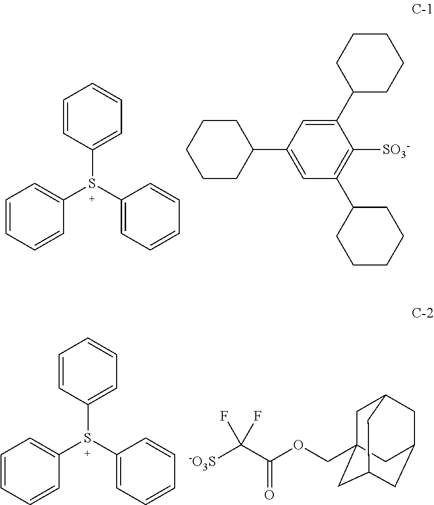

### Acid Diffusion Control Agent (D)

As the acid diffusion control agent (D), D-1 and D-2 were used. The structural formulas of D-1 and D-2 will be described below.

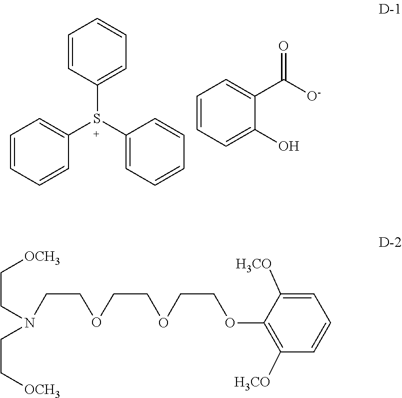

### Hydrophobic Resin

As a hydrophobic resin, T-1 was used. The structural formula of T-1, the contents (mol %) of the repeating units, the weight-average molecular weights (Mw), and the dispersities (Mw/Mn) will be described below. The content of each repeating unit is the content ratio (molar ratio) of the repeating unit relative to all the repeating units.

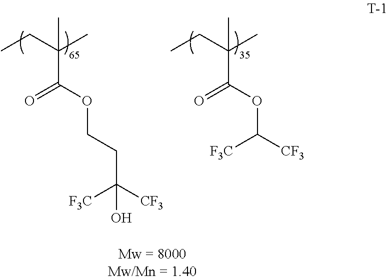

### Solvents

The solvents used are as follows.
S-1: Propylene glycol monomethyl ether acetate (PGMEA)
S-2: Propylene glycol monomethyl ether (PGME)
S-3: Ethyl lactate
S-4: γ-Butyrolactone

### Preparation of Resist Compositions

Components described in the following Tables 2, 3, and 4 were dissolved in solvents described in Tables 2, 3, and 4 to prepare solutions having a solid-content concentration of 3.0 mass %, and the solutions were filtered through a polyethylene filter having a pore size of 0.02 m to prepare resist compositions (R-1 to R-39 and XR-1 to XR-3).

In Tables 2, 3, and 4, the columns “Content (mass %)” indicate the content (mass %) of each component relative to the total solid content in the resist composition. The solid content refers to components other than the solvent.

Tables 2, 3, and 4 describe the types of solvents used and their mixing ratios (mass ratios).

In Tables 2, 3, and 4, when two or more of such a component were used, the types and the amounts thereof are described so as to be separated by “/”.

TABLE 2

| | | | | | | | Acid diffusion | | | | | |
|---|---|---|---|---|---|---|---|---|---|---|---|---|
| | | | | | Photoacid | | control agent | | Hydrophobic | | | |
| Resist | Resin (A) | | Compound (B) | | generator | | (D) | | resin | | Solvent | |
| compo- | | Content | | Content | | Content | | Content | | Content | | Mixing ratio |
| sition | Type | (mass %) | Type | (mass %) | Type | (mass %) | Type | (mass %) | Type | (mass %) | Type | (mass ratio) |
| R-1 | A-1 | 73.6 | B-1 | 3.9 | C-1 | 11.2 | D-1 | 11.3 | — | — | S-1/S-2 | 80/20 |
| R-2 | A-2 | 72.1 | B-2 | 3.2 | C-1 | 14.7 | D-2 | 10.0 | — | — | S-1/S-2 | 80/20 |
| R-3 | A-3 | 73.4 | B-3 | 2.8 | C-1 | 15.3 | D-1 | 8.4 | — | — | S-1/S-2 | 80/20 |
| R-4 | A-4 | 65.3 | B-4 | 4.8 | C-1 | 18.0 | D-1 | 8.4 | T-1 | 3.5 | S-1/S-2 | 80/20 |
| R-5 | A-5 | 69.8 | B-5 | 5.0 | C-1 | 16.9 | D-1 | 8.3 | — | — | S-1/S-2/S-3 | 40/20/40 |
| R-6 | A-6 | 68.9 | B-6 | 3.3 | C-1 | 17.5 | D-1 | 10.3 | — | — | S-1/S-2 | 80/20 |
| R-7 | A-7 | 69.8 | B-7 | 5.5 | C-2 | 12.2 | D-1 | 12.5 | — | — | S-1/S-2/S-4 | 60/30/10 |
| R-8 | A-8 | 71.8 | B-8 | 5.8 | C-2 | 12.5 | D-2 | 9.9 | — | — | S-1/S-2 | 80/20 |
| R-9 | A-9 | 85.1 | B-9 | 5.8 | — | — | D-1 | 9.1 | — | — | S-1/S-2 | 80/20 |
| R-10 | A-10 | 86.1 | B-10 | 3.3 | — | — | D-1 | 10.6 | — | — | S-1/S-2/S-3 | 40/20/40 |
| R-11 | A-3 | 72.1 | B-11 | 4.5 | C-1 | 15.5 | D-1 | 7.9 | — | — | S-1/S-2/S-3 | 40/20/40 |
| R-12 | A-1 | 74.1 | B-12 | 3.2 | C-1 | 11.7 | D-1 | 11.0 | — | — | S-1/S-2/S-4 | 60/30/10 |
| R-13 | A-3 | 72.6 | B-13 | 4.2 | C-1 | 11.9 | D-1 | 11.3 | — | — | S-1/S-2 | 80/20 |
| R-14 | A-2 | 73.8 | B-14 | 3.9 | C-1 | 11.8 | D-1 | 10.5 | — | — | S-1/S-2/S-4 | 60/30/10 |
| R-15 | A-6 | 73.5 | B-15 | 4.0 | C-1 | 11.2 | D-1 | 11.3 | — | — | S-1/S-2/S-3 | 40/20/40 |
| R-16 | A-4 | 62.0 | B-16 | 5.2 | C-1 | 18.5 | D-1 | 10.1 | T-1 | 4.2 | S-1/S-2/S-3 | 40/20/40 |
| R-17 | A-5 | 68.7 | B-17 | 4.8 | C-1 | 18.3 | D-1 | 8.2 | — | — | S-1/S-2/S-3 | 40/20/40 |

TABLE 3

| | | | | | | | | | | | Solvent | |
|---|---|---|---|---|---|---|---|---|---|---|---|---|
| | | | | | Photoacid | | Acid diffusion | | Hydrophobic | | | Mixing |
| Resist | Resin (A) | | Compound (B) | | generator | | control agent (D) | | resin | | | ratio |
| compo- | | Content | | Content | | Content | | Content | | Content | | (mass |
| sition | Type | (mass %) | Type | (mass %) | Type | (mass %) | Type | (mass %) | Type | (mass %) | Type | ratio) |
| R-18 | A-4 | 70.6 | B-18 | 5.0 | C-1 | 15.0 | D-1 | 9.4 | — | — | S-1/S-2/S-4 | 60/30/10 |
| R-19 | A-1 | 71.7 | B-19 | 5.1 | C-1 | 14.9 | D-2 | 8.3 | — | — | S-1/S-2 | 80/20 |
| R-20 | A-7 | 69.4 | B-20 | 4.9 | C-2 | 17.8 | D-1 | 7.9 | — | — | S-1/S-2/S-4 | 60/30/10 |
| R-21 | A-6 | 68.9 | B-21 | 3.6 | C-1 | 18.6 | D-1 | 8.8 | — | — | S-1/S-2/S-4 | 60/30/10 |
| R-22 | A-3 | 72.1 | B-22 | 5.1 | C-1 | 14.1 | D-1 | 8.7 | — | — | S-1/S-2 | 80/20 |
| R-23 | A-5 | 69.6 | B-23 | 4.6 | C-1 | 18.3 | D-1 | 7.4 | — | — | S-1/S-2/S-4 | 60/30/10 |
| R-24 | A-6 | 67.5 | B-24 | 8.0 | C-1 | 13.4 | D-1 | 11.2 | — | — | S-1/S-2/S-3 | 40/20/40 |
| R-25 | A-1 | 73.0 | B-25 | 4.1 | C-1 | 11.0 | D-1 | 11.8 | — | — | S-1/S-2 | 80/20 |
| R-26 | A-4 | 72.4 | B-26 | 3.7 | C-1 | 16.9 | D-1 | 7.1 | — | — | S-1/S-2/S-3 | 40/20/40 |
| R-27 | A-2 | 71.5 | B-27 | 5.0 | C-1 | 15.6 | D-1 | 7.9 | — | — | S-1/S-2/S-3 | 40/20/40 |
| R-28 | A-5 | 67.7 | B-20/B-27 | 2.3/2.3 | C-1 | 19.1 | D-1 | 8.5 | — | — | S-1/S-2/S-3 | 40/20/40 |
| R-29 | A-7 | 70.0 | B-1/B-22 | 3.0/3.0 | C-2 | 13.7 | D-1 | 10.3 | — | — | S-1/S-2/S-3 | 40/20/40 |
| R-30 | A-2 | 75.3 | B-11 | 3.6 | C-1/C-2 | 7.8/3.2 | D-1 | 10.1 | — | — | S-1/S-2/S-4 | 60/30/10 |
| R-31 | A-7 | 71.0 | B-15 | 6.6 | C-2 | 12.9 | D-1/D-2 | 5.6/3.8 | — | — | S-1/S-2/S-4 | 60/30/10 |
| XR-1 | A-4 | 68.3 | BR-1 | 5.2 | C-1 | 17.2 | D-1 | 9.3 | — | — | S-1/S-2/S-4 | 60/30/10 |
| XR-2 | A-6 | 71.2 | BR-2 | 3.8 | C-1 | 16.3 | D-2 | 8.7 | — | — | S-1/S-2/S-3 | 40/20/40 |
| XR-3 | A-3 | 68.6 | BR-3 | 6.7 | C-1 | 13.7 | D-1 | 11.0 | — | — | S-1/S-2/S-3 | 40/20/40 |

TABLE 4

| | | | | | | | Acid diffusion | | | | Solvent | |
|---|---|---|---|---|---|---|---|---|---|---|---|---|
| | | | | | Photoacid | | control agent | | Hydrophobic | | | Mixing |
| Resist | Resin (A) | | Compound (B) | | generator | | (D) | | resin | | | ratio |
| compo- | | Content | | Content | | Content | | Content | | Content | | (mass |
| sition | Type | (mass %) | Type | (mass %) | Type | (mass %) | Type | (mass %) | Type | (mass %) | Type | ratio) |
| R-32 | A-2 | 66.0 | B-28 | 7.4 | C-1 | 13.7 | D-1 | 13.0 | — | — | S-1/S-2 | 80/20 |
| R-33 | A-3 | 69.1 | B-29 | 5.1 | C-1 | 14.5 | D-1 | 11.3 | — | — | S-1/S-2/S-4 | 60/30/10 |
| R-34 | A-5 | 66.0 | B-30 | 9.1 | C-1 | 13.3 | D-1 | 11.7 | — | — | S-1/S-2 | 80/20 |
| R-35 | A-6 | 68.5 | B-31 | 5.2 | C-1 | 12.7 | D-1 | 13.6 | — | — | S-1/S-2 | 80/20 |
| R-36 | A-1 | 69.1 | B-32 | 5.0 | C-1 | 11.9 | D-1 | 14.1 | — | — | S-1/S-2/S-3 | 40/20/40 |
| R-37 | A-7 | 64.6 | B-33 | 8.1 | C-1 | 14.3 | D-1 | 13.1 | — | — | S-1/S-2/S-3 | 40/20/40 |
| R-38 | A-4 | 71.3 | B-34 | 5.3 | C-1 | 13.5 | D-1 | 9.9 | — | — | S-1/S-2/S-4 | 60/30/10 |
| R-39 | A-6 | 68.7 | B-35 | 4.5 | C-1 | 16.9 | D-1 | 9.9 | — | — | S-1/S-2 | 80/20 |

### Examples 1-1 to 1-39 and Comparative Examples X1-1 to X1-3

### Pattern Forming Method (1): EB Exposure and Alkali Development (Positive)

A resist composition in Table 5 and Table 6 below was applied onto a 6-inch Si wafer having been subjected to hexamethyldisilazane (HMDS) treatment in advance, using a spin coater Mark8 manufactured by Tokyo Electron Ltd., and dried on a hot plate at 100° C. for 60 seconds to obtain a resist film having a film thickness of 100 nm.

Note that, even when the Si wafer is changed to a chromium substrate, similar results are obtained.

The wafer coated with the resist film obtained above was subjected to pattern irradiation using an electron beam lithography apparatus (HL750 manufactured by Hitachi, Ltd., accelerating voltage: 50 keV). During this process, patterning was performed so as to form a 1:1 line-and-space. After the electron beam patterning, post exposure bake (PEB) was performed by heating on a hot plate at 110° C. for 60 seconds; subsequently development was performed with a 2.38 mass % aqueous tetramethylammonium hydroxide solution for 30 seconds; rinsing was performed with pure water; subsequently the wafer was rotated at a rotational rate of 4000 rpm for 30 seconds; and subsequently heating was performed at 95° C. for 60 seconds; in this way, resist patterns of 1:1 line-and-space patterns having a line width of 50 nm were obtained.

Note that the PEB temperature dependence was evaluated for patterns formed under conditions described later.

### Performance Evaluations

### Resolution

The profile of such an obtained pattern was observed using a scanning electron microscope (manufactured by Hitachi, Ltd., S-9380II). The exposure dose (electron beam irradiation dose) at which a 1:1 line-and-space resist pattern having a line width of 50 nm was resolved was defined as sensitivity (Eop).

The resolving power limit at the exposure dose providing the above sensitivity (Eop) (the minimum line width at which a line and a space (line:space=1:1) are separately resolved) was defined as resolution (nm). The smaller this value, the higher the resolution.

### PEB Temperature Dependence

When post exposure bake (PEB) was performed at 110° C. for 90 seconds, the irradiation dose at which a 1:1 line-and-space pattern having a width of 50 nm was reproduced was defined as the optimal exposure dose. Subsequently, irradiation at the optimal exposure dose was performed; subsequently, post bake was performed at two temperatures of +2° C. and −2° C. (that is, 112° C. and 108° C.) relative to the post exposure bake temperature; the obtained line-and-space patterns were measured, and their line widths L1 and L2 were determined. PEB temperature dependence was defined as the variation in line width per 1° C. change in PEB temperature, and was calculated by the following formula.

PEB temperature dependence (nm/° C.)=L1−L2|/4

The smaller the value of the PEB temperature dependence, the smaller the change in performance in response to temperature change, which is better.

The PEB temperature dependence was evaluated in accordance with the following grades.
A: the PEB temperature dependence is less than 1.0 nm/° C.
B: the PEB temperature dependence is 1.0 nm/° C. or more and less than 2.0 nm/° C.
C: the PEB temperature dependence is 2.0 nm/° C. or more

Table 5 and Table 6 below describe the resist compositions used in Examples and Comparative Examples, and the evaluation results of Examples and Comparative Examples.

TABLE 5

| | | | PEB temperature |
|---|---|---|---|
| | Resist | Resolution | dependence |
| | composition | [nm] | [nm/° C.] |
| Example 1-1 | R-1 | 25 | A |
| Example 1-2 | R-2 | 21 | A |
| Example 1-3 | R-3 | 16 | B |
| Example 1-4 | R-4 | 21 | B |
| Example 1-5 | R-5 | 26 | B |
| Example 1-6 | R-6 | 27 | B |
| Example 1-7 | R-7 | 21 | A |
| Example 1-8 | R-8 | 30 | B |
| Example 1-9 | R-9 | 22 | B |
| Example 1-10 | R-10 | 28 | B |
| Example 1-11 | R-11 | 17 | A |
| Example 1-12 | R-12 | 22 | A |
| Example 1-13 | R-13 | 16 | B |
| Example 1-14 | R-14 | 27 | A |
| Example 1-15 | R-15 | 19 | A |
| Example 1-16 | R-16 | 21 | B |
| Example 1-17 | R-17 | 25 | B |
| Example 1-18 | R-18 | 25 | B |
| Example 1-19 | R-19 | 24 | B |
| Example 1-20 | R-20 | 20 | B |
| Example 1-21 | R-21 | 19 | A |
| Example 1-22 | R-22 | 21 | A |
| Example 1-23 | R-23 | 17 | A |
| Example 1-24 | R-24 | 21 | A |
| Example 1-25 | R-25 | 19 | A |
| Example 1-26 | R-26 | 18 | B |
| Example 1-27 | R-27 | 19 | B |
| Example 1-28 | R-28 | 19 | B |
| Example 1-29 | R-29 | 25 | A |
| Example 1-30 | R-30 | 20 | A |
| Example 1-31 | R-31 | 16 | A |
| Comparative | XR-1 | 50 | C |
| Example X1-1 | | | |
| Comparative | XR-2 | 50 | C |
| Example X1-2 | | | |
| Comparative | XR-3 | 50 | C |
| Example X1-3 | | | |

TABLE 6

| | | | PEB temperature |
|---|---|---|---|
| | Resist | Resolution | dependence |
| | composition | [nm] | [nm/° C.] |
| Example 1-32 | R-32 | 23 | A |
| Example 1-33 | R-33 | 25 | A |
| Example 1-34 | R-34 | 19 | A |
| Example 1-35 | R-35 | 20 | A |
| Example 1-36 | R-36 | 19 | A |
| Example 1-37 | R-37 | 22 | A |
| Example 1-38 | R-38 | 22 | A |
| Example 1-39 | R-39 | 26 | A |

### Examples 2-1 to 2-39 and Comparative Examples X2-1 to X2-3

### Pattern Forming Method (2): EUV Exposure and Alkali Development (Positive)

A resist composition in Table 7 and Table 8 below was applied onto a 6-inch Si wafer having been subjected to hexamethyldisilazane (HMDS) treatment in advance, using a spin coater Mark8 manufactured by Tokyo Electron Ltd., and dried on a hot plate at 100° C. for 60 seconds to obtain a resist film having a film thickness of 100 nm.

Note that, even when the Si wafer is changed to a chromium substrate, similar results are obtained.

The wafer coated with the resist film obtained above was subjected to pattern exposure using an EUV exposure apparatus (manufactured by Exitech Ltd., Micro Exposure Tool, NA (numerical aperture): 0.3, Quadrupole, outer sigma: 0.68, inner sigma: 0.36) through an exposure mask (line/space=1/1). After the exposure, as post exposure bake (PEB), the resist film was heated on a hot plate at 110° C. for 60 seconds, subsequently immersed in a 2.38 mass % tetramethylammonium hydroxide (TMAH) aqueous solution for 60 seconds, and then rinsed with water for 30 seconds. Subsequently, the wafer was rotated at a rotational rate of 4000 rpm for 30 seconds, and then heated at 95° C. for 60 seconds; in this way, resist patterns of 1:1 line-and-space patterns having a line width of 50 nm were obtained.

### Performance Evaluation

The resolution and the PEB temperature dependence were evaluated by the same methods as those described above in the description of Examples 1-1 to 1-39 and Comparative Examples X1-1 to X1-3.

The obtained evaluation results will be described in Table 7 and Table 8.

TABLE 7

| | | | PEB temperature |
|---|---|---|---|
| | Resist | Resolution | dependence |
| | composition | [nm] | [nm/° C.] |
| Example 2-1 | R-1 | 22 | A |
| Example 2-2 | R-2 | 22 | A |
| Example 2-3 | R-3 | 16 | B |
| Example 2-4 | R-4 | 23 | B |
| Example 2-5 | R-5 | 26 | B |
| Example 2-6 | R-6 | 27 | B |
| Example 2-7 | R-7 | 21 | A |
| Example 2-8 | R-8 | 27 | B |
| Example 2-9 | R-9 | 25 | B |
| Example 2-10 | R-10 | 27 | B |
| Example 2-11 | R-11 | 19 | A |
| Example 2-12 | R-12 | 23 | A |
| Example 2-13 | R-13 | 17 | B |
| Example 2-14 | R-14 | 26 | A |
| Example 2-15 | R-15 | 18 | A |
| Example 2-16 | R-16 | 24 | B |
| Example 2-17 | R-17 | 21 | B |
| Example 2-18 | R-18 | 24 | B |
| Example 2-19 | R-19 | 23 | B |
| Example 2-20 | R-20 | 19 | B |
| Example 2-21 | R-21 | 17 | A |
| Example 2-22 | R-22 | 21 | A |
| Example 2-23 | R-23 | 17 | A |
| Example 2-24 | R-24 | 25 | A |
| Example 2-25 | R-25 | 17 | A |
| Example 2-26 | R-26 | 17 | B |
| Example 2-27 | R-27 | 16 | B |
| Example 2-28 | R-28 | 18 | B |
| Example 2-29 | R-29 | 22 | A |
| Example 2-30 | R-30 | 19 | A |
| Example 2-31 | R-31 | 18 | A |
| Comparative | XR-1 | 50 | C |
| Example X2-1 | | | |
| Comparative | XR-2 | 50 | C |
| Example X2-2 | | | |
| Comparative | XR-3 | 50 | C |
| Example X2-3 | | | |

TABLE 8

| | | | PEB temperature |
|---|---|---|---|
| | Resist | Resolution | dependence |
| | composition | [nm] | [nm/° C.] |
| Example 2-32 | R-32 | 23 | A |
| Example 2-33 | R-33 | 22 | A |
| Example 2-34 | R-34 | 18 | A |
| Example 2-35 | R-35 | 17 | A |
| Example 2-36 | R-36 | 20 | A |
| Example 2-37 | R-37 | 24 | A |
| Example 2-38 | R-38 | 21 | A |
| Example 2-39 | R-39 | 27 | A |

The results in Tables 5 to 8 have demonstrated that the resist compositions used in Examples provide high resolution and low PEB temperature dependence.

The present invention can provide an actinic ray-sensitive or radiation-sensitive resin composition that provides high resolution and has low PEB temperature dependence. The present invention can also provide an actinic ray-sensitive or radiation-sensitive film, a pattern forming method, and a method for producing an electronic device that use the actinic ray-sensitive or radiation-sensitive resin composition.

The present invention has been described in detail and with reference to specific embodiments thereof, however, it would be apparent to those skilled in the art that various changes and modifications can be made therein without departing from the spirit and scope of the present invention.

What is claimed is:

1. An actinic ray-sensitive or radiation-sensitive resin composition comprising:
a resin (A) including a repeating unit having a group that is decomposed by an action of an acid, thereby increasing polarity; and
a compound (B) represented by a formula (N1) below and having a molecular weight of 400 or more, 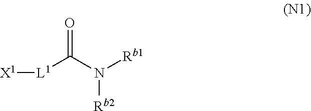
wherein in the formula (N1),
L¹ represents a single bond, *¹—OCR^{b3}R^{b4}—*², or *¹—CR^{b5}R^{b6}—*², *¹ represents a bonding site to C(═O), *² represents a bonding site to X¹,
X¹ represents an aryl group, a heteroaryl group, *³—CR^{b7}═CR^{b8}R^{b9}, or *³—C≡CR^{b10}, *³ represents a bonding site to L¹,
R^{b1} represents a hydrogen atom or a substituent,
R^{b2} represents a substituent,
provided that R^{b1} and R^{b2} do not include a structure represented by a formula (NX1) below, and R^{b1} and R^{b2} may be bonded together to form a ring, 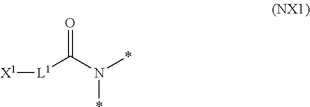
in the formula (NX1), L¹ and X¹ respectively have the same meanings as L¹ and X¹ in the formula (N1), and * represents a bonding site,
R^{b3} to R^{b8} each independently represent a hydrogen atom or a substituent,
R^{b9} and R^{b10} each independently represent a substituent.

2. The actinic ray-sensitive or radiation-sensitive resin composition according to claim 1, wherein, when L¹ in the formula (N1) represents a single bond or *¹—OCR^{b3}R^{b4}—*², X¹ in the formula (N1) represents an aryl group, a heteroaryl group, or *³—CR^{b7}═CR^{b8}R^{b9}, or
when L¹ in the formula (N1) represents *¹—CR^{b5}R^{b6}—*², X¹ in the formula (N1) represents an aryl group or a heteroaryl group.

3. The actinic ray-sensitive or radiation-sensitive resin composition according to claim 1, wherein the compound (B) is represented by a formula (N2) below: 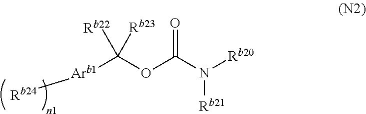
in the formula (N2),
R^{b20} represents a hydrogen atom or a substituent,
R^{b21} represents a substituent,
provided that R^{b20} and R^{b21} do not include the structure represented by the formula (NX1), and R^{b20} and R^{b21} may be bonded together to form a ring,
R^{b22} and R^{b23} each independently represent a hydrogen atom or a substituent,
R^{b24} represents a substituent,
Ar^{b1} represents an aromatic ring group having 4 to 20 ring members,
n1 represents an integer of 0 to 12, and when n1 represents an integer of 2 or more, a plurality of R^{b24} may be the same or different, and the plurality of R^{b24} may be bonded together to form a ring.

4. The actinic ray-sensitive or radiation-sensitive resin composition according to claim 3, wherein R^{b22} and R^{b23} in the formula (N2) each independently represent a hydrogen atom, an alkyl group, an alkoxy group, an alkylthio group, a cycloalkyl group, a cycloalkyloxy group, a cycloalkylthio group, an aryl group, a heteroaryl group, an aryloxy group, or an arylthio group.

5. The actinic ray-sensitive or radiation-sensitive resin composition according to claim 3, wherein R^{b20} and R²¹ in the formula (N2) each independently represent an alkyl group or a cycloalkyl group, and R^{b20} and R^{b21} may be bonded together to form a ring.

6. The actinic ray-sensitive or radiation-sensitive resin composition according to claim 1, wherein the compound (B) is represented by a formula (N3) below: 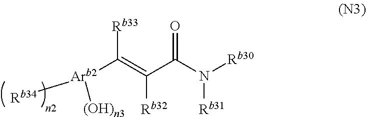
in the formula (N3),
R^{b30} represents a hydrogen atom or a substituent,
R^{b31} represents a substituent,
provided that R^{b30} and R^{b31} do not include the structure represented by the formula (NX1), and R^{b30} and R^{b31} may be bonded together to form a ring,
R^{b32} and R^{b33} each independently represent a hydrogen atom or a substituent,
R^{b34} represents a substituent other than a hydroxy group,
Ar^{b2} represents an aromatic ring group having 4 to 20 ring members,
n2 represents an integer of 0 to 11, and when n2 represents an integer of 2 or more, a plurality of R^{b34} may be the same or different, and the plurality of R^{b34} may be bonded together to form a ring, and
n3 represents 1 or 2.

7. The actinic ray-sensitive or radiation-sensitive resin composition according to claim 1, wherein the compound (B) is represented by a formula (N4) below: 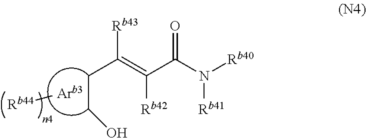
in the formula (N4),
R^{b40} and R^{b41} each independently represent an alkyl group or a cycloalkyl group, provided that R^{b40} and R^{b41} do not include the structure represented by the formula (NX1), and R^{b40} and R^{b41} may be bonded together to form a ring,
R^{b42} and R^{b43} each independently represent a hydrogen atom or a substituent,
R^{b44} represents a substituent other than a hydroxy group,
Ar^{b3} represents an aromatic ring group having 4 to 20 ring members,
n4 represents an integer of 0 to 11, and when n4 represents an integer of 2 or more, a plurality of R^{b44} may be the same or different, and the plurality of R^{b44} may be bonded together to form a ring.

8. The actinic ray-sensitive or radiation-sensitive resin composition according to claim 1, wherein, in the formula (N1),
R^{b1} represents a hydrogen atom, an alkyl group, a cycloalkyl group, an aryl group, or a group represented by a formula (GN1) below, and
R^{b2} represents an alkyl group, a cycloalkyl group, an aryl group, or a group represented by the following formula (GN1), 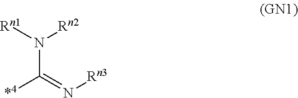
in the formula (GN1), Rⁿ¹ to Rⁿ³ each independently represent a hydrogen atom or a substituent, provided that at least one of Rⁿ¹ to Rⁿ³ represents a substituent, at least two of R¹ to Rⁿ³ may be bonded together to form a ring, and
*⁴ represents a bonding site to the nitrogen atom.

9. The actinic ray-sensitive or radiation-sensitive resin composition according to claim 1, wherein the compound (B) has a molecular weight of 450 or more.

10. The actinic ray-sensitive or radiation-sensitive resin composition according to claim 1, wherein the resin (A) has a repeating unit represented by a formula (Pa1) below: 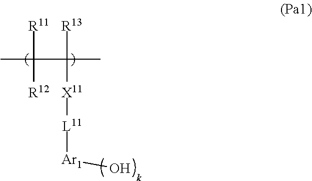
in the formula (Pa1), R¹¹, R¹², and R¹³ each independently represent a hydrogen atom, an alkyl group, a cycloalkyl group, a halogen atom, a cyano group, or an alkoxycarbonyl group; R¹² may be bonded to Ar₁ to form a ring and, in this case, R¹² represents a single bond or an alkylene group;
X¹¹ represents a single bond, —COO—, or —CONR¹⁴—,
R¹⁴ represents a hydrogen atom or an alkyl group,
L¹¹ represents a single bond or an alkylene group;
Ar₁ represents a (k+1)-valent aromatic ring group or represents, in a case of being bonded to R¹² to form a ring, a (k+2)-valent aromatic ring group; and
k represents an integer of 1 to 5.

11. The actinic ray-sensitive or radiation-sensitive resin composition according to claim 1, wherein the resin (A) has a repeating unit represented by a formula (Ga1) below: 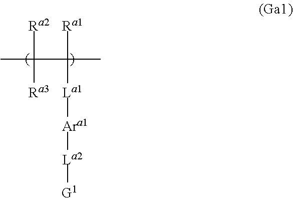
in the formula (Ga1), R^{a1}, R^{a2}, and R^{a3} each independently represent a hydrogen atom, an alkyl group, a cycloalkyl group, a halogen atom, a cyano group, or an alkoxycarbonyl group,
L^{a1} represents a single bond or a divalent linking group,
Ar^{a1} represents an aromatic ring group,
L^{a2} represents —O— or —C(═O)O—,
G¹ represents a group represented by a formula (G-1) or (G-2) below: 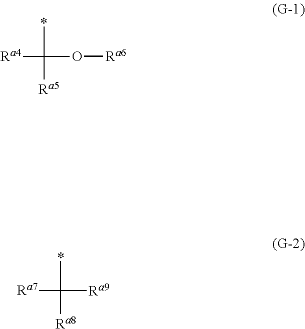
in the formula (G-1), R^{a4} represents a hydrogen atom, an alkyl group, a cycloalkyl group, an aryl group, an aralkyl group, or an alkenyl group,
R^{a5} and R^{a6} each independently represent an alkyl group, a cycloalkyl group, an aryl group, an aralkyl group, or an alkenyl group,
R^{a4} and R^{a5} may be bonded together to form a ring;
when G¹ is a group represented by the formula (G-1), Ar^{a1} may be bonded to R^{a3} or R^{a4} to form a ring;
* represents a bonding site, and
in the formula (G-2), R^{a7}, R^{a8}, and R^{a9} each independently represent an alkyl group, a cycloalkyl group, an aryl group, an aralkyl group, or an alkenyl group, two of R^{a7}, R^{a8}, and R^{a9} may be bonded together to form a ring, and
* represents a bonding site.

12. The actinic ray-sensitive or radiation-sensitive resin composition according to claim 1, further comprising a compound (C) that generates an acid upon irradiation with an actinic ray or a radiation.

13. The actinic ray-sensitive or radiation-sensitive resin composition according to claim 1, further comprising an acid diffusion control agent (D).

14. An actinic ray-sensitive or radiation-sensitive film formed from the actinic ray-sensitive or radiation-sensitive resin composition according to claim 1.

15. A pattern forming method comprising:
using the actinic ray-sensitive or radiation-sensitive resin composition according to claim 1 to form an actinic ray-sensitive or radiation-sensitive film on a substrate,
exposing the actinic ray-sensitive or radiation-sensitive film, and
using a developer to develop the exposed actinic ray-sensitive or radiation-sensitive film to form a pattern.

16. A method for producing an electronic device, the method comprising the pattern forming method according to claim 15.
